(19) United States
(12) Patent Application Publication
(10) Pub. No.: US 2016/0190145 A1
(43) Pub. Date: Jun. 30, 2016

(54) SEMICONDUCTOR DEVICE AND MANUFACTURING METHOD THEREOF

(71) Applicant: Renesas Electronics Corporation, Tokyo (JP)

(72) Inventors: Keiichi MAEKAWA, Hitachinaka-shi (JP); Shoji YOSHIDA, Hitachinaka-shi (JP); Takashi TAKEUCHI, Hitachinaka-shi (JP); Hiroshi YANAGITA, Hitachinaka-shi (JP)

(73) Assignee: Renesas Electronics Corporation, Tokyo (JP)

(21) Appl. No.: 14/972,260

(22) Filed: Dec. 17, 2015

(30) Foreign Application Priority Data
Dec. 25, 2014 (JP) 2014-262849

(51) Int. Cl. H01L 27/112

(52) U.S. Cl. CPC H01L 27/11206

(57) ABSTRACT

A semiconductor device includes an SOI substrate and an anti-fuse element formed on the SOI substrate. The SOI substrate has a p type well region formed on a main surface side of a support substrate and an SOI layer formed on the p type well region via a BOX layer. The anti-fuse element has a gate electrode formed on the SOI layer via agate insulating film. The anti-fuse element constitutes a storage element, and a first potential is applied to the gate electrode and a second potential of the same polarity as the first potential is applied to the p type well region in a write operation of the storage element.

### CROSS-REFERENCE TO RELATED APPLICATION

The present application claims priority from Japanese Patent Application No. 2014-262849 filed on Dec. 25, 2014, the content of which is hereby incorporated by reference into this application.

### TECHNICAL FIELD OF THE INVENTION

The present invention relates to a semiconductor device and a manufacturing method thereof, for example, a technique effectively applied to a semiconductor device having a semiconductor element formed on a semiconductor substrate and a manufacturing method thereof.

### BACKGROUND OF THE INVENTION

As a semiconductor device having a memory including semiconductor elements formed on a semiconductor substrate, a semiconductor device having memory cells formed of anti-fuse elements has been known. In such a semiconductor device, a high voltage is applied between a gate electrode and a source/drain region of the anti-fuse element to cause the dielectric breakdown of a gate insulating film of the anti-fuse element, thereby writing date in the memory cell. In this write operation, a read current as a gate leakage current increases between before and after the write operation due to the dielectric breakdown of the gate insulating film of the anti-fuse element.

In addition, the dielectric breakdown of a gate insulating film in a certain anti-fuse element occurs only once. Therefore, the write to the memory cell formed of the anti-fuse element is referred to as OTP (One Time Program). Also, the memory element formed of the anti-fuse element is referred to as OTP (One Time Programmable) memory element and is used for ROM (Read Only Memory) or the like.

In the technique disclosed in Japanese Patent Application Laid-Open Publication No. 2005-504434 (Patent Document 1), in a storage element including a MOS (Metal-Oxide-Semiconductor) data storage element, the write to the storage element is performed by breaking down an ultrathin dielectric film of the MOS data storage element and the read from the storage element is performed by detecting a current passing through the storage element.

Japanese Patent Application Laid-Open Publication No. 2009-117461 (Patent Document 2) discloses a technique of an anti-fuse element having an insulating film provided between a drain electrode of a MOS transistor and an electrode, in which the drain electrode and the electrode are electrically conducted by the dielectric breakdown of the insulating film.

### SUMMARY OF THE INVENTION

As a semiconductor device having the memory cell like this, a semiconductor device having an anti-fuse element formed on an SOI (Silicon On Insulator) layer formed on a support substrate via a BOX (Buried Oxide) layer in an SOI substrate in order to reduce power consumption has been known.

In this semiconductor device, hot carriers are generated when the dielectric breakdown of the gate insulating film is caused in the anti-fuse element for the write operation. For example, when the anti-fuse element has a structure similar to that of an n channel type MISFET

(Metal-Insulator-Semiconductor Field Effect Transistor) and a positive potential is applied to the gate electrode, hot holes as generated hot carriers are accelerated in the SOI layer toward the BOX layer. The hot holes accelerated toward the BOX layer are injected to the BOX layer and degrade the film quality of the BOX layer, for example, the insulation properties of the BOX layer. As a result, the read current or the like of a non-selected bit around a selected bit in the memory cell fluctuates in the read operation, and this may lead to the degradation of the data reliability of the memory cell.

The other problems and novel characteristics of the present invention will be apparent from the description of the present specification and the accompanying drawings.

According to an embodiment, a semiconductor device includes an SOI substrate and an anti-fuse element formed on the SOI substrate. The SOI substrate has a p type well region formed on a main surface side of a support substrate and an SOI layer formed on the p type well region via a BOX layer. The anti-fuse element has a gate electrode formed on the SOI layer via a gate insulating film. The anti-fuse element constitutes a storage element, and a first potential is applied to the gate electrode and a second potential of the same polarity as the first potential is applied to the p type well region in a write operation of the storage element.

Also, according to another embodiment, a semiconductor device includes an SOI substrate and an anti-fuse element and a field effect transistor formed on the SOI substrate. The SOI substrate includes a p type well region formed on a main surface side of a support substrate and an SOI layer formed on the p type well region via a BOX layer. The anti-fuse element has a gate electrode formed on the SOI layer via a gate insulating film in a memory cell region. The field effect transistor includes a gate electrode formed on the SOI layer via a gate insulating film in a peripheral circuit region. The anti-fuse element constitutes a storage element. The gate electrode of each of the anti-fuse element and the field effect transistor is made of a semiconductor film to which an n type impurity is introduced. A concentration of the n type impurity in the gate electrode of the anti-fuse element is lower than a concentration of the n type impurity in the gate electrode of the field effect transistor.

Also, according to still another embodiment, in a manufacturing method of a semiconductor device, an SOI substrate having an SOI layer formed via a BOX layer on a p type well region formed on a main surface side of a support substrate in a memory cell region is prepared. Next, in the memory cell region, a gate electrode made of a semiconductor film for an anti-fuse element is formed on the SOI layer via a gate insulating film and a hard mask film is formed on the gate electrode, and in a peripheral circuit region, a gate electrode made of a semiconductor film for a field effect transistor is formed on the SOI layer via a gate insulating film. Next, in the memory cell region, an n type impurity is ion-implanted to form an n⁺ type semiconductor region, and then the hard mask film is removed in the memory cell region. Next, in the memory cell region, an n⁻ type semiconductor region for the anti-fuse element is formed and an n type impurity is ion-implanted to the gate electrode for an anti-fuse element, and in the peripheral circuit region, an n⁻ type semiconductor region for the field effect transistor is formed. Next, in the peripheral circuit region, an n⁺ type semiconductor region for the field effect transistor is formed, and an n type impurity is ion-implanted to the gate electrode for the field effect transistor. A concentration of the n type impurity in the gate electrode for the anti-fuse element to which the n type impurity has been ion-implanted in the step of forming the n⁻ type semiconductor region for the anti-fuse element is lower than a concentration of the n type impurity in the gate electrode for the field effect transistor to which the n type impurity has been ion-implanted in the step of forming the n⁺ type semiconductor region for the field effect transistor.

According to an embodiment, it is possible to improve the performance of the semiconductor device.

### BRIEF DESCRIPTIONS OF THE DRAWINGS

FIG. 1 is a cross-sectional view illustrating the principal part of a semiconductor device of the first embodiment;

FIG. 2 is an equivalent circuit diagram of a memory cell in the semiconductor device of the first embodiment;

FIG. 3 is a table illustrating an example of voltage application conditions to respective components in a read operation and a write operation;

FIG. 4 is a manufacturing process flowchart illustrating a part of a manufacturing process of the semiconductor device of the first embodiment;

FIG. 5 is a manufacturing process flowchart illustrating a part of the manufacturing process of the semiconductor device of the first embodiment;

FIG. 6 is a cross-sectional view illustrating the principal part in the manufacturing process of the semiconductor device of the first embodiment;

FIG. 7 is a cross-sectional view illustrating the principal part in the manufacturing process of the semiconductor device of the first embodiment;

FIG. 8 is a cross-sectional view illustrating the principal part in the manufacturing process of the semiconductor device of the first embodiment;

FIG. 9 is a cross-sectional view illustrating the principal part in the manufacturing process of the semiconductor device of the first embodiment;

FIG. 10 is a cross-sectional view illustrating the principal part in the manufacturing process of the semiconductor device of the first embodiment;

FIG. 11 is a cross-sectional view illustrating the principal part in the manufacturing process of the semiconductor device of the first embodiment;

FIG. 12 is a cross-sectional view illustrating the principal part in the manufacturing process of the semiconductor device of the first embodiment;

FIG. 13 is a cross-sectional view illustrating the principal part in the manufacturing process of the semiconductor device of the first embodiment;

FIG. 14 is a cross-sectional view illustrating the principal part in the manufacturing process of the semiconductor device of the first embodiment;

FIG. 15 is a cross-sectional view illustrating the principal part in the manufacturing process of the semiconductor device of the first embodiment;

FIG. 16 is a cross-sectional view illustrating the principal part in the manufacturing process of the semiconductor device of the first embodiment;

FIG. 17 is a cross-sectional view illustrating the principal part in the manufacturing process of the semiconductor device of the first embodiment;

FIG. 18 is a cross-sectional view illustrating the principal part in the manufacturing process of the semiconductor device of the first embodiment;

FIG. 19 is a cross-sectional view illustrating the principal part in the manufacturing process of the semiconductor device of the first embodiment;

FIG. 20 is a band diagram illustrating an energy distribution in the write operation of a semiconductor device of a comparative example 1;

FIG. 21 is a diagram illustrating a potential distribution in the write operation of the semiconductor device of the first embodiment calculated by a device simulation;

FIG. 22 is a cross-sectional view illustrating the principal part of a semiconductor device of the second embodiment;

FIG. 23 is a manufacturing process flowchart illustrating a part of a manufacturing process of the semiconductor device of the second embodiment;

FIG. 24 is a cross-sectional view illustrating the principal part in the manufacturing process of the semiconductor device of the second embodiment;

FIG. 25 is a cross-sectional view illustrating the principal part in the manufacturing process of the semiconductor device of the second embodiment;

FIG. 26 is a cross-sectional view illustrating the principal part in the manufacturing process of the semiconductor device of the second embodiment;

FIG. 27 is a cross-sectional view illustrating the principal part in the manufacturing process of the semiconductor device of the second embodiment;

FIG. 28 is a cross-sectional view illustrating the principal part in the manufacturing process of the semiconductor device of the second embodiment;

FIG. 29 is a cross-sectional view illustrating the principal part in the manufacturing process of the semiconductor device of the second embodiment;

FIG. 30 is a cross-sectional view illustrating the principal part in the manufacturing process of the semiconductor device of the second embodiment;

FIG. 31 is a cross-sectional view illustrating the principal part in the manufacturing process of the semiconductor device of the second embodiment;

FIG. 32 is a cross-sectional view illustrating the principal part in the manufacturing process of the semiconductor device of the second embodiment;

FIG. 33 is a band diagram illustrating an energy distribution in the write operation of a semiconductor device of a comparative example 2;

FIG. 34 is a cross-sectional view illustrating the principal part of a semiconductor device of the third embodiment;

FIG. 35 is a manufacturing process flowchart illustrating a part of a manufacturing process of the semiconductor device of the third embodiment;

FIG. 36 is a cross-sectional view illustrating the principal part in the manufacturing process of the semiconductor device of the third embodiment;

FIG. 37 is a cross-sectional view illustrating the principal part in the manufacturing process of the semiconductor device of the third embodiment;

FIG. 38 is a cross-sectional view illustrating the principal part in the manufacturing process of the semiconductor device of the third embodiment;

FIG. 39 is a cross-sectional view illustrating the principal part in the manufacturing process of the semiconductor device of the third embodiment;

FIG. 40 is a cross-sectional view illustrating the principal part in the manufacturing process of the semiconductor device of the third embodiment;

FIG. 41 is a cross-sectional view illustrating the principal part in the manufacturing process of the semiconductor device of the third embodiment; and

FIG. 42 is a cross-sectional view illustrating the principal part in the manufacturing process of the semiconductor device of the third embodiment.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference characters throughout the drawings for describing the embodiments, and the repetitive description thereof will be omitted. In addition, in the embodiments described below, the description of the same or similar portions is not repeated in principle unless particularly required.

Also, in the drawings used in the following embodiments, hatching is sometimes omitted even in a cross-sectional view so as to make the drawings easy to see.

### First Embodiment

### Structure of Semiconductor Device

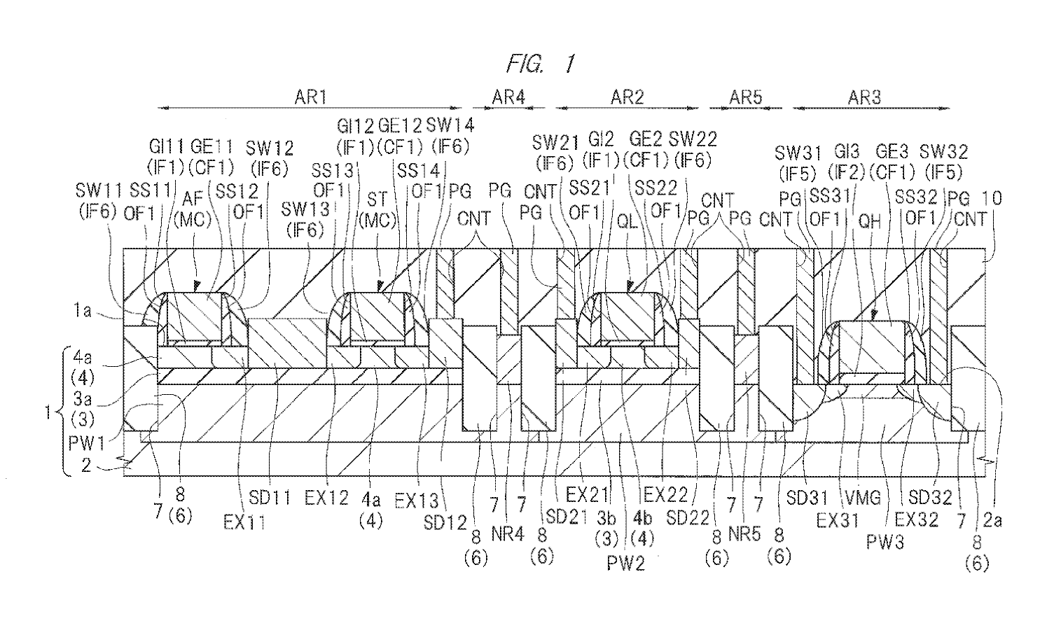

First, a structure of a semiconductor device of the first embodiment will be described with reference to drawings. FIG. 1 is a cross-sectional view illustrating the principal part of the semiconductor device of the first embodiment.

As illustrated in FIG. 1, the semiconductor device of the first embodiment is provided with an SOI substrate 1 as a semiconductor substrate. The SOI substrate 1 includes a support substrate 2 as a base member, a BOX layer 3 which is an insulating layer formed on an upper surface 2a serving as a main surface of the support substrate 2, that is, a buried oxide film, and an SOI layer 4 which is a semiconductor layer formed on the BOX layer 3.

The support substrate 2 is, for example, a single crystal silicon (Si) substrate. The BOX layer 3 is, for example, a silicon oxide (SiO₂) film and the film thickness thereof is, for example, about 4 to 100 nm. Also, the SOI layer 4 is, for example, a single crystal silicon layer and the film thickness thereof is, for example, about 4 to 100 nm.

On an upper surface 1a as a main surface of the SOI substrate 1 or the upper surface 2a as the main surface of the support substrate 2, element isolation regions 6 and a memory cell region AR1 and peripheral circuit regions AR2 and AR3 as active regions are defined. Each of the memory cell region AR1 and the peripheral circuit regions AR2 and AR3 is the region delimited by the element isolation regions 6.

In the element isolation region 6, an element isolation trench 7 penetrating through the SOI layer 4 and the BOX layer 3 is formed in the upper surface 1a as the main surface of the SOI substrate 1 so that a bottom surface thereof is located at an intermediate position in the thickness of the support substrate 2. Then, an element isolation film 8 is buried in the element isolation trench 7. The element isolation film 8 is preferably made of a silicon oxide film. The element isolation film 8 in the element isolation region 6 can be formed by the STI (Shallow Trench Isolation) method as described later.

Namely, the semiconductor device of the first embodiment has the memory cell region AR1 and the peripheral circuit regions AR2 and AR3 as partial regions of the upper surface 1a as the main surface of the SOI substrate 1 or partial regions of the upper surface 2a as the main surface of the support substrate 2.

In the memory cell region AR1, an anti-fuse element AF and a selection transistor ST as a field effect transistor are formed. The anti-fuse element AF and the selection transistor ST constitute a memory cell MC as a storage element. In the peripheral circuit region AR2, a MISFET QL as a field effect transistor is formed. In the peripheral circuit region AR3, a MISFET QH as a field effect transistor is formed.

Therefore, the semiconductor device of the first embodiment includes the SOI substrate 1, the anti-fuse element AF formed on the SOI substrate 1, the selection transistor ST formed on the SOI substrate and the MISFETs QL and QH formed on the SOI substrate 1. Namely, in the semiconductor device of the first embodiment, in order to reduce the power consumption, the anti-fuse element AF and the selection transistor ST formed on the SOI substrate 1 constitute the memory cell in the memory cell region AR1, and the MISFET QL formed on the SOI substrate 1 constitutes the peripheral circuit in the peripheral circuit region AR2.

The peripheral circuit mentioned here is, for example, a processor such as a CPU (Central Processing Unit), a sense amplifier, a column decoder, a row decoder or an input/output circuit. The MISFET QL formed in the peripheral circuit region AR2 and the MISFET QH formed in the peripheral circuit region AR3 are MISFETs for the peripheral circuit.

The peripheral circuit region AR2 is a low voltage MIS (Metal-Insulator-Semiconductor) region, and the peripheral circuit region AR3 is a high voltage MIS region. Therefore, the MISFET QL formed in the peripheral circuit region AR2 is a low withstand voltage MISFET, and the MISFET QH formed in the peripheral circuit region AR3 is a high withstand voltage MISFET. The peripheral circuit region includes the low voltage MIS region and the high voltage MIS region, and thus various types of circuits can be formed therein.

Although FIG. 1 illustrates the structure in which the memory cell region AR1 and the peripheral circuit region AR2 are adjacent to each other and the peripheral circuit region AR2 and the peripheral circuit region AR3 are adjacent to each other for easy understanding, the actual positional relation of the memory cell region AR1 and the peripheral circuit regions AR2 and AR3 can be altered as needed. In addition, a region AR4 as an external region of the memory cell region AR1 may be provided between the memory cell region AR1 and the peripheral circuit region AR2, and a region AR5 as an external region of the peripheral circuit region AR2 may be provided between the peripheral circuit region AR2 and the peripheral circuit region AR3.

In the following, the case in which an n channel type MISFET is formed as each of the selection transistor ST and the MISFETs QL and QH and an n channel type MISFET which does not have one of source/drain regions is formed as the anti-fuse element AF will be described as an example. However, a p channel type MISFET may be formed as each of the selection transistor ST and the MISFETs QL and QH and a p channel type MISFET which does not have one of source/drain regions may be formed as the anti-fuse element AF. Namely, the conductivity type of the semiconductor elements in each semiconductor region may be collectively changed to the opposite conductivity type between an n type and a p type.

Note that the “p type” indicates a conductivity type whose main charge carriers are holes. Also, the “n type” indicates a conductivity type which is opposite to the p type and whose main charge carriers are electrons.

In the memory cell region AR1, a p type well region PW1 which is a p type semiconductor region to which a p type impurity such as boron (B) is introduced is formed in the upper surface 2a as the main surface of the support substrate 2. Also, in the memory cell region AR1, a BOX layer 3a as the BOX layer 3 which is an insulating layer is formed on the p type well region PW1, and an SOI layer 4a as the SOI layer 4 which is a semiconductor layer is formed on the BOX layer 3a. The BOX layer 3 is made of, for example, a silicon oxide film, and the SOI layer 4 is made of, for example, single crystal silicon.

In the peripheral circuit region AR2, a p type well region PW2 which is a p type semiconductor region to which a p type impurity such as boron is introduced is formed in the upper surface 2a as the main surface of the support substrate 2. Also, in the peripheral circuit region AR2, a BOX layer 3b as the BOX layer 3 is formed on the p type well region PW2, and an SOI layer 4b as the SOI layer 4 is formed on the BOX layer 3b.

In the peripheral circuit region AR3, a p type well region PW3 which is a p type semiconductor region is formed in the upper surface 2a as the main surface of the support substrate 2. Also, in the peripheral circuit region AR3, the BOX layer 3 and the SOI layer 4 on the p type well region PW3 are removed.

Next, the anti-fuse element AF formed in the memory cell region AR1 will be described. The anti-fuse element AF includes a gate electrode GE11, an n⁺ type semiconductor region SD11 and an n⁻ type semiconductor region EX11.

The gate electrode GE11 is formed on the SOI layer 4a via a gate insulating film GI11 in the memory cell region AR1. The gate insulating film GI11 is made of an insulating film IF1 and the gate electrode GE11 is made of a conductive film CF1.

The insulating film. IF1 is made of, for example, an insulating film such as a silicon oxide film or a silicon oxynitride (SiON) film. Alternatively, as the insulating film IF1, for example, an insulating film made of a High-k film (high dielectric constant film) which is a metal oxide film such as a hafnium oxide (HfO₂) film, a zirconium oxide (ZrO₂) film, an aluminum oxide (Al₂O₃) film, a tantalum oxide (Ta₂O₅) film or a lanthanum oxide (La₂O₃) film can be used. Furthermore, as the insulating film IF1, a stacked film of a silicon oxide film or a silicon oxynitride film and a High-k film (high dielectric constant film) can also be used.

Note that the high dielectric constant film indicates an insulating film having a dielectric constant higher than that of, for example, a silicon nitride (SiN) film.

The conductive film. CF1 is made of, for example, a conductive film whose resistivity is reduced by introducing an n type impurity to a semiconductor film such as a polycrystalline silicon film (doped silicon film). In this case, the gate electrode GE11 is made of an n type semiconductor film to which an n type impurity is introduced.

Alternatively, as the conductive film CF1, for example, a conductive film made of a metal film such as a titanium nitride (TiN) film, a tantalum nitride (TaN) film, a tungsten nitride (WN) film, a titanium carbide (TiC) film, a tantalum carbide (TaC) film, a tungsten carbide (WC) film or a tantalum carbonitride (TaCN) film can be used. Furthermore, as the conductive film CF1, a conductive film having an MIPS (Metal Inserted Poly-silicon Stack) structure which is a stacked structure of these metal films and a doped silicon film can be used.

Sidewall spacers SW11 and SW12 as sidewall insulating films are formed on side walls of the gate electrode GE11.

Specifically, on a side surface SS11 of the gate electrode GE11 on one side (left side in FIG. 1) in a gate length direction, the sidewall spacer SW11 is formed via an offset spacer OF1. Also, on a side surface SS12 of the gate electrode GE11 on the other side (right side in FIG. 1) in the gate length direction, the sidewall spacer SW12 is formed via an offset spacer OF1. Each of the sidewall spacers SW11 and SW12 is made of an insulating film IF6.

The offset spacer OF1 is made of, for example, a silicon oxide film or a silicon nitride film or a stacked film of a silicon oxide film and a silicon nitride film. The insulating film IF6 included in each of the sidewall spacers SW11 and SW12 is made of, for example, a silicon nitride film.

Note that, since the side surface SS11 of the gate electrode GE11 and the element isolation region 6 are not far separated, the sidewall spacer SW11 is formed on the element isolation film 8.

On a part of the SOI layer 4a located on a side opposite to the gate electrode GE11 with the sidewall spacer SW12 interposed therebetween, the n⁺ type semiconductor region SD11 as a source/drain region made of a silicon layer selectively grown by, for example, the selective epitaxial growth is formed. An n type impurity such as phosphorus or arsenic is introduced to the n⁺ type semiconductor region SD11.

Note that the n⁺ type semiconductor region SD11 may be formed not only in the silicon layer formed on the SOI layer 4a by the selective epitaxial growth but also in the SOI layer 4a located below the silicon layer. Alternatively, the n⁺ type semiconductor region SD11 may be formed in a part of the SOI layer 4a located on the side opposite to the gate electrode GE11 with the sidewall spacer SW11 interposed therebetween without forming the silicon layer.

In a part of the SOI layer 4a located between the n⁺ type semiconductor region SD11 and the gate electrode GE11, an n⁻ type semiconductor region EX11 as an extension region is formed. Namely, the n⁻ type semiconductor region EX11 is formed in a part of the SOI layer 4a located on the other side (right side in FIG. 1) of the gate electrode GE11 on a side opposite to the one side (left side in FIG. 1) in the gate length direction of the gate electrode GE11. An n type impurity such as phosphorus or arsenic is introduced to the n⁻ type semiconductor region EX11.

A concentration of the n type impurity in the n⁺ type semiconductor region SD11 is higher than that of the n type impurity in the n⁻ type semiconductor region EX11. Thus, the source/drain region having an LDD (Lightly Doped Drain) structure made up of the n⁻ type semiconductor region EX11 and the n⁺ type semiconductor region SD11 can be formed.

Although the illustration thereof is omitted in FIG. 1, a metal silicide layer such as a cobalt silicide layer or a nickel silicide layer can also be formed on the gate electrode GE11 by using the salicide (Self Aligned Silicide) technology.

As illustrated in FIG. 1, a source/drain region and an extension region are not formed on a side of the side surface SS11 of the gate electrode GE11. Therefore, the anti-fuse element AF is a so-called half transistor in which the source/drain region and the extension region are not formed on one side of the gate electrode in a MISFET.

Next, the selection transistor ST formed in the memory cell region AR1 will be described. The selection transistor ST includes a gate electrode GE12, n⁺ type semiconductor regions SD11 and SD12, and n⁻ type semiconductor regions EX12 and EX13. Therefore, the anti-fuse element AF and the selection transistor ST share the n⁺ type semiconductor region SD11.

The gate electrode GE12 is also formed on the SOI layer 4a via a gate insulating film GI12 in the memory cell region AR1 like the gate electrode GE11. The gate electrode GE12 is formed via the gate insulating film GI12 on a part of the SOI layer 4a located on a side opposite to the gate electrode GE11 with the n⁺ type semiconductor region SD11 interposed therebetween. The gate insulating film GI12 is made of the insulating film IF1 and the gate electrode GE12 is made of the conductive film CF1. Like the gate electrode GE11, the gate electrode GE12 can be made of an n type semiconductor film to which an n type impurity is introduced.

As the insulating film IF1 included in the gate insulating film GI12, the same insulating film as the insulating film IF1 included in the gate insulating film GI11 can be used. In addition, the same conductive film as the conductive film CF1 included in the gate electrode GE11 can be used as the conductive film CF1 included in the gate electrode GE12.

Sidewall spacers SW13 and SW14 are formed as sidewall insulating films on side walls of the gate electrode GE12.

Specifically, on a side surface SS13 of the gate electrode GE12 on a side close to the gate electrode GE11 (left side in FIG. 1), the sidewall spacer SW13 is formed via the offset spacer OF1. Also, on aside surface SS14 of the gate electrode GE12 on a side opposite to the gate electrode GE11 (right side in FIG. 1), the sidewall spacer SW14 is formed via the offset spacer OF1. Each of the sidewall spacers SW13 and SW14 is made of the insulating film IF6.

As the insulating film IF6 included in each of the sidewall spacers SW13 and SW14, the same insulating film as the insulating film IF6 included in each of the sidewall spacers SW11 and SW12 can be used.

The n⁺ type semiconductor region SD11 made of a silicon layer is formed on a side opposite to the gate electrode GE12 with the sidewall spacer SW13 interposed therebetween.

On a part of the SOI layer 4a located on a side opposite to the gate electrode GE12 with the sidewall spacer SW14 interposed therebetween, the n⁺ type semiconductor region SD12 as a source/drain region made of a silicon layer selectively grown by the selective epitaxial growth is formed. Namely, the n⁺ type semiconductor region SD12 is formed on apart of the SOI layer 4a located on a side opposite to the n⁺ type semiconductor region SD11 with the gate electrode GE12 interposed therebetween. An n type impurity such as phosphorus or arsenic is introduced also to the n⁺ type semiconductor region SD12 like the n⁺ type semiconductor region SD11.

Note that the n⁺ type semiconductor region SD12 may also be formed not only in the silicon layer formed on the SOI layer 4a by the selective epitaxial growth but also in the SOI layer 4a located below the silicon layer like the n⁺ type semiconductor region SD11. Alternatively, the n⁺ type semiconductor region SD12 may be formed in a part of the SOI layer 4a located on a side opposite to the gate electrode GE12 with the sidewall spacer SW14 interposed therebetween without forming the silicon layer.

In a part of the SOI layer 4a located between the n⁺ type semiconductor region SD11 and the gate electrode GE12, an n⁻ type semiconductor region EX12 as an extension region is formed. Namely, the n⁻ type semiconductor region EX12 is formed in a part of the SOI layer 4a located on one side (left side in FIG. 1) of the gate electrode GE12 in the gate length direction of the gate electrode GE12. An n type impurity such as phosphorus or arsenic is introduced to the n⁻ type semiconductor region EX12 like the n⁻ type semiconductor region EX11.

In addition, in a part of the SOI layer 4a located between the n⁺ type semiconductor region SD12 and the gate electrode GE12, an n⁻ type semiconductor region EX13 as an extension region is formed. Namely, the n⁻ type semiconductor region EX13 is formed in a part of the SOI layer 4a located on the other side (right side in FIG. 1) of the gate electrode GE12 in the gate length direction of the gate electrode GE12. An n type impurity such as phosphorus or arsenic is introduced to the n⁻ type semiconductor region EX13 like the n⁻ type semiconductor region EX11.

A concentration of the n type impurity in the n⁺ type semiconductor region SD11 is higher than that of the n type impurity in the n⁻ type semiconductor region EX12. Thus, the source/drain region having an LDD structure made up of the n⁻ type semiconductor region EX12 and the n⁺ type semiconductor region SD11 can be formed.

A concentration of the n type impurity in the n⁺ type semiconductor region SD12 is higher than that of the n type impurity in the n⁻ type semiconductor region EX13. Thus, the source/drain region having an LDD structure made up of the n⁻ type semiconductor region EX13 and the n⁺ type semiconductor region SD12 can be formed.

Although the illustration thereof is omitted in FIG. 1, a metal silicide layer such as a cobalt silicide layer or a nickel silicide layer can also be formed on the n⁺ type semiconductor region SD12 and the gate electrode GE12 by using the salicide technology.

Next, the MISFET QL formed in the peripheral circuit region AR2 will be described. The MISFET QL includes a gate electrode GE2, n⁺ type semiconductor regions SD21 and SD22 and n⁻ type semiconductor regions EX21 and EX22.

The gate electrode GE2 is formed on the SOI layer 4b via a gate insulating film GI2 in the peripheral circuit region AR2. The gate insulating film GI2 is made of the insulating film IF1 and the gate electrode GE2 is made of the conductive film CF1.

As the insulating film IF1 included in the gate insulating film GI2, the same insulating film as the insulating film IF1 included in the gate insulating film GI11 can be used. In addition, the same conductive film as the conductive film CF1 included in the gate electrode GE11 can be used as the conductive film CF1 included in the gate electrode GE2. Also, like the gate electrode GE11, the gate electrode GE2 can be made of an n type semiconductor film.

Sidewall spacers SW21 and SW22 are formed as sidewall insulating films on side walls of the gate electrode GE2.

Specifically, on aside surface SS21 on one side (left side in FIG. 1) of the gate electrode GE2, the sidewall spacer SW21 is formed via the offset spacer OF1. Also, on a side surface SS22 on the other side (right side in FIG. 1) of the gate electrode GE2, the sidewall spacer SW22 is formed via the offset spacer OF1. Each of the sidewall spacers SW21 and SW22 is made of the insulating film IF6.

As the insulating film IF6 included in each of the sidewall spacers SW21 and SW22, the same insulating film as the insulating film IF6 included in each of the sidewall spacers SW11 and SW12 can be used.

On a part of the SOI layer 4b located on a side opposite to the gate electrode GE2 with the sidewall spacer SW21 interposed therebetween, the n⁺ type semiconductor region SD21 as a source/drain region made of a silicon layer selectively grown by the selective epitaxial growth is formed. In addition, on a part of the SOI layer 4b located on a side opposite to the gate electrode GE2 with the sidewall spacer SW22 interposed therebetween, the n⁺ type semiconductor region SD22 as a source/drain region made of a silicon layer selectively grown by the selective epitaxial growth is formed. An n type impurity such as phosphorus or arsenic is introduced to each of the n⁺ type semiconductor regions SD21 and SD22 like the n⁺ type semiconductor region SD11.

Note that each of the n⁺ type semiconductor regions SD21 and SD22 may be formed not only in the silicon layer formed on the SOI layer 4b by the selective epitaxial growth but also in the SOI layer 4b located below the silicon layer like the n⁺ type semiconductor region SD11. Alternatively, the n⁺ type semiconductor region SD21 may be formed in a part of the SOI layer 4b located on a side opposite to the gate electrode GE2 with the sidewall spacer SW21 interposed therebetween without forming the silicon layer. Also, the n⁺ type semiconductor region SD22 may be formed in a part of the SOI layer 4b located on a side opposite to the gate electrode GE2 with the sidewall spacer SW22 interposed therebetween without forming the silicon layer.

In a part of the SOI layer 4b located between the n⁺ type semiconductor region SD21 and the gate electrode GE2, an n⁻ type semiconductor region EX21 as an extension region is formed. In addition, in a part of the SOI layer 4b located between the n⁺ type semiconductor region SD22 and the gate electrode GE2, an n⁻ type semiconductor region EX22 as an extension region is formed. An n type impurity such as phosphorus or arsenic is introduced to each of the n⁻ type semiconductor regions EX21 and EX22 like the n⁻ type semiconductor region EX11.

A concentration of the n type impurity in the n⁺ type semiconductor region SD21 is higher than that of the n type impurity in the n⁻ type semiconductor region EX21. Thus, the source/drain region having an LDD structure made up of the n⁻ type semiconductor region EX21 and the n⁺ type semiconductor region SD21 can be formed.

A concentration of the n type impurity in the n⁺ type semiconductor region SD22 is higher than that of the n type impurity in the n⁻ type semiconductor region EX22. Thus, the source/drain region having an LDD structure made up of the n⁻ type semiconductor region EX22 and the n⁺ type semiconductor region SD22 can be formed.

Although the illustration thereof is omitted in FIG. 1, a metal silicide layer such as a cobalt silicide layer or a nickel silicide layer can also be formed on each of the n⁺ type semiconductor regions SD21 and SD22 and the gate electrode GE2 by using the salicide technology.

A concentration of the n type impurity in each of the n⁻ type semiconductor regions EX11, EX12, EX13, EX21 and EX22 is, for example, about 2×10¹⁹ cm⁻³ or more and is preferably about 1×10²⁰ cm⁻³ or more. Also, a concentration of the n type impurity in each of the n⁺ type semiconductor regions SD11, SD12, SD21 and SD22 is, for example, about 5×10²⁰ cm³ or more. Note that a concentration of the p type impurity in each of the p type well regions PW1 and PW2 is, for example, 5×10¹⁷ to 7×10¹⁸ cm³.

Next, the MISFET QH formed in the peripheral circuit region AR3 will be described. The MISFET QH includes a gate electrode GE3, n⁺ type semiconductor regions SD31 and SD32 and n⁻ type semiconductor regions EX31 and EX32.

When an n channel type MISFET is used as the MISFET QH which is a high withstand voltage MISFET, a high withstand voltage p type well region PW3 having a p type impurity concentration lower than that of the p type well region PW2 in the peripheral circuit region AR2 can be formed in the support substrate 2 in the peripheral circuit region AR3.

In addition, in an upper layer part of the p type well region PW3, that is, in a part where the channel region is formed, a p type semiconductor region VMG is formed. By adjusting the p type impurity concentration in the p type semiconductor region VMG, the threshold voltage of the MISFET QH can be adjusted.

The gate electrode GE3 is formed on the p type well region PW3, that is, on the p type semiconductor region VMG via a gate insulating film GI3 in the peripheral circuit region AR3. The gate insulating film GI3 is made of an insulating film IF2, and the gate electrode GE3 is made of the conductive film CF1.

As the insulating film IF2 included in the gate insulating film GI3, the same insulating film as the insulating film IF1 included in the gate insulating film GI11 can be used. However, since the MISFET QH is a high withstand voltage MISFET, the insulating film IF2 can be formed to have a thickness larger than that of the insulating film IF1. In addition, the same conductive film as the conductive film CF1 included in the gate electrode GE11 can be used as the conductive film CF1 included in the gate electrode GE2.

Sidewall spacers SW31 and SW32 are formed as sidewall insulating films on side walls of the gate electrode GE3.

Specifically, on a side surface SS31 on one side (left side in FIG. 1) of the gate electrode GE3, the sidewall spacer SW31 is formed via the offset spacer OF1. Also, on a side surface SS32 on the other side (right side in FIG. 1) of the gate electrode GE3, the sidewall spacer SW32 is formed via the offset spacer OF1. Each of the sidewall spacers SW31 and SW32 is made of an insulating film IF5.

As the insulating film IF5 included in each of the sidewall spacers SW31 and SW32, the same insulating film as the insulating film IF6 included in each of the sidewall spacers SW11 and SW12 can be used.

The n⁺ type semiconductor region SD31 as a source/drain region is formed in a part of the p type well region PW3 located on a side opposite to the gate electrode GE3 with the sidewall spacer SW31 interposed therebetween, that is, in the p type semiconductor region VMG. Also, the n⁺ type semiconductor region SD32 as a source/drain region is formed in a part of the p type well region PW3 located on a side opposite to the gate electrode GE3 with the sidewall spacer SW32 interposed therebetween, that is, in the p type semiconductor region VMG. An n type impurity such as phosphorus or arsenic is introduced to each of the n⁺ type semiconductor regions SD31 and SD32.

The n⁻ type semiconductor region EX31 as an extension region is formed in a part of the p type well region PW3 located between the n⁺ type semiconductor region SD31 and the gate electrode GE3, that is, in the p type semiconductor region VMG. Also, the n⁻ type semiconductor region EX32 as an extension region is formed in a part of the p type well region PW3 located between the n⁺ type semiconductor region SD32 and the gate electrode GE2, that is, in the p type semiconductor region VMG. An n type impurity such as phosphorus or arsenic is introduced to each of the n⁻ type semiconductor regions EX31 and EX32.

A concentration of the n type impurity in the n⁺ type semiconductor region SD31 is higher than that of the n type impurity in the n⁻ type semiconductor region EX31. Thus, the source/drain region having an LDD structure made up of the n⁻ type semiconductor region EX31 and the n⁺ type semiconductor region SD31 can be formed.

A concentration of the n type impurity in the n⁺ type semiconductor region SD32 is higher than that of the n type impurity in the n⁻ type semiconductor region EX32. Thus, the source/drain region having an LDD structure made up of the n⁻ type semiconductor region EX32 and the n⁺ type semiconductor region SD32 can be formed.

Although the illustration thereof is omitted in FIG. 1, a metal silicide layer such as a cobalt silicide layer or a nickel silicide layer can also be formed on each of the n⁺ type semiconductor regions SD31 and SD32 and the gate electrode GE3 by using the salicide technology.

The n⁻ type semiconductor region EX11 overlaps with a part of the gate electrode GE11 on a side close to the side surface SS12 in the gate length direction when seen in a plan view. In addition, the n⁻ type semiconductor region EX12 overlaps with a part of the gate electrode GE12 on a side close to the side surface SS13 in the gate length direction when seen in a plan view, and the n⁻ type semiconductor region EX13 overlaps with a part of the gate electrode GE12 on a side close to the side surface SS14 in the gate length direction when seen in a plan view. Meanwhile, the n⁻ type semiconductor region EX21 overlaps with a part of the gate electrode GE2 on a side close to the side surface SS21 in the gate length direction when seen in a plan view, and the n⁻ type semiconductor region EX22 overlaps with a part of the gate electrode GE2 on a side close to the side surface SS22 in the gate length direction when seen in a plan view.

An interlayer insulating film 10 is formed on the entire upper surface 1a of the SOI substrate 1 so as to cover the anti-fuse element AF, the selection transistor ST and the MISFETs QL and QH. The interlayer insulating film 10 is made of, for example, a single film of a silicon oxide film or a stacked film of a silicon nitride film and a silicon oxide film thicker than the silicon nitride film. An upper surface of the interlayer insulating film 10 is planarized so as to have a uniform height in each of the memory cell region AR1 and the peripheral circuit regions AR2 and AR3.

A contact hole CNT is formed in the interlayer insulating film 10 and a conductive plug PG is formed in the contact hole CNT. In the memory cell region AR1, the contact hole CNT and the plug PG buried therein are formed on each of the n⁺ type semiconductor region SD12 and the gate electrodes GE11 and GE12, and the plug PG is electrically connected to each of the n⁺ type semiconductor region SD12 and the gate electrodes GE11 and GE12.

In the peripheral circuit region AR2, the contact hole CNT and the plug PG buried therein are formed on each of the n⁺ type semiconductor regions SD21 and SD22 and the gate electrode GE2, and the plug PG is electrically connected to each of the n⁺ type semiconductor regions SD21 and SD22 and the gate electrodes GE2. In the peripheral circuit region AR3, the contact hole CNT and the plug PG buried therein are formed on each of the n⁺ type semiconductor regions SD31 and SD32 and the gate electrode GE3, and the plug PG is electrically connected to each of the n⁺ type semiconductor regions SD31 and SD32 and the gate electrodes GE3.

Note that the illustrations of the contact hole CNT and the plug PG on each of the gate electrodes GE11, GE12, GE2 and GE3 are omitted in FIG. 1.

On the interlayer insulating film 10 in which the plug PG is buried, a first layer wiring is formed as a damascene wiring which is a buried wiring using copper (Cu) as a main conductive material, and an upper layer wiring is further formed as a damascene wiring on the first layer wiring, but the illustrations and descriptions thereof are omitted here. The first layer wiring and the upper layer wiring thereof are not limited to the damascene wiring, and can be formed by patterning a conductive film for wiring. For example, a tungsten (W) wiring or an aluminum (Al) wiring may be used as these wirings.

<Operation of Memory Cell>

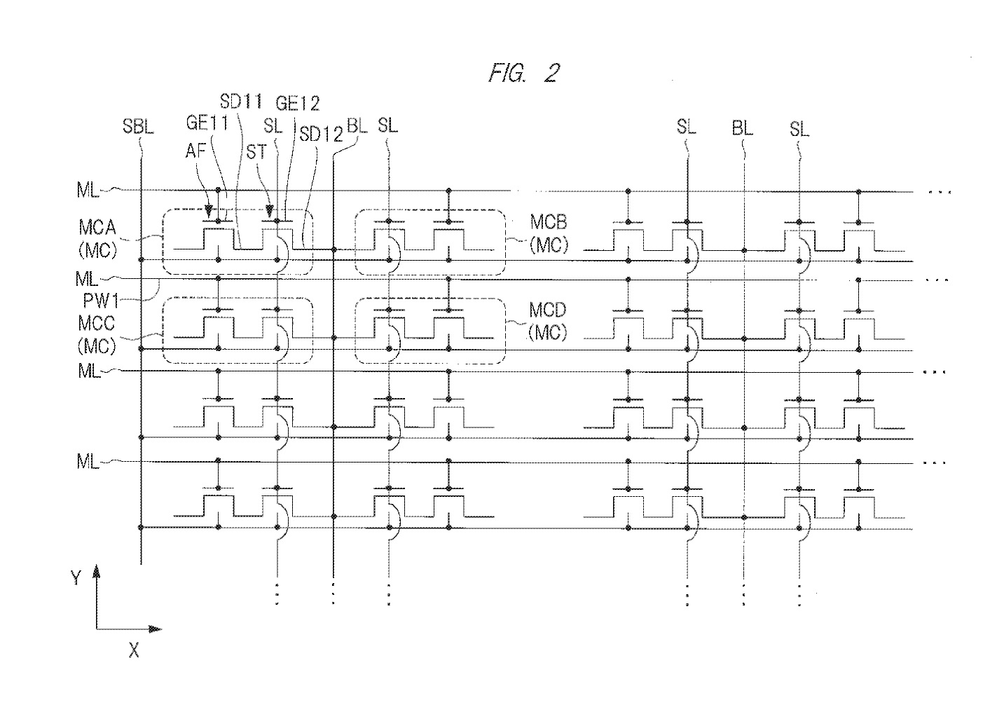

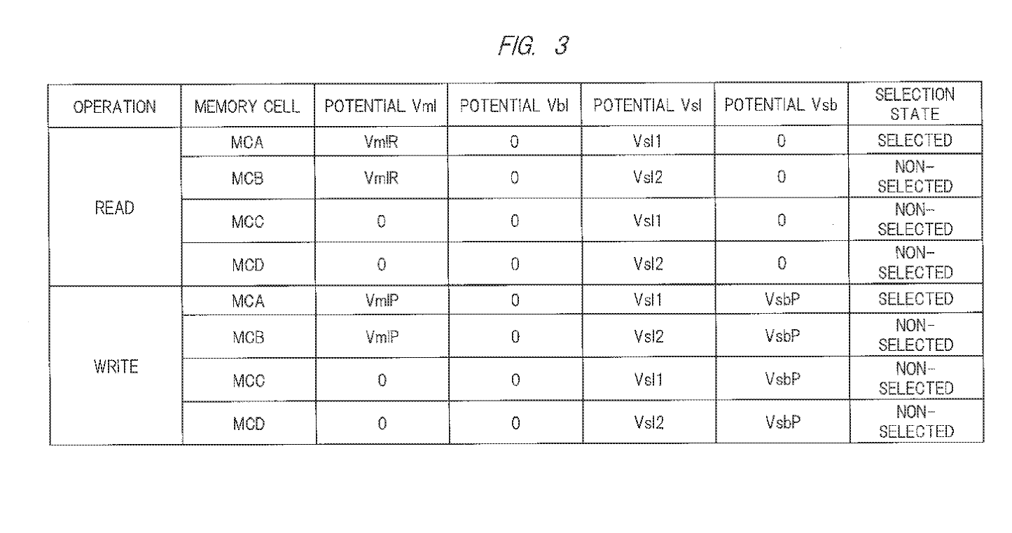

Next, an operation of the memory cell in the semiconductor device of the first embodiment will be described. FIG. 2 is an equivalent circuit diagram of a memory cell in the semiconductor device of the first embodiment. FIG. 3 is a table illustrating an example of voltage application conditions to respective components in a read operation and a write operation.

The table of FIG. 3 illustrates a potential Vml applied to the gate electrode GE11 of the anti-fuse element AF, a potential Vbl applied to the n⁺ type semiconductor region SD12 of the selection transistor ST and a potential Vsl applied to the gate electrode GE12 of the selection transistor ST in each of the read operation and the write operation. In addition, the table of FIG. 3 illustrates a potential Vsb applied to the p type well region PW1 in each of the read operation and the write operation. Note that the table of FIG. 3 illustrates a preferable example of the voltage application conditions, and the present invention is not limited thereto and various modifications can be made as needed.

In this specification, a voltage applied to a certain component is defined as a difference between a potential applied to the component and a ground potential unless otherwise stated. Therefore, the following descriptions will be made using potential instead of voltage, and the potential is equal to the voltage unless otherwise stated.

As illustrated in FIG. 2, the semiconductor device of the first embodiment includes a plurality of memory cells MC. Each of the plurality of memory cells MC is formed in the memory cell region AR1 (see FIG. 1) and includes the anti-fuse element AF and the selection transistor ST. As described with reference to FIG. 1 above, the anti-fuse element AF is formed of, for example, an n channel type half transistor and the selection transistor ST is formed of a MISFET. The anti-fuse element AF and the selection transistor ST are connected in series by sharing, for example, the n⁺ type semiconductor region SD11.

As illustrated in FIG. 2, the semiconductor device of the first embodiment includes a plurality of memory lines ML, a plurality of selection lines SL, a plurality of bit lines BL and a substrate bias line SBL. The plurality of memory lines ML are formed in the memory cell region AR1, extend in, for example, an X axis direction and are arranged in a Y axis direction which preferably orthogonally intersects with the X axis direction. The plurality of selection lines SL are formed in the memory cell region AR1, extend in, for example, the Y axis direction and are arranged in the X axis direction. The plurality of bit lines BL are formed in the memory cell region AR1, extend in, for example, the Y axis direction and are arranged in the X axis direction. The substrate bias line SBL is formed in the memory cell region AR1 and extends in, for example, the Y axis direction.

The plurality of memory lines ML and the plurality of bit lines BL intersect with each other, and the memory cell MC is formed at each of the intersections between the plurality of memory lines ML and the plurality of bit lines BL. Therefore, the memory cells MC are arranged in a matrix form in the X axis direction and the Y axis direction.

The gate electrode GE11 of the anti-fuse element AF included in the memory cell MC is connected to the memory line ML, and the gate electrode GE12 of the selection transistor ST is connected to the selection line SL. Therefore, each of the plurality of gate electrodes GE11 included in each of the plurality of memory cells MC arranged in the X axis direction is connected to the same memory line ML. Also, each of the plurality of gate electrodes GE12 included in each of the plurality of memory cells MC arranged in the Y axis direction is connected to the same selection line SL.

Out of the source/drain regions of the selection transistor ST included in the memory cell MC, the n⁺ type semiconductor region SD12 which is the source/drain region on a side opposite to the anti-fuse element AF included in the memory cell MC is connected to the bit line BL. In addition, in the anti-fuse element AF included in the memory cell MC, no source/drain region is formed on a side opposite to the selection transistor ST included in the memory cell MC, and thus the side of the anti-fuse element AF opposite to the side close to the selection transistor ST is not connected to anywhere.

Each of the plurality of n⁺ type semiconductor regions SD12 included in each of the plurality of memory cells MC arranged in the Y axis direction is connected to the same bit line BL. Also, in the example illustrated in FIG. 2, each of the two n⁺ type semiconductor regions SD12 included in each of the two memory cells MC arranged on both sides of a certain bit line BL in the X axis direction is connected to the bit line BL.

A part of the p type well region PW1 located below each of the plurality of memory cells MC is connected to the substrate bias line SBL.

As illustrated in FIG. 2, four memory cells MC arranged in a matrix form in the X axis direction and the Y axis direction are referred to as memory cells MCA, MCB, MCC and MCD. In the following description, the read operation of reading the data in the memory cell MCA among the memory cells MCA, MCB, MCC and MCD will be described as the read operation of reading data from the memory cell MC. In addition, the write operation of writing the data to the memory cell MCA among the memory cells MCA, MCB, MCC and MCD will be described as the write operation of writing data to the memory cell MC. Namely, as illustrated in FIG. 3, the case where the memory cell MCA is in a selected state and each of the memory cells MCB, MCC and MCD is in a non-selected state with respect to the selection state will be described.

In both of the read operation of reading the data of the memory cell MCA and the write operation of writing the data to the memory cell MCA, the potential Vbl applied to the n⁺ type semiconductor region SD12 of each of the memory cells MCA, MCB, MCC and MCD is set to 0 V as illustrated in FIG. 3. Namely, the potential of the n⁺ type semiconductor region SD12 of each of the memory cells MCA, MCB, MCC and MCD is the ground potential. Also, the potential Vsl applied to the gate electrode GE12 of each of the memory cells MCA and MCC is referred to as Vsl1 and the potential Vsl applied to the gate electrode GE12 of each of the memory cells MCB and MCD is referred to as Vsl2. The potential Vsl1 is a potential equal to or higher than the threshold voltage of the selection transistor ST, and the potential Vsl2 is a potential lower than the threshold voltage of the selection transistor ST.

Thus, the channel region of the selection transistor ST included in the selected memory cell MCA is sufficiently intensively inverted to be an inversion layer, so that the selection transistor ST can be turned to an ON state. Therefore, the potential Vbl of 0 V which is the potential of the bit line BL connected to the n⁺ type semiconductor region SD12 of the selection transistor ST is applied to the n⁺ type semiconductor region SD11 which the anti-fuse element AF connected in series with the selection transistor ST shares with the selection transistor ST. Namely, 0 V is applied to the n⁺ type semiconductor region SD11 of the anti-fuse element AF and the potential of the n⁺ type semiconductor region SD11 of the anti-fuse element AF becomes equal to the ground potential.

Note that the potential Vsl1 is equal to or higher than a power source voltage in the peripheral circuit region AR2 and is equal to or lower than a withstand voltage of the selection transistor ST in an ON state.

First, in the read operation of reading the data of the memory cell MCA, as illustrated in FIG. 3, the potential Vml applied to the gate electrode GE11 of each of the memory cells MCA and MCB is set to a potential VmlR, and the potential Vml applied to the gate electrode GE11 of each of the memory cells MCC and MCD is set to 0 V. Namely, the potential of the gate electrode GE11 of each of the memory cells MCC and MCD is the ground potential. In addition, the potential Vsb as the substrate bias of each of the memory cells MCA, MCB, MCC and MCD is set to 0 V. The potential VmlR is equal to the power source voltage in the peripheral circuit region AR2.

Before the gate insulating film GI11 included in the memory cell MCA is broken down, that is, before the dielectric breakdown is caused, a current flows by the FN (Fowler-Nordheim) tunneling in accordance with the potential difference between the potential VmlR of the gate electrode GE11 included in the memory cell MCA and the 0 V which is the potential of the n⁺ type semiconductor region SD11.

Meanwhile, in the write operation of writing the data to the memory cell MCA, as illustrated in FIG. 3, the potential Vml applied to the gate electrode GE11 of each of the memory cells MCA and MCB is set to the potential VmlP. Namely, in the write operation, the potential Vml applied to the gate electrode GE11 of each of the memory cells MCA and MCB is changed from the potential VmlR in the read operation. Here, the potential VmlP is a potential for the dielectric breakdown of the gate insulating film GI11. However, from the viewpoint of the reduction in power consumption, the lower potential VmlP is more desirable.

In addition, the potential Vml applied to the gate electrode GE11 of each of the memory cells MCC and MCD is set to 0 V. Namely, the potential of the gate electrode GE11 of each of the memory cells MCC and MCD is the ground potential. In addition, the potential Vsb as the substrate bias of each of the memory cells MCA, MCB, MCC and MCD is set to a potential VsbP.

In the first embodiment, the potential VsbP is a potential of the same polarity as the potential VmlP. Thus, it is possible to suppress the hot carriers from being injected to the BOX layer 3a (see FIG. 1).

The potential VsbP is preferably a potential in a range which does not increase the voltage for the dielectric breakdown of the gate insulating film GI11 of the anti-fuse element AF, that is, the gate withstand voltage in comparison with the case where the potential Vsb is 0 V in the memory cell MCA.

Furthermore, the potential Vsb is preferably a potential capable of maintaining the OFF state of the three selection transistors ST included in the memory cells MCB, MCC and MCD in the non-selected state, that is, a potential by which the inversion layer is not formed in any of the channel regions of the selection transistors ST.

In the first embodiment, in the write operation, when the potential of the n⁺ type semiconductor region SD11 is 0 V, that is, the ground potential and the selection transistor ST is in an ON state as illustrated in FIG. 3, the dielectric breakdown of the gate insulating film GI11 is caused, so that the gate electrode GE11 and the n⁺ type semiconductor region SD11 included in the memory cell MCA are electrically conducted. Therefore, the current flowing between the gate electrode GE11 and the n⁺ type semiconductor region SD11 included in the memory cell MCA, that is, the read current increases by about one order of magnitude, that is, about ten times between before and after the write operation. Whether the data in each memory cell MC is “0” or “1” is detected based on the presence/absence of the increase of the read current.

Namely, in the first embodiment, a high voltage is applied between the gate electrode GE11 and the n⁺ type semiconductor region SD11 of the anti-fuse element AF and the dielectric breakdown of the gate insulating film GI11 of the anti-fuse element AF is caused, so that data is written to the memory cell.

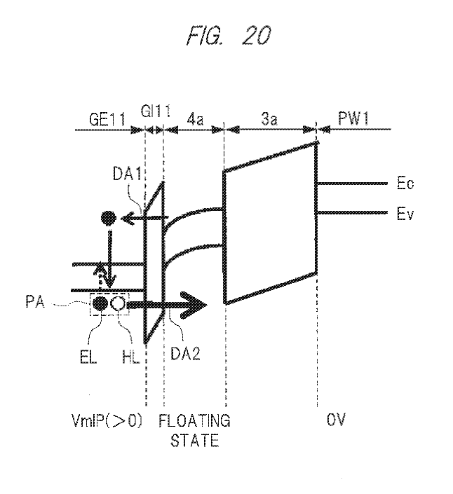

As described below with reference to FIG. 20, in the case where the anti-fuse element AF has the structure similar to that of the n channel type MISFET and the positive potential VmlP is applied to the gate electrode GE11 in the write operation, the inversion layer is formed in the channel region, while there is a fear that the hot holes as hot carriers may be injected to the BOX layer 3a.

In such a case, in the write operation, the positive potential VmlP is applied to the gate electrode GE11 and the potential VsbP of the same polarity as the potential VmlP applied to the gate electrode GE11 is applied to the p type well region PW1 as illustrated in FIG. 3. Namely, in the write operation, the positive potential VmlP is applied to the gate electrode GE11, and the positive potential VsbP is applied to the p type well region PW1. Consequently, it is possible to prevent or suppress the hot holes as hot carriers from injected to the BOX layer 3a.

Note that the potential VsbP is preferably lower than the potential VmlP. Consequently, since it is not necessary to prepare the power source voltage which supplies a potential higher than the potential VmlP, the power consumption of the semiconductor device does not increase in comparison with the case where the potential VsbP is higher than the potential VmlP.

In addition, preferably, it is necessary to set the potential VsbP, that is, the voltage VsbP to a voltage at which the FN tunneling through the BOX layer 3a does not occur or lower or a voltage at which the time dependent dielectric breakdown is guaranteed or lower in terms of the reliability of the BOX layer 3a.

Meanwhile, in the peripheral circuit region AR2, a positive potential is applied to the gate electrode GE2 and a negative potential is applied to the p type well region PW2. Therefore, a potential different from the potential VsbP applied to the p type well region PW1 is applied to the p type well region PW2. Namely, in the first embodiment, the potential applied to the p type well region PW2 and the potential VbsP applied to the p type well region PW1 in the write operation are separately controlled.

Also, when the anti-fuse element having the structure similar to that of the n channel type MISFET is formed on the semiconductor substrate as a bulk substrate and the potential of the same polarity as the potential applied to the gate electrode of the anti-fuse element is applied as the substrate bias, the potential higher than the ground potential which is the potential of the source/drain region is applied to the semiconductor substrate. Therefore, when the potential of the same polarity as the potential applied to the gate electrode is applied as the substrate bias, there is a fear that an extrinsic current may flow from the semiconductor substrate toward the source/drain region by the avalanche breakdown.

Meanwhile, in the first embodiment, the anti-fuse element AF having the structure similar to that of the n channel type MISFET is formed on the SOI substrate 1, the p type well region PW1 and the n⁺ type semiconductor region SD11 are not contact with each other, and no pn junction is interposed between the p type well region PW1 and the n⁺ type semiconductor region SD11. Therefore, even when the potential VsbP which is of the same polarity as the potential VmlP applied to the gate electrode GE11 and is higher than the ground potential which is the potential of the n⁺ type semiconductor region SD11 is applied to the p type well region PW1, there is no fear that an extrinsic current flows from the p type well region PW1 toward the n⁺ type semiconductor region SD11.

<Manufacturing Process of Semiconductor Device>

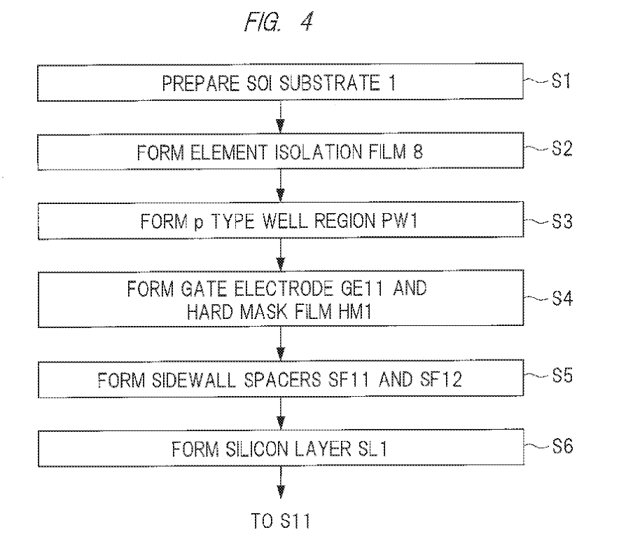

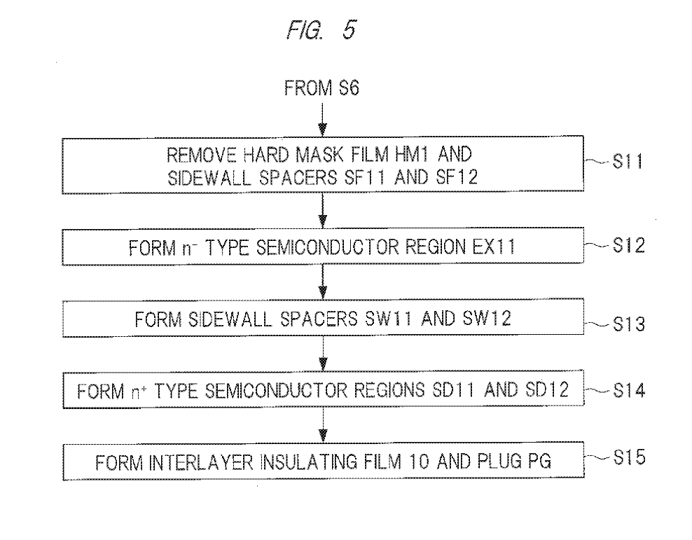

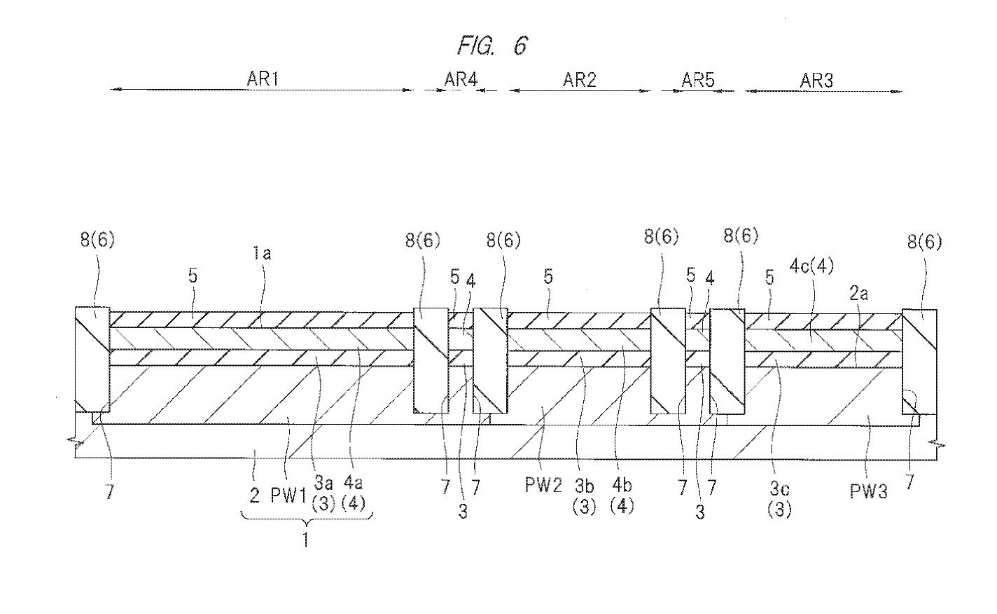

Next, a manufacturing process of the semiconductor device of the first embodiment will be described with reference to drawings. FIG. 4 and FIG. 5 are manufacturing process flowcharts each illustrating apart of the manufacturing process of the semiconductor device of the first embodiment. FIG. 6 to FIG. 19 are cross-sectional views illustrating the principal part in the manufacturing process of the semiconductor device of the first embodiment.

First, as illustrated in FIG. 6, the SOI substrate 1 is prepared (step S1 of FIG. 4). In this step S1, the SOI substrate 1 including the support substrate 2 as a base member, the BOX layer 3 which is an insulating layer formed on the upper surface 2a as the main surface of the support substrate 2, that is, a buried oxide film and the SOI layer 4 which is a semiconductor layer formed on the BOX layer 3 is prepared.

The support substrate 2 is, for example, a single crystal silicon (Si) substrate. The BOX layer 3 is, for example, a silicon oxide (SiO₂) film and the film thickness thereof is, for example, about 4 to 100 nm. Also, the SOI layer 4 is, for example, a single crystal silicon layer and the film thickness thereof is, for example, about 4 to 100 nm.

Next, as illustrated in FIG. 6, the element isolation film 8 is formed (step S2 of FIG. 4). In this step S2, the element isolation film 8 is formed in the element isolation region 6 of the SOI substrate 1 by the STI method.

Specifically, in the element isolation region 6, the element isolation trench 7 penetrating through the SOI layer 4 and the BOX layer 3 is formed in the upper surface 1a as the main surface of the SOI substrate 1 by the photolithography technique and the etching technique so that the bottom surface thereof is located at an intermediate position in the thickness of the support substrate 2. Then, an insulating film made of, for example, a silicon oxide film is formed on the SOI substrate 1 with the inclusion of the inside of the element isolation trench 7 by the chemical vapor deposition (CVD) method or the like. Thereafter, by polishing the insulating film by the chemical mechanical polishing (CMP) method or the like, the element isolation film 8 made of the insulating film is buried in the element isolation trench 7.

The memory cell region AR1 and the peripheral circuit regions AR2 and AR3 are defined or delimited by the element isolation region 6 in which the element isolation film 8 is formed in this manner. Also, the region AR4 as an external region of the memory cell region AR1 may be provided between the memory cell region AR1 and the peripheral circuit region AR2, and the region AR5 as an external region of the peripheral circuit region AR2 may be provided between the peripheral circuit region AR2 and the peripheral circuit region AR3.

In this case, the BOX layer 3 in the memory cell region AR1 is referred to as the BOX layer 3a, the SOI layer 4 in the memory cell region AR1 is referred to as the SOI layer 4a, the BOX layer 3 in the peripheral circuit region AR2 is referred to as the BOX layer 3b, and the SOI layer 4 in the peripheral circuit region AR2 is referred to as the SOI layer 4b. In addition, the BOX layer 3 in the peripheral circuit region AR3 is referred to as the BOX layer 3c and the SOI layer 4 in the peripheral circuit region AR3 is referred to as the SOI layer 4c.

In the example illustrated in FIG. 6, an insulating film 5 made of, for example, a silicon oxide film is formed on the SOI layer 4.

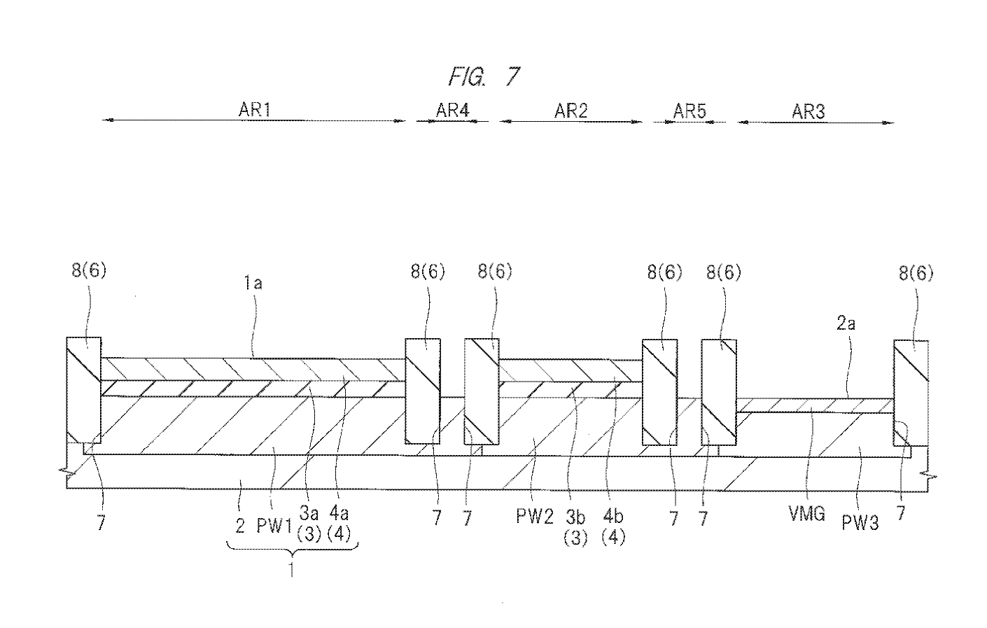

Next, as illustrated in FIG. 6 and FIG. 7, the p type well region PW1 is formed (step S3 of FIG. 4).

In this step S3, first, as illustrated in FIG. 6, the p type well region PW1 to which a p type impurity such as boron (B) is introduced is formed on the upper surface 2a as the main surface of the support substrate 2 in the memory cell region AR1. Also, the p type well region PW2 to which a p type impurity such as boron is introduced is formed on the upper surface 2a of the support substrate 2 in the peripheral circuit region AR2.

Specifically, the p type well regions PW1 and PW2 are formed by ion-implanting a p type impurity such as boron to the support substrate 2. Note that, when the p channel type MISFET or the like is formed in the peripheral circuit region AR2 and others, an n type well region is formed by ion-implanting an n type impurity such as phosphorus or arsenic to the support substrate 2.

Furthermore, in the peripheral circuit region AR3, the p type well region PW3 as a high withstand voltage well region to which a p type impurity is introduced is formed on the upper surface 2a of the support substrate 2 by ion-implanting a p type impurity such as boron to the support substrate 2. For example, the p type well region PW3 as the high withstand voltage well region can be formed by making the impurity concentration in the p type well region PW3 lower than the impurity concentration in the p type well region PW2.

Note that, when the p channel type MISFET or the like is formed in the peripheral circuit region AR2 and others, an n type well region is formed by ion-implanting an n type impurity such as phosphorus or arsenic to the support substrate 2.

In this step S3, next, the SOI layer 4c and the BOX layer 3c (see FIG. 6) are removed in the peripheral circuit region AR3 by using the photolithography technique, the dry etching and the wet etching as illustrated in FIG. 7.

Specifically, aphotoresist film (not illustrated) is first applied onto the entire upper surface 1a of the SOI substrate 1 and is then patterned through the exposure and development. Next, the insulating film 5, the SOI layer 4 and the BOX layer 3 are etched with using the patterned photoresist film as an etching mask, and the insulating film 5, the SOI layer 4 and the BOX layer 3 exposed from the photoresist film are selectively removed in the peripheral circuit region AR3. Wet etching using hydrofluoric acid or the like as an etchant can be used for this etching.

Consequently, in the region in which the insulating film 5, the SOI layer 4 and the BOX layer 3 have been removed, that is, the peripheral circuit region AR3, the upper surface 2a of the support substrate 2 is exposed. Meanwhile, in the memory cell region AR1 and the peripheral circuit region AR2, the SOI layer 4 and the BOX layer 3 covered with the photoresist film are left without being removed. Thereafter, the photoresist film is removed.

Note that, in the step S3, the SOI layer 4 and the BOX layer 3 are removed also in the regions AR4 and AR5. Also, the insulating film 5 is removed in all regions.

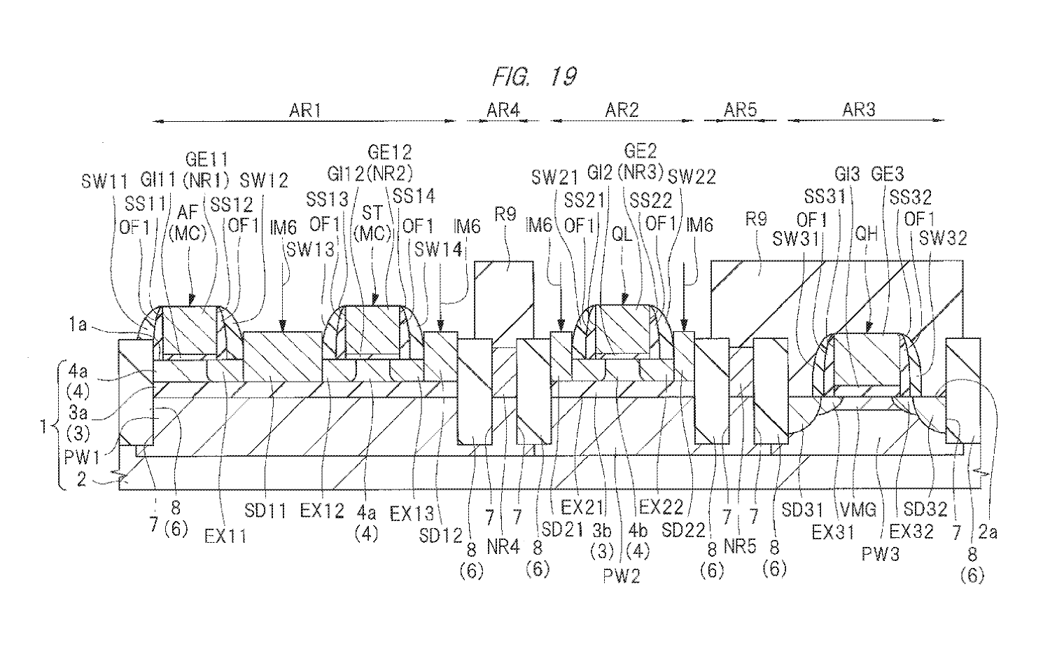

By performing the steps S1 to S3 in the above-described manner, the SOI substrate 1 including the support substrate 2, the p type well regions PW1 and PW2, the BOX layers 3a and 3b and the SOI layers 4a and 4b is prepared. The BOX layer 3a is formed on the p type well region PW1 and the SOI layer 4a is formed on the BOX layer 3a. The BOX layer 3b is formed on p type well region PW2 and the SOI layer 4b is formed on the BOX layer 3b. Further, the anti-fuse element AF (see FIG. 19), the selection transistor ST (see FIG. 19), the MISFET QL (see FIG. 19) and the MISFET QH (see FIG. 19) are formed on the SOI substrate 1 through the subsequent process.

Note that, in the peripheral circuit region AR3, the p type semiconductor region VMG is formed in an upper layer part of the p type well region PW3, that is, in a part where the channel region is formed, by ion-implanting a p type impurity such as boron to the support substrate 2. By adjusting the type of impurity to be ion-implanted or the ion-implantation conditions, the threshold voltage of the MISFET QH can be adjusted.

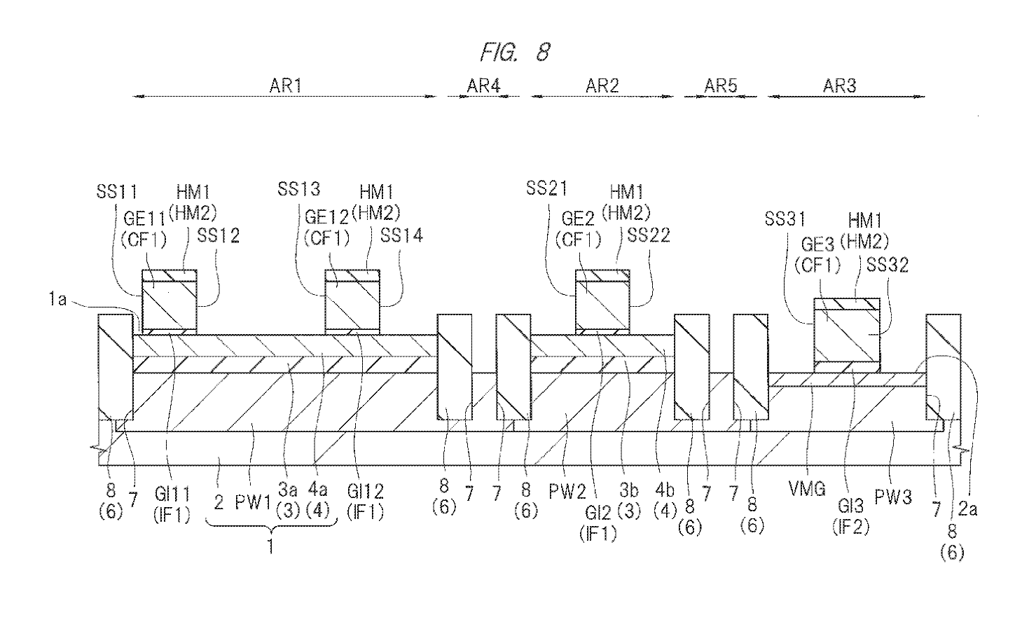

Next, as illustrated in FIG. 8, the gate electrode GE11 and a hard mask film HM1 are formed (step S4 of FIG. 4).

In this step S4, the insulating film IF1 for a gate insulating film made of, for example, a silicon oxide film is formed by, for example, thermal oxidation method on the upper surface 1a of the SOI substrate 1 in the memory cell region AR1 and the peripheral circuit region AR2.

Alternatively, as the insulating film IF1, the insulating film IF1 made of a silicon oxide film may be formed by the CVD method, and a silicon oxynitride (SiON) film in which about 3 to 10% of nitrogen is introduced to a silicon oxide film by the nitrogen plasma method may be formed. In addition, an insulating film made of a High-k film (high dielectric constant film) or a staked film of a silicon oxide film or a silicon oxynitride film and a High-k film (high dielectric constant film) may be formed as the insulating film IF1.

At this time, in the peripheral circuit region AR3, the insulating film IF2 is formed on the upper surface 2a of the support substrate 2. The thickness of the insulating film IF2 can be made larger than that of the insulating film IF1.

Next, in the memory cell region AR1 and the peripheral circuit regions AR2 and AR3, the conductive film CF1 for a gate electrode made of a conductive film whose resistivity is reduced by introducing an impurity to a semiconductor film such as a polycrystalline silicon film (doped silicon film) is formed on the insulating film IF1.

Next, in the memory cell region AR1 and the peripheral circuit regions AR2 and AR3, an insulating film HM2 made of, for example, a silicon nitride (SiN) film is formed by, for example, the CVD method on each of the insulating films IF1 and IF2.

Next, a photoresist film (not illustrated) is applied onto the entire upper surface 1a of the SOI substrate 1 and is then patterned through the exposure and development. Thereafter, the insulating film HM2, the conductive film CF1 and the insulating films IF1 and IF2 are etched by the dry etching using the patterned photoresist film as an etching mask. Consequently, in the memory cell region AR1, the gate insulating film GI11 made of the insulating film IF1 is formed on the SOI layer 4a, the gate electrode GE11 made of the conductive film CF1 is formed on the SOI layer 4a via the gate insulating film GI11, and the hard mask film HM1 as a protective film made of the insulating film HM2 is formed on the gate electrode GE11. In addition, in the memory cell region AR1, the gate insulating film GI12 made of the insulating film IF1 is formed on the SOI layer 4a, the gate electrode GE12 made of the conductive film CF1 is formed on the SOI layer 4a via the gate insulating film GI12, and the hard mask film HM1 as a protective film made of the insulating film HM2 is formed on the gate electrode GE12.

Meanwhile, in the peripheral circuit region AR2, the gate insulating film GI2 made of the insulating film IF1 is formed on the SOI layer 4b, the gate electrode GE2 made of the conductive film CF1 is formed on the SOI layer 4b via the gate insulating film GI2, and the hard mask film HM1 made of the insulating film HM2 is formed on the gate electrode GE2. In addition, in the peripheral circuit region AR3, the gate insulating film GI3 made of the insulating film IF2 is formed on the p type well region PW3, that is, the p type semiconductor region VMG, the gate electrode GE3 made of the conductive film CF1 is formed on the SOI layer 4c via the gate insulating film GI3, and the hard mask film HM1 made of the insulating film HM2 is formed on the gate electrode GE3. Thereafter, the photoresist film is removed.

Note that the side surface on one side (left side in FIG. 8) of the gate electrode GE11 is referred to as the side surface SS11, and the side surface on the other side (right side in FIG. 8) of the gate electrode GE11 is referred to as the side surface SS12. Also, the side surface of the gate electrode GE12 on the side close to the gate electrode GE11 (left side in FIG. 8) is referred to as the side surface SS13, and the side surface of the gate electrode GE12 on the side opposite to the gate electrode GE11 (right side in FIG. 8) is referred to as the side surface SS14.

Meanwhile, the side surface on one side (left side in FIG. 8) of the gate electrode GE2 is referred to as the side surface SS21, and the side surface on the other side (right side in FIG. 8) of the gate electrode GE2 is referred to as the side surface SS22. Also, the side surface on one side (left side in FIG. 8) of the gate electrode GE3 is referred to as the side surface SS31, and the side surface on the other side (right side in FIG. 8) of the gate electrode GE3 is referred to as the side surface SS32.

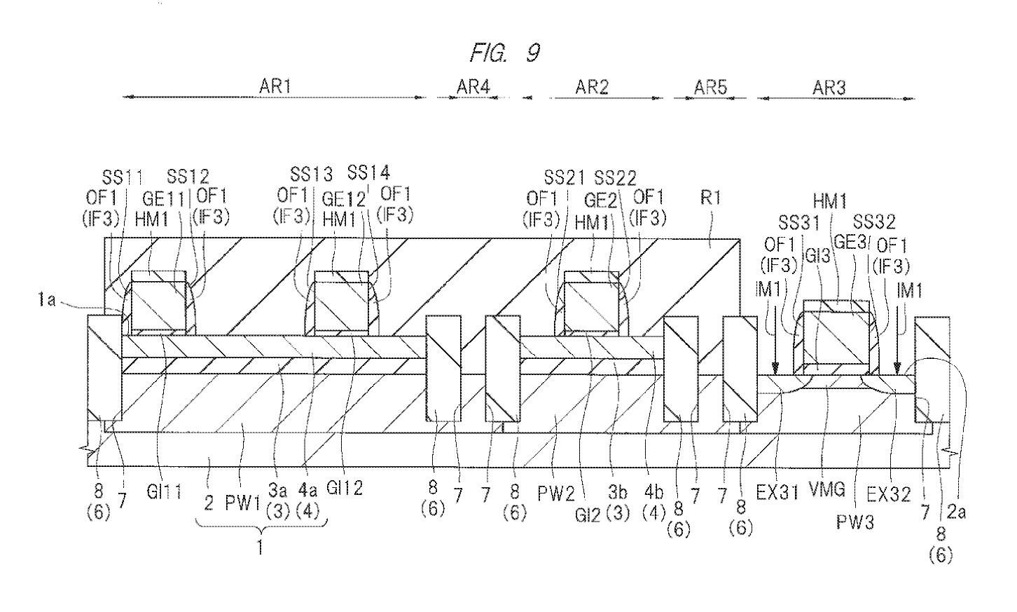

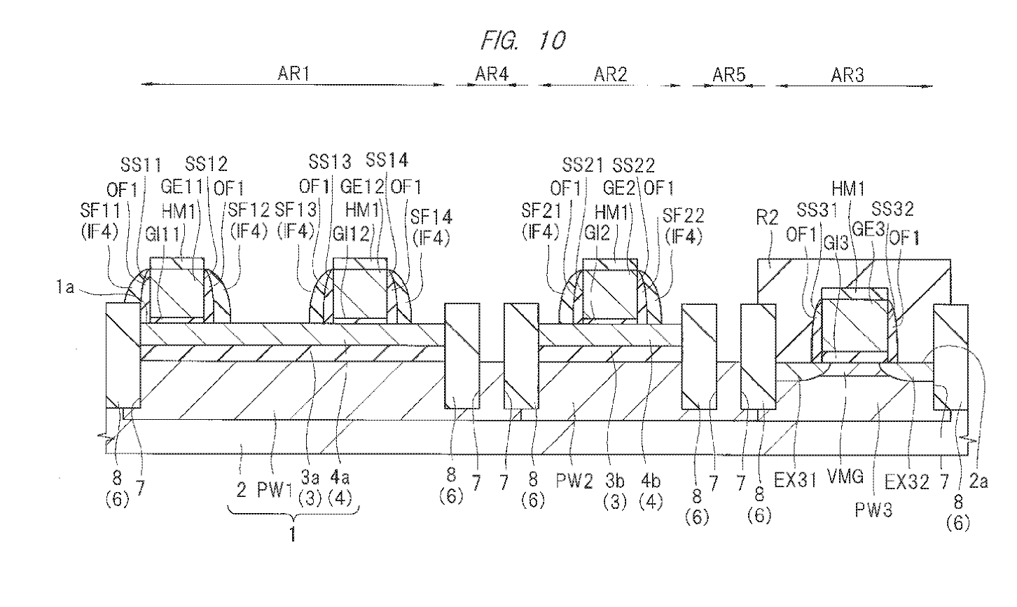

Next, as illustrated in FIG. 9 and FIG. 10, the sidewall spacers SF11 and SF12 are formed (step S5 of FIG. 4).

In this step S5, the offset spacer OF1 is first formed as illustrated in FIG. 9.

Specifically, an insulating film IF3 made of, for example, a silicon oxide film is formed by, for example, the CVD method so as to cover the gate electrodes GE11, GE12, GE2 and GE3 and the hard mask film HM1 formed on each of the gate electrodes GE11, GE12, GE2 and GE3. Then, the insulating film IF3 is etched back by anisotropic etching such as the reactive ion etching (RIE) method or the like.

Consequently, in the memory cell region AR1, the offset spacer OF1 made of a part of the insulating film IF3 left on the side surface SS11 of the gate electrode GE11 is formed, and the offset spacer OF1 made of a part of the insulating film IF3 left on the side surface SS12 of the gate electrode GE11 is formed. Also, in the memory cell region AR1, the offset spacer OF1 made of a part of the insulating film IF3 left on the side surface SS13 of the gate electrode GE12 is formed, and the offset spacer OF1 made of a part of the insulating film IF3 left on the side surface SS14 of the gate electrode GE12 is formed.

Meanwhile, in the peripheral circuit region AR2, the offset spacer OF1 made of a part of the insulating film IF3 left on the side surface SS21 of the gate electrode GE2 is formed, and the offset spacer OF1 made of a part of the insulating film IF3 left on the side surface SS22 of the gate electrode GE2 is formed. Also, in the peripheral circuit region AR3, the offset spacer OF1 made of apart of the insulating film IF3 left on the side surface SS31 of the gate electrode GE3 is formed, and the offset spacer OF1 made of a part of the insulating film IF3 left on the side surface SS32 of the gate electrode GE3 is formed.

In this step S5, next, the n⁻ type semiconductor regions EX31 and EX32 are formed as illustrated in FIG. 9.

Specifically, as illustrated in FIG. 9, a photoresist film (resist film) R1 is formed on the upper surface 1a of the SOI substrate 1 or the upper surface 2a of the support substrate 2 in the memory cell region AR1, the peripheral circuit regions AR2 and AR3 and the regions AR4 and AR5. Then, in the peripheral circuit region AR3, the photoresist film R1 formed on the upper surface 2a of the support substrate 2 is removed. At this time, the photoresist film R1 is left without being removed in the memory cell region AR1, the peripheral circuit region AR2 and the regions AR4 and AR5.

Then, an n type impurity ion IM1 is implanted to the p type well region PW3 and the p type semiconductor region VMG with using the photoresist film R1 and the hard mask film HM1 formed on the upper surface of the gate electrode GE3 as masks. Consequently, the n⁻ type semiconductor region EX31 is formed in the upper layer part of the p type well region PW3 located on the side close to the side surface SS31 with respect to the gate electrode GE3. Also, the n⁻ type semiconductor region EX32 is formed in the upper layer part of the p type well region PW3 located on the side close to the side surface SS32 with respect to the gate electrode GE3.

In this step S5, next, the sidewall spacers SF11 and SF12 are formed as illustrated in FIG. 10.

Specifically, an insulating film IF4 made of, for example, a silicon oxide film is formed by, for example, the CVD method so as to cover the hard mask film HM1 formed on each of the gate electrodes GE11, GE12 and GE2 and the offset spacer OF1 formed on the side surface of each of the gate electrodes GE11, GE12 and GE2. Then, the insulating film IF4 is etched back.

Consequently, in the memory cell region AR1, the sidewall spacer SF11 made of the insulating film IF4 is formed on the side surface SS11 of the gate electrode GE11 via the offset spacer OF1, and the sidewall spacer SF12 made of the insulating film IF4 is formed on the side surface SS12 of the gate electrode GE11 via the offset spacer OF1. Also, in the memory cell region AR1, the sidewall spacer SF13 made of the insulating film IF4 is formed on the side surface SS13 of the gate electrode GE12 via the offset spacer OF1, and the sidewall spacer SF14 made of the insulating film IF4 is formed on the side surface SS14 of the gate electrode GE11 via the offset spacer OF1.

Also, in the peripheral circuit region AR2, the sidewall spacer SF21 made of the insulating film IF4 is formed on the side surface SS21 of the gate electrode GE2 via the offset spacer OF1, and the sidewall spacer SF22 made of the insulating film IF4 is formed on the side surface SS22 of the gate electrode GE2 via the offset spacer OF1.

Meanwhile, in the peripheral circuit region AR3, a photoresist film R2 is formed so as to cover the hard mask film HM1 formed on the gate electrode GE3 and the offset spacer OF1 formed on the side surface of the gate electrode GE3.

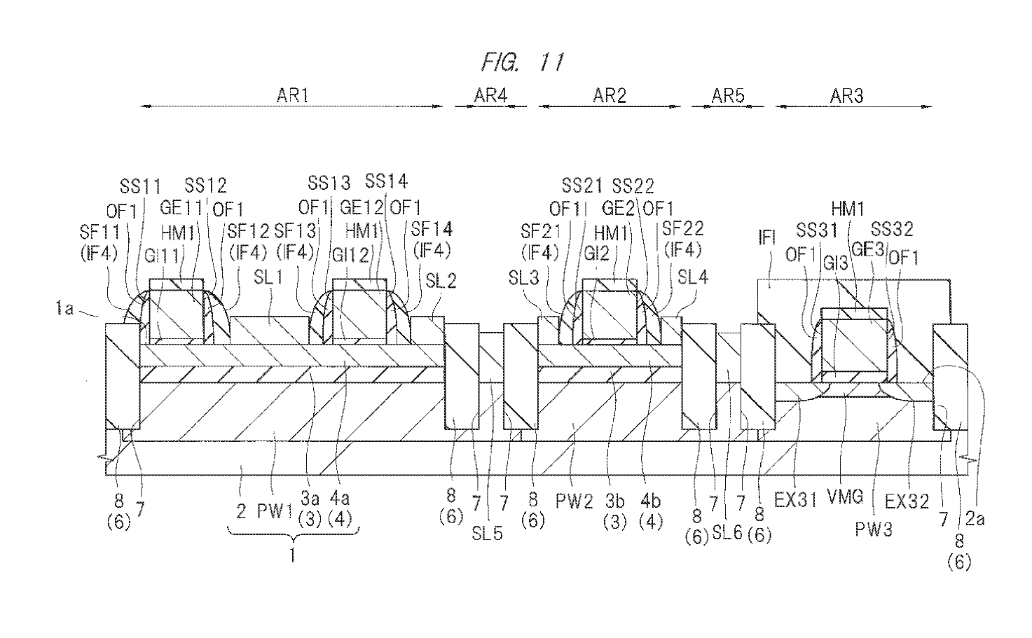

Next, as illustrated in FIG. 11, a silicon layer SL1 is formed (step S6 of FIG. 4). In this step S6, in the memory cell region AR1, silicon layers SL1 and SL2 are formed on the SOI layer 4a by the selective epitaxial growth method, and in the peripheral circuit region AR2, silicon layers SL3 and SL4 are formed on the SOI layer 4b by the selective epitaxial growth method. For example, the silicon layer is deposited by the low-pressure CVD method using dichlorosilane (SiH₂Cl₂) and hydrogen chloride (HCl) gas.

In this method, in the memory cell region AR1, the silicon layer deposited on a part where the SOI layer 4a is exposed is epitaxially grown along the single crystal of the SOI layer 4a, and in the peripheral circuit region AR2, the silicon layer deposited on a part where the SOI layer 4b is exposed is epitaxially grown along the single crystal of the SOI layer 4b.

Then, in the memory cell region AR1, the silicon layer SL1 is formed on a part of the SOI layer 4a located on the side opposite to the gate electrode GE11 with the sidewall spacer SF12 interposed therebetween when seen in a plan view and located on the side opposite to the gate electrode GE12 with the sidewall spacer SF13 interposed therebetween when seen in a plan view. Also, in the memory cell region AR1, the silicon layer SL2 is formed on a part of the SOI layer 4a located on the side opposite to the gate electrode GE12 with the sidewall spacer SF14 interposed therebetween when seen in a plan view.

Further, in the peripheral circuit region AR2, the silicon layer SL3 is formed on a part of the SOI layer 4a located on the side opposite to the gate electrode GE2 with the sidewall spacer SF21 interposed therebetween when seen in a plan view. In addition, in the peripheral circuit region AR2, the silicon layer SL4 is formed on a part of the SOI layer 4b located on the side opposite to the gate electrode GE2 with the sidewall spacer SF22 interposed therebetween when seen in a plan view.

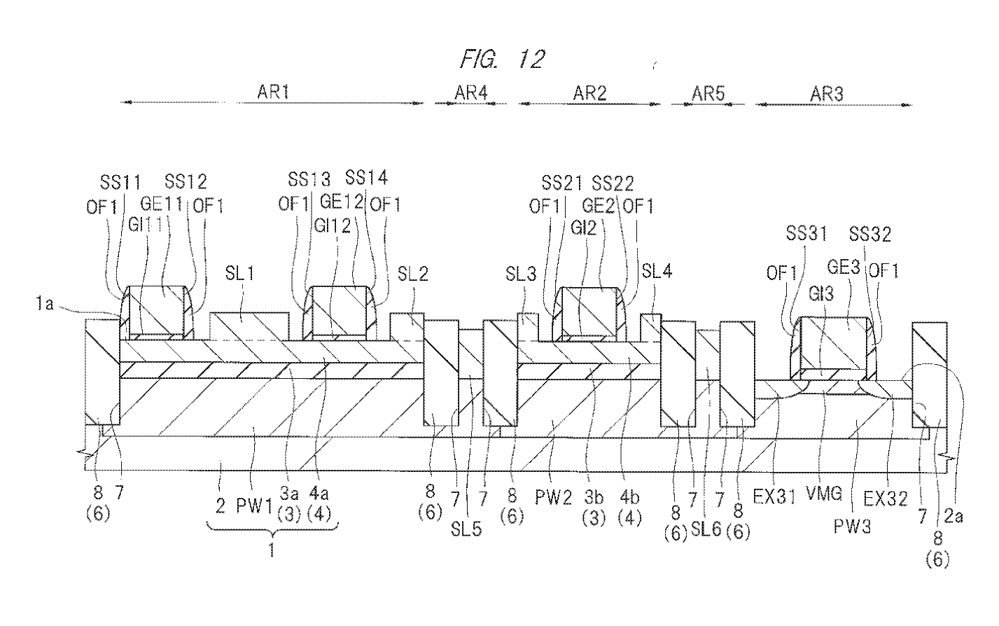

Note that a silicon layer SL5 is formed in the region AR4 and a silicon layer SL6 is formed in the region AR5. Also, in FIG. 12 and thereafter to be described below, each of the silicon layers SL1 and SL2 and the SOI layer 4a are illustrated in an integrated manner, and each of the silicon layers SL3 and SL4 and the SOI layer 4b are illustrated in an integrated manner.

Meanwhile, in the peripheral circuit region AR3, the insulating film IF1 made of, for example, a silicon nitride film is formed so as to cover the gate electrode GE3, the hard mask film HM1 formed on the gate electrode GE3 and the offset spacer OF1 formed on the side surface of the gate electrode GE3.

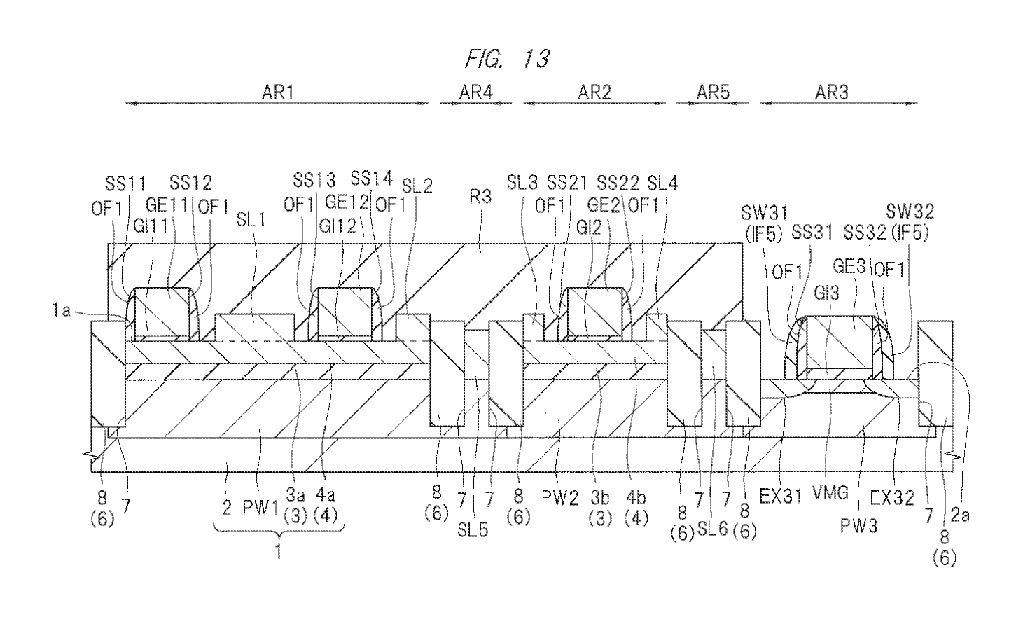

Next, as illustrated in FIG. 12 and FIG. 13, the hard mask film HM1 and the sidewall spacers SF11 and SF12 are removed (step S11 of FIG. 5).

In this step S11, first, as illustrated in FIG. 12, the hard mask film HM1 and the sidewall spacers SF11, SF12, SF13 and SF14 made of, for example, a silicon nitride film (see FIG. 11) are removed by, for example, the wet etching or dry etching using hot phosphoric acid in the memory cell region AR1.

At this time, in the peripheral circuit region AR2, the hard mask film HM1 and the sidewall spacers SF21 and SF22 (see FIG. 11) are removed. Also, in the peripheral circuit region AR3, the insulating film IF1 and the hard mask film HM1 (see FIG. 11) are removed.

In this step S11, next, as illustrated in FIG. 13, a photoresist film R3 is formed on the upper surface 1a of the SOI substrate 1 or the upper surface 2a of the support substrate 2 in the memory cell region AR1 and the peripheral circuit regions AR2 and AR3. Then, in the peripheral circuit region AR3, the photoresist film R3 formed on the upper surface 2a of the support substrate 2 is removed. At this time, in the memory cell region AR1, the peripheral circuit region AR2 and the regions AR4 and AR5, the photoresist film R3 is left without being removed.

Next, in the peripheral circuit region AR3, the insulating film IF5 made of, for example, a silicon nitride film is formed by, for example, the CVD method so as to cover the gate electrode GE3 and the offset spacer OF1 formed on each of the side surfaces SS31 and SS32 of the gate electrode GE3. Then, the insulating film IF5 is etched back.

Consequently, in the peripheral circuit region AR3, the sidewall spacer SW31 made of the insulating film IF5 is formed on the side surface SS31 of the gate electrode GE3 via the offset spacer OF1, and the sidewall spacer SW32 made of the insulating film IF5 is formed on the side surface SS32 of the gate electrode GE3 via the offset spacer OF1.

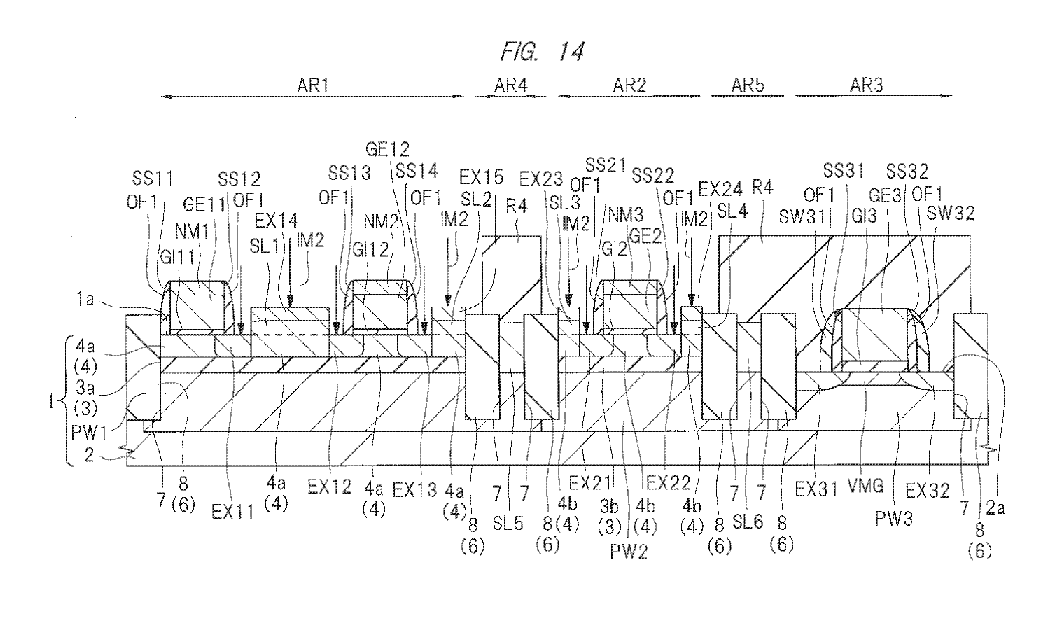

Next, as illustrated in FIG. 14, the n⁻ type semiconductor region EX11 is formed (step S12 of FIG. 5).

Specifically, in the memory cell region AR1, the peripheral circuit regions AR2 and AR3 and the regions AR4 and AR5, a photoresist film R4 is formed on the upper surface 1a of the SOI substrate 1 or the upper surface 2a of the support substrate 2. Then, the photoresist film R4 formed on the upper surface 1a of the SOI substrate 1 is removed in the memory cell region AR1 and the peripheral circuit region AR2. At this time, in the peripheral circuit region AR3 and the regions AR4 and AR5, the photoresist film R4 is left without being removed.

Then, an n type impurity ion IM2 is implanted to the SOI layers 4a and 4b with using the photoresist film R4 and the gate electrodes GE11, GE12 and GE2 as masks.

Consequently, in the memory cell region AR1, the n⁻ type semiconductor region EX11 is formed in a part of the SOI layer 4a located between the gate electrode GE11 and the silicon layer SL1. In addition, in the memory cell region AR1, the n⁻ type semiconductor region EX12 is formed in a part of the SOI layer 4a located between the gate electrode GE12 and the silicon layer SL1, and the n⁻ type semiconductor region EX13 is formed in a part of the SOI layer 4a located between the gate electrode GE12 and the silicon layer SL2. Note that the n⁻ type semiconductor region EX14 is formed also in an upper layer part of the silicon layer SL1 and the n⁻ type semiconductor region EX15 is formed also in an upper layer part of the silicon layer SL2.

Also, in the peripheral circuit region AR2, the n⁻ type semiconductor region EX21 is formed in a part of the SOI layer 4b located between the gate electrode GE2 and the silicon layer SL3, and the n⁻ type semiconductor region EX22 is formed in a part of the SOI layer 4b located between the gate electrode GE2 and the silicon layer SL4. Note that the n⁻ type semiconductor region EX23 is formed also in an upper layer part of the silicon layer SL3 and the n⁻ type semiconductor region EX24 is formed also in an upper layer part of the silicon layer SL4.

At this time, the n type impurity ion IM2 is implanted at a low concentration also to each of the gate electrodes GE11, GE12 and GE2. Consequently, an n⁻ type semiconductor region NM1 is formed in the upper layer part of the gate electrode GE11, an n⁻ type semiconductor region NM2 is formed in the upper layer part of the gate electrode GE12, and an n⁻ type semiconductor region NM3 is formed in the upper layer part of the gate electrode GE2. Thereafter, the photoresist film R4 is removed.

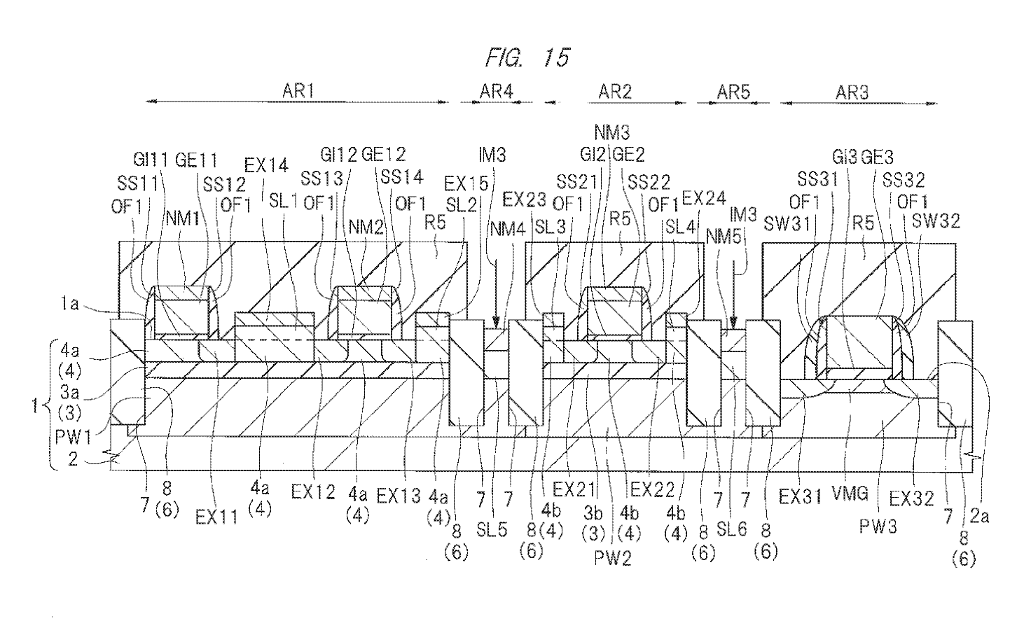

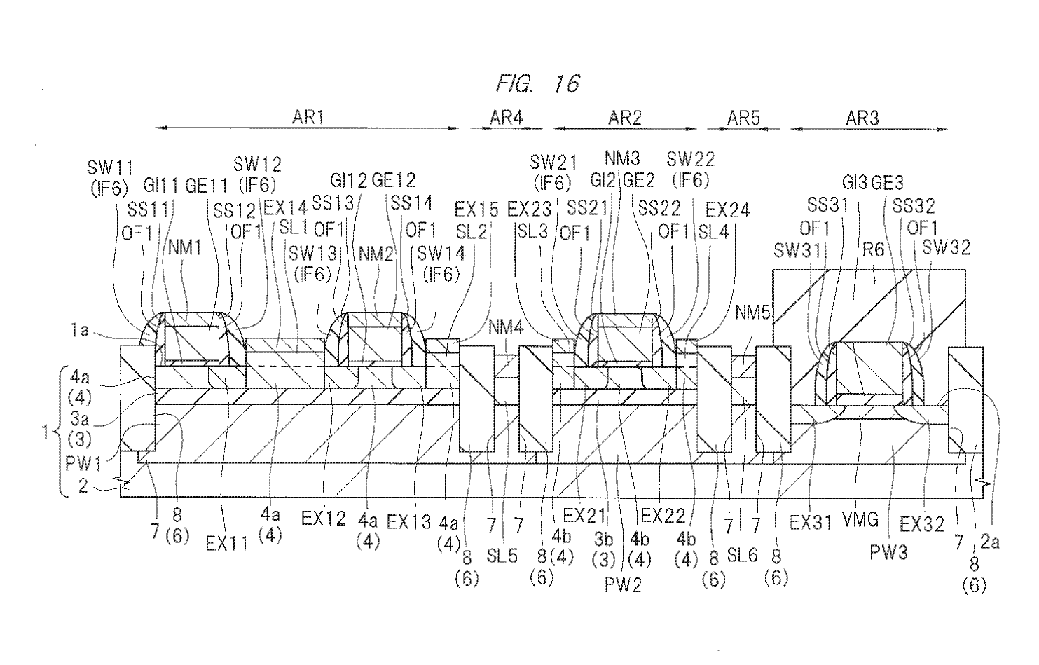

Next, as illustrated in FIG. 15 and FIG. 16, the sidewall spacers SW11 and SW12 are formed (step S13 of FIG. 5).

In this step S13, first, as illustrated in FIG. 15, a p type impurity is ion-implanted at a low concentration to the silicon layers SL5 and SL6 in the regions AR4 and AR5. Although the illustration thereof is omitted in FIG. 15, for example, a p type semiconductor region of a p channel type MISFET can be formed when the p type impurity is ion-implanted at a low concentration to the silicon layers SL5 and SL6.

Specifically, in the memory cell region AR1, the peripheral circuit regions AR2 and AR3 and the regions AR4 and AR5, a photoresist film R5 is formed on the upper surface 1a of the SOI substrate 1 or the upper surface 2a of the support substrate 2. Then, in the regions AR4 and AR5, the photoresist film R5 formed on each of the silicon layers SL5 and SL6 is removed. At this time, in the memory cell region AR1 and the peripheral circuit regions AR2 and AR3, the photoresist film R5 is left without being removed.

Then, a p type impurity ion IM3 is implanted at a low concentration to each of the silicon layers SL5 and SL6 with using the photoresist film R5 as a mask.

Consequently, in the region AR4, the n⁻ type semiconductor region NM4 is formed in an upper layer part of the silicon layer SL5. Also, in the region AR5, the p type semiconductor region NM5 is formed in an upper layer part of the silicon layer SL6. Thereafter, the photoresist film R5 is removed.

In this step S13, next, the sidewall spacers SW11 and SW12 are formed as illustrated in FIG. 16.

Specifically, the insulating film IF6 made of, for example, a silicon nitride film is formed by, for example, the CVD method so as to cover the gate electrodes GE11, GE12 and GE2 and the offset spacer OF1 formed on the side surface of each of the gate electrodes GE11, GE12 and GE2. Then, the insulating film IF6 is etched back.

Consequently, in the memory cell region AR1, the sidewall spacer SW11 made of the insulating film IF6 is formed on the side surface SS11 of the gate electrode GE11 via the offset spacer OF1, and the sidewall spacer SW12 made of the insulating film IF6 is formed on the side surface SS12 of the gate electrode GE11 via the offset spacer OF1. Also, in the memory cell region AR1, the sidewall spacer SW13 made of the insulating film IF6 is formed on the side surface SS13 of the gate electrode GE12 via the offset spacer OF1, and the sidewall spacer SW14 made of the insulating film IF6 is formed on the side surface SS14 of the gate electrode GE12 via the offset spacer OF1.

Meanwhile, in the peripheral circuit region AR3, a photoresist film R6 is formed so as to cover the gate electrode GE3 and the sidewall spacers SW31 and SW32 formed on the side surfaces of the gate electrode GE3 via the offset spacers OF1.

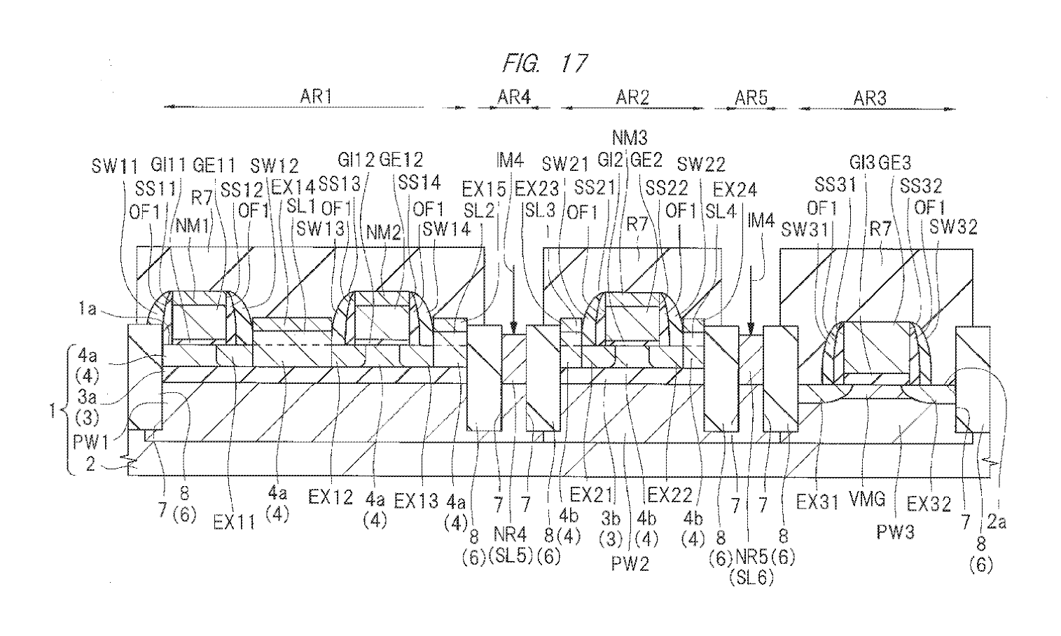

Next, as illustrated in FIG. 17 to FIG. 19, the n⁺ type semiconductor regions SD11 and SD12 are formed (step S14 of FIG. 5).

In this step S14, first, as illustrated in FIG. 17, a p type impurity is ion-implanted at a high concentration to the silicon layers SL5 and SL6 in the regions AR4 and AR5. Although the illustration thereof is omitted in FIG. 17, for example, a p⁺ type semiconductor region of a p channel type MISFET can be formed when the p type impurity is ion-implanted at a high concentration to the silicon layers SL5 and SL6.

Specifically, in the memory cell region AR1, the peripheral circuit regions AR2 and AR3 and the regions AR4 and AR5, a photoresist film R7 is formed on the upper surface 1a of the SOI substrate 1 or the upper surface 2a of the support substrate 2. Then, in the regions AR4 and AR5, the photoresist film R7 formed on each of the silicon layers SL5 and SL6 is removed. At this time, in the memory cell region AR1 and the peripheral circuit regions AR2 and AR3, the photoresist film R7 is left without being removed.

Then, a p type impurity ion IM4 is implanted at a high concentration to each of the silicon layers SL5 and SL6 with using the photoresist film R7 as a mask.

Consequently, in the region AR4, the p⁺ type semiconductor region NR4 is formed in the silicon layer SL5. Also, in the region AR5, the p⁺ type semiconductor region NR5 is formed in the silicon layer SL6. Thereafter, the photoresist film R7 is removed.

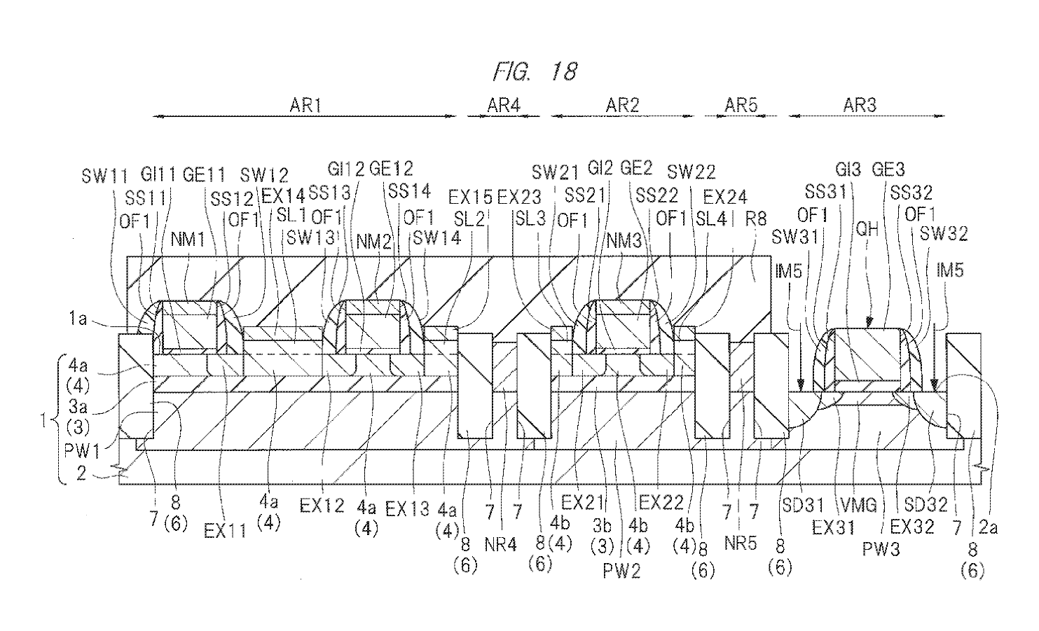

In this step S14, next, the n⁺ type semiconductor regions SD31 and SD32 are formed as illustrated in FIG. 18.

Specifically, as illustrated in FIG. 18, in the memory cell region AR1, the peripheral circuit regions AR2 and AR3 and the regions AR4 and AR5, a photoresist film R8 is formed on the upper surface 1a of the SOI substrate 1 or the upper surface 2a of the support substrate 2. Then, in the peripheral circuit region AR3, the photoresist film R8 formed on the upper surface 2a of the support substrate 2 is removed. At this time, in the memory cell region AR1, the peripheral circuit region AR2 and the regions AR4 and AR5, the photoresist film R8 is left without being removed.

Then, an n type impurity ion IM5 is implanted at a high concentration to the p type well region PW3 with using the photoresist film R8, the gate electrode GE3 and the sidewall spacers SW31 and SW32 formed on the side surfaces of the gate electrode GE3 via the offset spacers OF1 as masks. Consequently, the n⁺ type semiconductor region SD31 is formed in a part of the p type well region PW3 located on the side opposite to the gate electrode GE3 with the sidewall spacer SW31 interposed therebetween. Also, the n⁺ type semiconductor region SD32 is formed in a part of the p type well region PW3 located on the side opposite to the gate electrode GE3 with the sidewall spacer SW32 interposed therebetween. Thereafter, the photoresist film R8 is removed.

Note that, in the step S14, the MISFET QH including the gate electrode GE3, the n⁺ type semiconductor regions SD31 and SD32 and the n⁻ type semiconductor regions EX31 and EX32 is formed in the peripheral circuit region AR3.

In this step S14, next, as illustrated in FIG. 19, the n⁺ type semiconductor regions SD11 and SD12 are formed.

Specifically, in the memory cell region AR1, the peripheral circuit regions AR2 and AR3 and the regions AR4 and AR5, a photoresist film R9 is formed on the upper surface 1a of the SOI substrate 1 or the upper surface 2a of the support substrate 2. Then, in the memory cell region AR1 and the peripheral circuit region AR2, the photoresist film R9 formed on the upper surface 1a of the SOI substrate 1 is removed. At this time, in the peripheral circuit region AR3 and the regions AR4 and AR5, the photoresist film R9 is left without being removed.

Then, an n type impurity ion IM6 is implanted to the silicon layers SL1, SL2, SL3 and SL4 (see FIG. 18) and the SOI layers 4a and 4b with using the gate electrodes GE11, GE12 and GE2 and the sidewall spacers SW11, SW12, SW13, SW14, SW21 and SW22 as masks.

Consequently, in the memory cell region AR1, the n⁺ type semiconductor region SD11 is formed in the silicon layer SL1 and in a part of the SOI layer 4a located below the silicon layer SL1. Also, in the memory cell region AR1, the n⁺ type semiconductor region SD12 is formed in the silicon layer SL2 and in a part of the SOI layer 4a located below the silicon layer SL2.

In addition, in the peripheral circuit region AR2, the n⁺ type semiconductor region SD21 is formed in the silicon layer SL3 and in a part of the SOI layer 4b located below the silicon layer SL3, and the n⁺ type semiconductor region SD22 is formed in the silicon layer SL4 and in a part of the SOI layer 4b located below the silicon layer SL4.

At this time, the n type impurity ion IM6 is implanted at a high concentration also to the gate electrodes GE11, GE12 and GE2. Consequently, the n⁺ type semiconductor region NR1 is formed in the gate electrode GE11, the n⁺ type semiconductor region NR2 is formed in the gate electrode GE12, and the n⁺ type semiconductor region NR3 is formed in the gate electrode GE2. Thereafter, the photoresist film R9 is removed.

In the manner described above, the anti-fuse element AF including the gate electrode GE11, the n⁺ type semiconductor region SD11 and the n⁻ type semiconductor region EX11 is formed in the memory cell region AR1. In addition, the selection transistor ST including the gate electrode GE12, the n⁺ type semiconductor regions SD11 and SD12 and the n⁻ type semiconductor regions EX12 and EX13 is formed in the memory cell region AR1. The n type impurity concentration in each of the n⁺ type semiconductor regions SD11 and SD12 is higher than the n type impurity concentration in each of the n type semiconductor regions EX11, EX12 and EX13.

Meanwhile, the MISFET QL including the gate electrode GE2, the n⁺ type semiconductor regions SD21 and SD22 and the n⁻ type semiconductor regions EX21 and EX22 is formed in the peripheral circuit region AR2. The n type impurity concentration in each of the n⁺ type semiconductor regions SD21 and SD22 is higher than the n type impurity concentration in each of the n⁻ type semiconductor regions EX21 and EX22.

Note that, after the impurity is introduced to each of the source/drain regions and the gate electrodes by ion implantation, the annealing treatment for activating the introduced impurity may be performed.

In addition, a low resistance metal silicide layer (not illustrated) made of cobalt silicide, nickel silicide or the like may also be formed on the surfaces of the gate electrodes GE11, GE12, GE2 and GE3 and the n⁺ type semiconductor regions SD12, SD21, SD22, SD31 and SD32 by using the salicide technology. This metal silicide layer can be formed by depositing a metal film such as a cobalt (Co) film or a nickel (Ni) film so as to cover the region in which the metal silicide layer is to be formed and then performing the heat treatment, and the unreacted metal film is then removed.

Next, as illustrated in FIG. 1, the interlayer insulating film 10 and the plug PG are formed (step S15 of FIG. 5).

In this step S15, first, the interlayer insulating film 10 is formed on the entire upper surface 1a of the SOI substrate 1. Namely, the interlayer insulating film 10 is formed on the entire upper surface 1a of the SOI substrate 1 so as to cover the anti-fuse element AF, the selection transistor ST and the MISFETs QL and QH. The interlayer insulating film 10 is made of, for example, a single film of a silicon oxide film or a stacked film of a silicon nitride film and a silicon oxide film thicker than the silicon nitride film. Thereafter, the upper surface of the interlayer insulating film 10 is planarized by polishing the upper surface of the interlayer insulating film 10 by the CMP method or the like.

Next, the contact hole CNT is formed in the interlayer insulating film 10 by performing the dry etching to the interlayer insulating film 10 with using a photoresist film (not illustrated) formed and patterned on the interlayer insulating film 10 as an etching mask. At a bottom part of the contact hole CNT, for example, the n⁺ type semiconductor regions SD12, SD21, SD22, SD31 and SD32 are exposed. Although the illustration thereof is omitted in FIG. 1, for example, the gate electrodes GE11, GE12, GE2 and GE3 are also exposed at a bottom part of the contact hole CNT.

Next, the conductive plug PG made of tungsten (W) or the like is formed in the contact hole CNT. For the formation of the plug PG, for example, a barrier conductor film (for example, titanium film, titanium nitride film or stacked film thereof) is formed by the plasma CVD method or the like on the interlayer insulating film 10 with the inclusion of the inside of the contact hole CNT. Then, a main conductor film made of a tungsten film or the like is formed by the CVD method or the like on the barrier conductor film so as to fill the contact hole CNT, and the unnecessary main conductor film and barrier conductor film on the interlayer insulating film 10 are removed by the CMP method or the etch-back method. In this manner, the plug PG can be formed.

The plug PG is in contact with and electrically connected to, for example, the n⁺ type semiconductor regions SD12, SD21, SD22, SD31 and SD32 at the bottom part thereof. Although the illustration thereof is omitted in FIG. 1, the plug PG is further in contact with and electrically connected to, for example, the gate electrodes GE11, GE12, GE2 and GE3 at the bottom part thereof.

Thereafter, on the interlayer insulating film 10 in which the plug PG has been buried, the first layer wiring is formed as a damascene wiring which is a buried wiring using copper (Cu) as a main conductive material, and an upper layer wiring is further formed as a damascene wiring on the first layer wiring, but the illustrations and descriptions thereof are omitted here. Also, the first layer wiring and the upper layer wiring thereof are not limited to the damascene wiring, and can be formed by patterning a conductive film for wiring. For example, a tungsten (W) wiring or an aluminum (Al) wiring may be used as these wirings.

<Injection of Hot Carrier to BOX Layer>

Next, injection of hot carriers to the BOX layer will be described while being compared with the case where the potential applied to the p type well region PW1 is 0 V or has a polarity opposite to that of the potential applied to the gate electrode GE11, that is, the comparative example 1.

FIG. 20 is a band diagram illustrating an energy distribution in the write operation of a semiconductor device of the comparative example 1. In FIG. 20, an energy at an upper end of the valence band is represented as an energy Ev and an energy at a lower end of the conduction band is represented as an energy Ec for each layer.

The structure of the semiconductor device of the comparative example 1 is the same as that of the semiconductor device of the first embodiment, and a high voltage is applied between the gate electrode GE11 and the n⁺ type semiconductor region SD11 of the anti-fuse element AF (see FIG. 1) in the write operation. However, in the semiconductor device of the comparative example 1, a potential of 0 V is applied to the p type well region PW1 in the write operation, that is, the potential of the p type well region PW1 is the ground potential unlike the semiconductor device of the first embodiment. Alternatively, in the semiconductor device of the comparative example 1, a potential having a polarity opposite to that of the potential VmlP applied to the gate electrode GE11 is applied to the p type well region PW1 in the write operation unlike the semiconductor device of the first embodiment.

Also in the semiconductor device of the comparative example 1, a high voltage is applied between the gate electrode GE11 and the n⁺ type semiconductor region SD11 (see FIG. 1) of the anti-fuse element AF (see FIG. 1) and the dielectric breakdown of the gate insulating film GI11 of the anti-fuse element AF is caused, so that data is written to the memory cell like in the semiconductor device of the first embodiment. In this write operation, the dielectric breakdown of the gate insulating film GI11 of the anti-fuse element AF is caused, whereby the current flowing between the gate electrode GE11 and the n⁺ type semiconductor region SD11, that is, the read current as the gate leakage current increases by about one order of magnitude, that is, about ten times between before and after the write operation.

The insulation of the gate insulating film in the anti-fuse element which has been once dielectrically broken down is not restored and the read current does not decrease. Namely, the dielectric breakdown of a gate insulating film in a certain anti-fuse element occurs only once. Therefore, the write to the memory cell formed of the anti-fuse element is referred to as OTP, and the memory element formed of the anti-fuse element is referred to as OTP memory element and is used for ROM and others.

In the semiconductor device of the comparative example 1, the potential applied to the gate electrode GE11 in the write operation has the same polarity as the potential applied to the gate electrode GE11 when the inversion layer is formed in the channel region.

Meanwhile, also in the semiconductor device of the comparative example 1, the anti-fuse element AF is formed on the SOI layer 4a of the SOI substrate 1 (see FIG. 1) instead of a semiconductor substrate as a bulk substrate like in the semiconductor device of the first embodiment. Namely, also in the semiconductor device of the comparative example 1, in order to reduce the power consumption, the anti-fuse element AF and the selection transistor ST formed on the SOI substrate 1 constitute the memory cell in the memory cell region AR1 (see FIG. 1), and the MISFET QL formed on the SOI substrate 1 constitutes the peripheral circuit in the peripheral circuit region AR2 (see FIG. 1) like in the first embodiment.

However, the inventors of the present invention have found that the semiconductor device of the comparative example 1 in which the potential having a polarity opposite to that of the potential applied to the gate electrode GE11 or the potential of 0 V is applied to the p type well region PW1 in the write operation as described above has the following problem.

In the semiconductor device of the comparative example 1, the inversion layer in which the conductivity type of the carrier is inverted is formed in a part of the SOI layer 4a in contact with the gate insulating film GI11, that is, the channel region in the write operation, and electrons EL in the inversion layer are injected from the SOI layer 4a to the gate electrode GE11 by the FN tunneling as indicated by an arrow DA1.

Meanwhile, in the gate electrode GE11, hot carriers are generated when the dielectric breakdown of the gate insulating film GI11 is caused in the anti-fuse element AF for the write operation. When the anti-fuse element AF in the semiconductor device of the comparative example 1 has the structure similar to an n channel type MISFET and the positive potential VmlP is applied to the gate electrode GE11, hot holes made of holes HL of the pairs PA of the electrons EL and the holes HL are generated as hot carriers in the gate electrode GE11. Then, the hot holes generated in the gate electrode GE11 are injected to the SOI layer 4a, and are accelerated in the SOI layer 4a toward the p type well region PW1 as indicated by an arrow DA2.

Here, in the case where the anti-fuse element is formed on a semiconductor substrate as a bulk substrate, hot holes generated as hot carriers easily reach the lower surface side of the semiconductor substrate and thus do not affect the operation of each memory cell.

Meanwhile, in the semiconductor device of the comparative example 1 in which the anti-fuse element AF is formed on the SOI substrate 1, the BOX layer 3a is disposed between the SOI layer 4a and the p type well region PW1. Therefore, in the write operation, the hot holes accelerated toward the p type well region PW1 are injected to the BOX layer 3a and degrade the film quality of the BOX layer 3a, for example, the insulation properties of the BOX layer 3a. As a result, the read current in a memory cell in which data is written fluctuates in the read operation, and this may lead to the degradation of the data reliability of the memory cell in which data is written.

In addition, in the memory cell region AR1, the BOX layer 3a is shared by the plurality of memory cells MC. Therefore, if even a part of the film quality of the BOX layer 3a is degraded and even a part of the insulation properties of the BOX layer 3a is deteriorated, the read current in the memory cell in which data is not written and others also fluctuate, and this may lead to the degradation of the data reliability of the memory cell in which data is not written.

Specifically, when the potential of the gate electrode GE11 with respect to the n⁺ type semiconductor region SD11, that is, the gate voltage is increased to cause the dielectric breakdown of the gate insulating film GI11 in the write operation, the current flowing from the gate electrode GE11 to the BOX layer 3a in conjunction with the dielectric breakdown is observed. Also, when the potential of the gate electrode GE11 with respect to the n⁺ type semiconductor region SD11, that is, the gate voltage is increased again after the dielectric breakdown of the gate insulating film GI11, the current flowing to the BOX layer 3a is observed even in a range of low gate voltage.

Considering the film thickness of the BOX layer 3a, the magnitude of the current flowing from the gate electrode GE11 to the BOX layer 3a after the dielectric breakdown of the gate insulating film GI11 is much larger than the magnitude of the current expected on the assumption that the current is caused to flow by the FN tunneling. Therefore, it is conceivable that the current flowing from the gate electrode GE11 to the BOX layer 3a after the dielectric breakdown of the gate insulating film GI11 is the current resulting from the current flowing in the p type well region PW1 from the gate electrode GE11 via the BOX layer 3a due to the degradation of the film quality and the deterioration of the insulation properties of the BOX layer 3a.

### Main Characteristics and Effect of Present Embodiment

On the other hand, in the semiconductor device of the first embodiment, the potential having the same polarity as the potential applied to the gate electrode GE11 is applied to the p type well region PW1 in the write operation.

Consequently, when the dielectric breakdown of the gate insulating film GI11 is caused in the anti-fuse element AF for the write operation, the hot holes generated as hot carriers are not accelerated toward the p type well region PW1. Therefore, the injection of the hot holes to the BOX layer 3a can be prevented or suppressed in the write operation, and it is possible to prevent or suppress the degradation of the film quality of the BOX layer 3a, for example, the deterioration of the insulation properties of the BOX layer 3a. Accordingly, the fluctuation of the read current in the memory cell can be prevented or suppressed in the read operation, and it is possible to improve the data reliability of the memory cell.

In addition, when the potential applied to the p type well region PW1 is excessively increased in the write operation and the potential of the channel region of the anti-fuse element AF becomes high, the potential immediately below the gate insulating film GI11 also becomes high. Therefore, there is a fear that the voltage for the dielectric breakdown of the gate insulating film GI11, that is, the gate withstand voltage becomes high. Accordingly, the potential VsbP applied to the p type well region PW1 in the write operation is preferably in the range which does not increase the gate withstand voltage in comparison with the case where the potential Vsb is 0 V in the memory cell MCA.

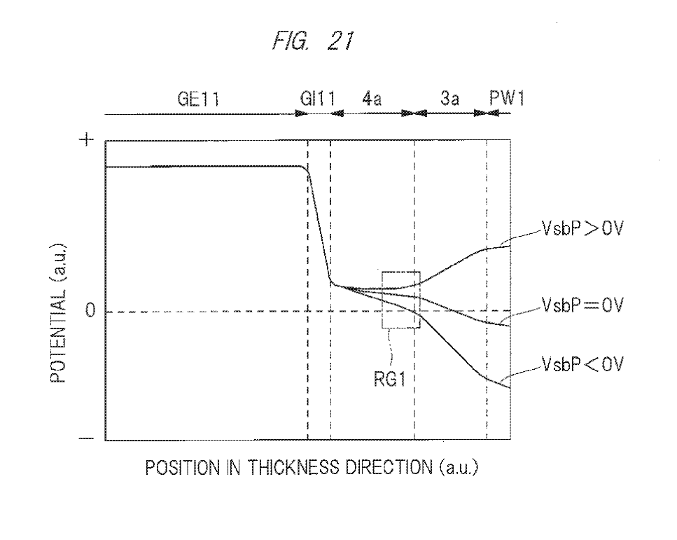

FIG. 21 is a diagram illustrating a potential distribution in the write operation of the semiconductor device of the first embodiment calculated by a device simulation. FIG. 21 schematically illustrates the result of the device simulation about the potential distribution in the thickness direction of the anti-fuse element AF and the SOI substrate 1 in the cases where the potential VsbP is a negative voltage, 0 V and a positive voltage. The horizontal axis of FIG. 21 represents the position in the thickness direction and the vertical axis of FIG. 21 represents the potential.

As illustrated in FIG. 21, as the potential VsbP applied to the p type well region PW1 in the write operation increases, the potential in the p type well region PW1 also increases. In addition, the potential in the BOX layer 3a also increases. Furthermore, as illustrated in a region RG1 surrounded by a two-dot chain line of FIG. 21, the potential in a part of the SOI layer 4a on the side close to the BOX layer 3a also increases.

However, the potential in a part of the SOI layer 4a on the side close to the gate insulating film GI11 does not change regardless of the potential VsbP applied to the p type well region PW1 in the write operation. This indicates that there is a voltage range in which the influence of the potential VsbP applied to the p type well region PW1 in the write operation does not directly reach the part of the SOI layer 4a on the side close to the gate insulating film GI11. As described above, the potential VsbP applied to the p type well region PW1 in the write operation is preferably in the range which does not increase the gate withstand voltage in comparison with the case where the potential Vsb is 0 V in the memory cell MCA.

Note that, when the I-V characteristics of the gate leakage current which actually flows between the gate electrode GE11 and the n⁺ type semiconductor region SD11 by the FN tunneling in the range in which the potential VsbP applied to the p type well region PW1 in the write operation does not affect the potential immediately below the gate insulating film GI11 are measured, any difference is not observed regardless of the potential VsbP. Also from this fact, it is apparent that the influence of the potential VsbP applied to the p type well region PW1 does not directly reach the part of the SOI layer 4a on the side close to the gate insulating film GI11 as described above.

In addition, when the potential which has the same polarity as the potential applied to the gate electrode GE11 included in the anti-fuse element AF and is applied to the p type well region PW1 becomes high in the write operation, the forward bias is applied to a part of the p type well region PW1 located below the selection transistor ST. Therefore, there is a fear that the threshold voltage of the selection transistor ST decreases. Accordingly, the potential VsbP applied to the p type well region PW1 in the write operation is preferably the potential at which the selection transistor ST included in each of the memory cells MCB and MCD in a non-selected state can maintain the OFF state. Namely, the potential VsbP is a potential at which the inversion layer is not formed in any of the channel regions ST of the selection transistor included in each of the memory cells MCB and MCD in a non-selected state.

### Second Embodiment

The example in which the conductivity type of the conductive film CF1 included in the gate electrode GE11 of the anti-fuse element AF is an n type has been described in the first embodiment. Meanwhile, an example in which the conductivity type of the conductive film CF1 included in the gate electrode GE11 of the anti-fuse element AF is a p type or the conductivity type thereof is made close to a p type even though it is an n type will be described in the second embodiment.

<Structure of Semiconductor Device>

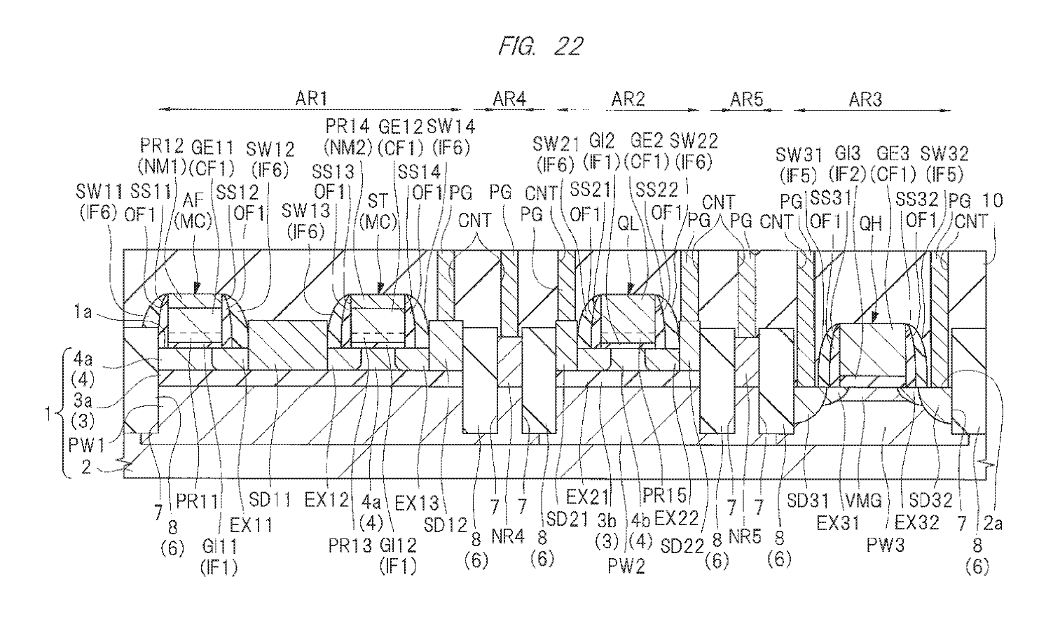

First, a structure of a semiconductor device of the second embodiment will be described with reference to drawings. FIG. 22 is a cross-sectional view illustrating the principal part of the semiconductor device of the second embodiment.

The structure of the semiconductor device of the second embodiment is the same as that of the semiconductor device of the first embodiment except that the conductivity type of at least apart PR1 of the conductive film CF1 included in the gate electrode GE11 of the anti-fuse element AF, the part PR1 being in contact with the gate insulating film GI11, is a p type or the conductivity type thereof is made close to a p type even though it is an n type. Therefore, the difference from the structure of the semiconductor device of the first embodiment will be mainly described below.

Also in the second embodiment, the gate electrode GE11 of the anti-fuse element AF and the gate electrode GE12 of the selection transistor ST are both made of the conductive film CF1 like in the first embodiment.

Meanwhile, in the second embodiment, the conductive film CF1 is made of a conductive film whose resistivity is reduced by introducing a p type impurity to a semiconductor film such as a polycrystalline silicon film (doped silicon film). Namely, the conductivity type of the conductive film CF1 is a p type.

Also, the n⁻ type semiconductor region NM1 to which an n type impurity is introduced at a low concentration is formed in an upper layer part PR12 of the gate electrode GE11, but the n type impurity is not introduced to the gate electrode GE11 other than the part in which the n⁻ type semiconductor region NM1 is formed, and the gate electrode GE11 other than the part in which the n⁻ type semiconductor region NM1 is formed is made of the conductive film CF1 serving as a p type semiconductor film. At this time, the gate electrode GE11 is made of a p type semiconductor film on the whole.

Alternatively, the n⁻ type semiconductor region NM2 to which an n type impurity is introduced at a low concentration is formed in an upper layer part PR14 of the gate electrode GE12, but the n type impurity is not introduced to the gate electrode GE12 other than the part in which the n⁻ type semiconductor region NM2 is formed, and the gate electrode GE12 other than the part in which the n⁻ type semiconductor region NM2 is formed is made of the conductive film CF1 serving as a p type semiconductor film. At this time, the gate electrode GE12 is made of a p type semiconductor film on the whole.

Therefore, a part PR11 of the gate electrode GE11, which is in contact with the gate insulating film GI11, is made of the conductive film CF1 serving as a p type semiconductor film. Also, a part PR13 of the gate electrode GE12, which is in contact with the gate insulating film GI12, is made of the conductive film CF1 serving as a p type semiconductor film.

Alternatively, the conductive film CF1 may be made of a conductive film whose resistivity is reduced by introducing an n type impurity to a semiconductor film such as a polycrystalline silicon film at a low concentration (doped silicon film). Namely, the conductivity type of the conductive film CF1 may be an n type. At this time, each of the gate electrodes GE11 and GE12 is made of an n type semiconductor film to which an n type impurity is introduced.

The gate electrode GE2 of the MISFET QL is also made of the conductive film CF1, but an n type impurity is introduced at a high concentration totally to the conductive film CF1 included in the gate electrode GE2 from the upper surface to the lower surface thereof. Namely, the gate electrode GE2 is made of a high-concentration n type semiconductor film to which an n type impurity is introduced at a high concentration like in the first embodiment.

Accordingly, even when the conductivity type of the conductive film CF1 is an n type, the n type impurity concentration in the gate electrode GE11 other than the part in which the n⁻ type semiconductor region NM1 is formed is lower than the n type impurity concentration in the gate electrode GE2. Also, even when the conductivity type of the conductive film CF1 is an n type, the n type impurity concentration in the gate electrode GE12 other than the part in which the n⁻ type semiconductor region NM2 is formed is lower than the n type impurity concentration in the gate electrode GE2.

In such a case, the n type impurity concentration in the part PR11 of the gate electrode GE11, which is in contact with the gate insulating film GI11, is lower than the n type impurity concentration in apart PR15 of the gate electrode GE2, which is in contact with the gate insulating film GI2. Also, the n type impurity concentration in the part PR13 of the gate electrode GE12, which is in contact with the gate insulating film GI12, is lower than the n type impurity concentration in the part PR15 of the gate electrode GE2, which is in contact with the gate insulating film GI2.

Alternatively, the n type impurity concentration in the part PR11 of the gate electrode GE11, which is in contact with the gate insulating film GI11, is lower than the n type impurity concentration in the upper layer part PR12 of the gate electrode GE11. At this time, as described above, the n type impurity concentration in the gate electrode GE11 and the n type impurity concentration in the gate electrode GE2 may be different from each other or equal to each other.

Consequently, it is possible to prevent or suppress the deterioration of the insulation properties of the BOX layer 3a due to the hot carriers injected to the BOX layer 3a in the write operation of writing data to the memory cell MC, and the absolute value of the potential applied to the gate electrode GE11 can be reduced.

Note that an average value of the n type impurity concentration in each part of the gate electrode GE11 may be lower than an average value of the n type impurity concentration in each part of the gate electrode GE2. Also, an average value of the n type impurity concentration in each part of the gate electrode GE12 may be lower than an average value of the n type impurity concentration in each part of the gate electrode GE2.

<Operation of Memory Cell>

Since the operation of the memory cell in the semiconductor device of the second embodiment is the same as that of the memory cell in the semiconductor device of the first embodiment described with reference to FIG. 2 and FIG. 3 except that a negative potential is applied to the gate electrode GE11 in the write operation of writing data to the memory cell MC, the description thereof is omitted.

However, in the second embodiment, a negative potential is applied to the gate electrode GE11 in the write operation of writing data to the memory cell MC. Consequently, it is possible to suppress the injection of the hot carriers to the BOX layer 3a.

Also in the second embodiment, the potential VsbP (see FIG. 3) may have the same polarity as the potential VmlP (see FIG. 3) like in the first embodiment. At this time, the potential VsbP and the potential VmlP (see FIG. 3) are both negative potentials.

<Manufacturing Process of Semiconductor Device>

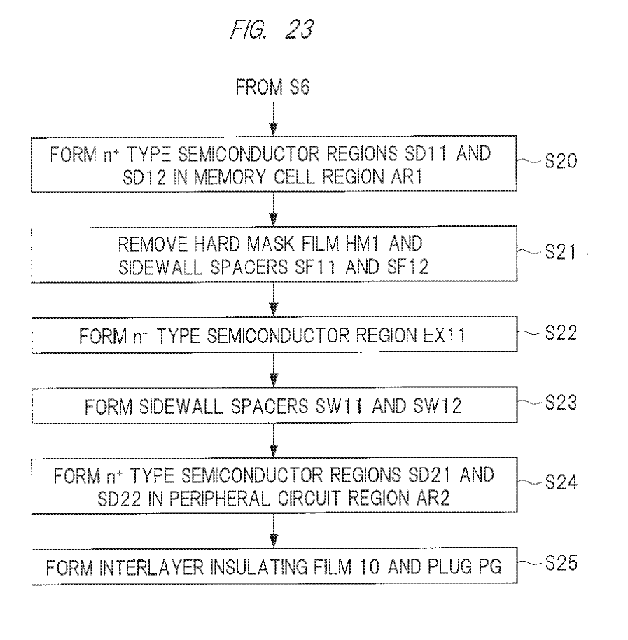

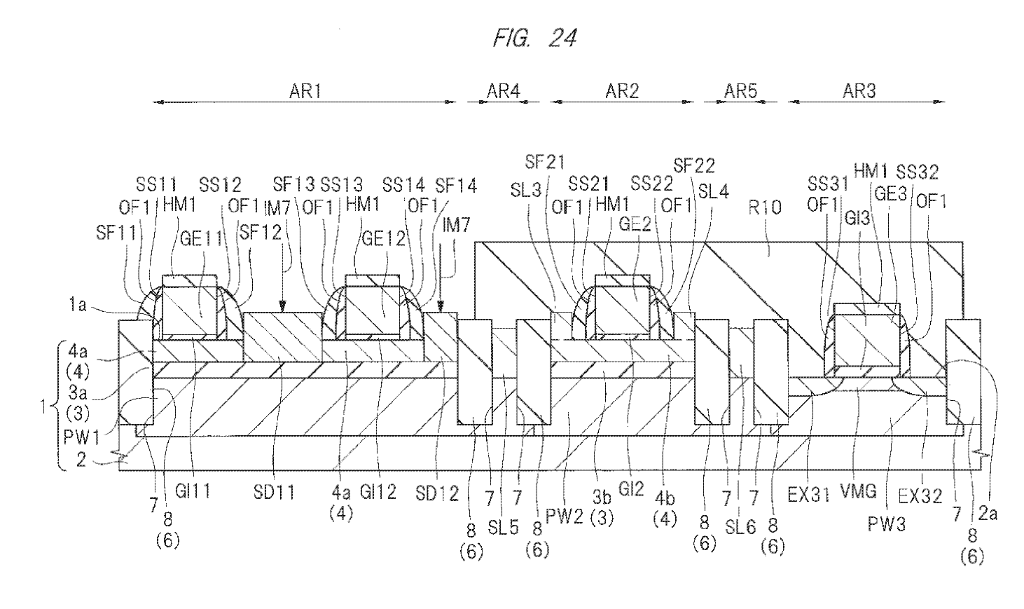

Next, a manufacturing process of the semiconductor device of the second embodiment will be described with reference to drawings. FIG. 23 is a manufacturing process flowchart illustrating a part of the manufacturing process of the semiconductor device of the second embodiment. FIG. 24 to FIG. 32 are cross-sectional views illustrating the principal part in the manufacturing process of the semiconductor device of the second embodiment.

In the manufacturing process of the semiconductor device of the second embodiment, after the silicon layer SL1 is formed through the process described with reference to FIG. 6 to FIG. 11 (steps S1 to S6 of FIG. 4) in the first embodiment, the n⁺ type semiconductor regions SD11 and SD12 are formed in the memory cell region AR1 as illustrated in FIG. 24 (step S20 of FIG. 23). This step S20 is the same step as the step S14 of FIG. 5 insofar as they are compared in terms of the process in the memory cell region AR1.

In this step S20, first, a photoresist film R10 is formed on the upper surface 1a of the SOI substrate 1 or the upper surface 2a of the support substrate 2 in the memory cell region AR1, the peripheral circuit regions AR2 and AR3 and the regions AR4 and AR5. Then, the photoresist film R10 formed on the upper surface 1a of the SOI substrate 1 is removed in the memory cell region AR1. At this time, in the peripheral circuit regions AR2 and AR3 and the regions AR4 and AR5, the photoresist film R10 is left without being removed.

Then, an n type impurity ion IM7 is implanted to the silicon layers SL1 and SL2 (see FIG. 11) and the SOI layer 4a with using the hard mask film HM1 formed on each of the gate electrodes GE11 and GE12 and the sidewall spacers SF11, SF12, SF13 and SF14 as masks.

Consequently, in the memory cell region AR1, the n⁺ type semiconductor region SD11 is formed in the silicon layer SL1 (see FIG. 11) and in a part of the SOI layer 4a located below the silicon layer SL1. In addition, in the memory cell region AR1, the n⁺ type semiconductor region SD12 is formed in the silicon layer SL2 (see FIG. 11) and in a part of the SOI layer 4a located below the silicon layer SL2. Thereafter, the photoresist film R10 is removed.

Namely, in the step S20, the n⁺ type semiconductor region SD11 is formed by ion-implanting an n type impurity to a part of the SOI layer 4a located on the side opposite to the gate electrode GE11 with the sidewall spacer SF11 interposed therebetween, and the n type impurity is not ion-implanted to the SOI layer 4b.

Meanwhile, since the hard mask film HM1 is formed on each of the gate electrodes GE11 and GE12 in the process of the step S20, the n type impurity ion IM7 is not implanted at a high concentration to the gate electrodes GE11 and GE12.

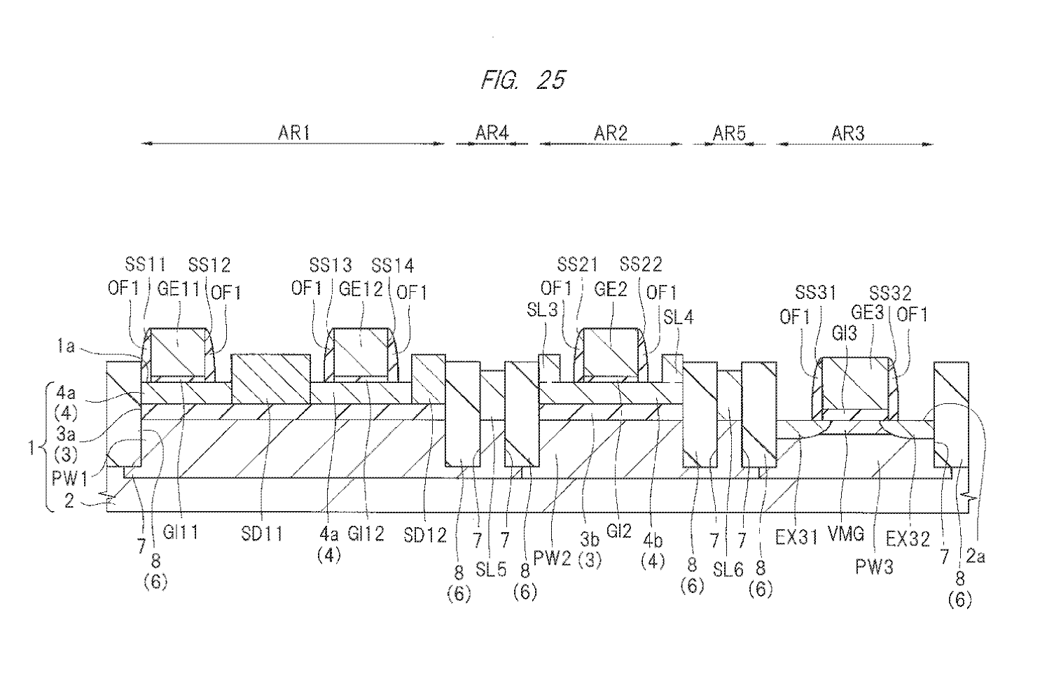

Next, as illustrated in FIG. 25, the hard mask film HM1 and the sidewall spacers SF11 and SF12 (see FIG. 24) are removed (step S21 of FIG. 23). In this step S21, the process similar to that described with reference to FIG. 12 in the first embodiment (step S11 of FIG. 5) is performed to remove the hard mask film HM1 and the sidewall spacers SF11, SF12, SF13 and SF14 (see FIG. 24).

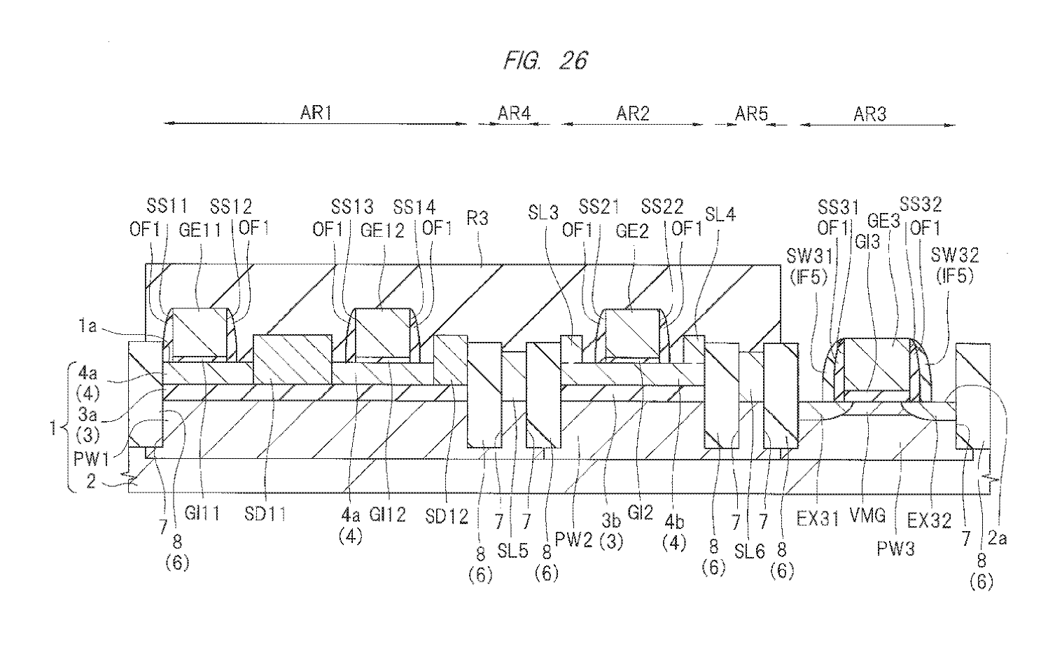

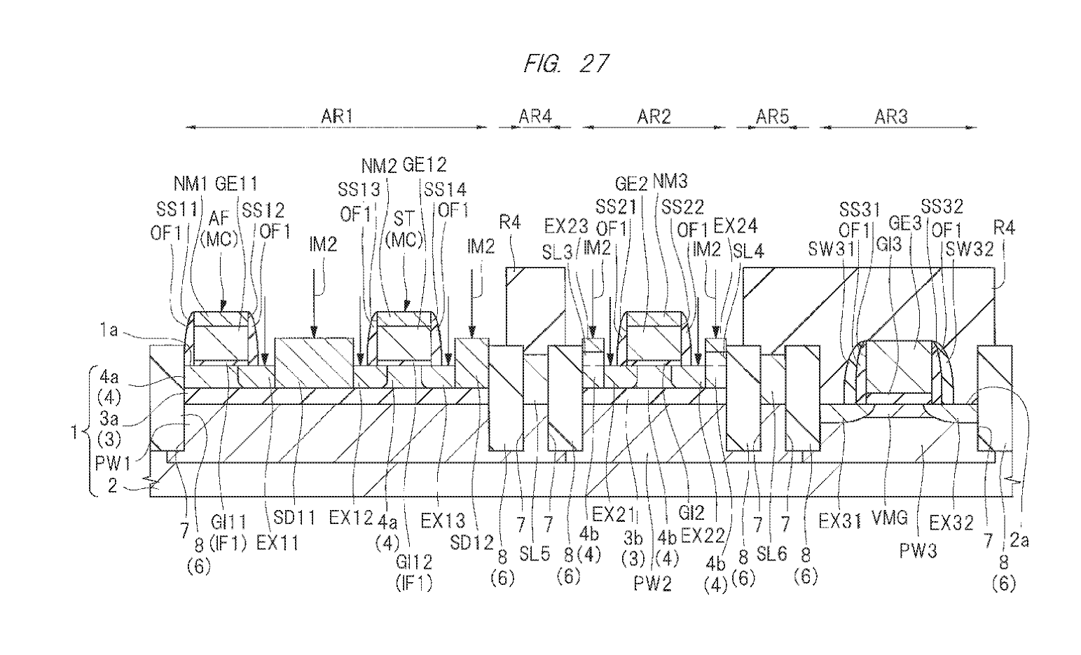

Next, as illustrated in FIG. 26 and FIG. 27, the n⁻ type semiconductor regions EX11 and EX12 are formed (step S22 of FIG. 23). In this step S22, the process similar to that described with reference to FIG. 13 and FIG. 14 in the first embodiment (step S12 of FIG. 5) is performed to form the n⁻ type semiconductor regions EX11, EX12 and EX13.

However, in the second embodiment, the n⁺ type semiconductor region SD11 has already been formed in the silicon layer SL1 (see FIG. 11), and thus the n⁻ type semiconductor region EX14 (see FIG. 14) is not formed. Also, the n⁺ type semiconductor region SD12 has already been formed in the silicon layer SL2 (see FIG. 11), and thus the n⁻ type semiconductor region EX15 (see FIG. 14) is not formed.

Namely, in the step S22, the n⁻ type semiconductor region EX11 is formed by ion-implanting an n⁻ type impurity to a part of the SOI layer 4a located between the gate electrode GE11 and the n⁺ type semiconductor region SD11. Also, the n⁻ type semiconductor region EX21 is formed by ion-implanting an n type impurity to a part of the SOI layer 4a located on one side (left side in FIG. 27) of the gate electrode GE2.

Note that, in the step S22, an n type impurity is ion-implanted at a low concentration to the gate electrodes GE11, GE12 and GE2, so that the n⁻ type semiconductor regions NM1, NM2 and NM3 are formed.

In the manner described above, the anti-fuse element AF including the gate electrode GE11, the n⁺ type semiconductor region SD11 and the n⁻ type semiconductor region EX11 is formed in the memory cell region AR1. In addition, the selection transistor ST including the gate electrode GE12, the n⁺ type semiconductor regions SD11 and SD12 and the n⁻ type semiconductor regions EX12 and EX13 is formed in the memory cell region AR1. The n type impurity concentration in each of the n⁺ type semiconductor regions SD11 and SD12 is higher than the n type impurity concentration in each of the n⁻ type semiconductor regions EX11, EX12 and EX13.

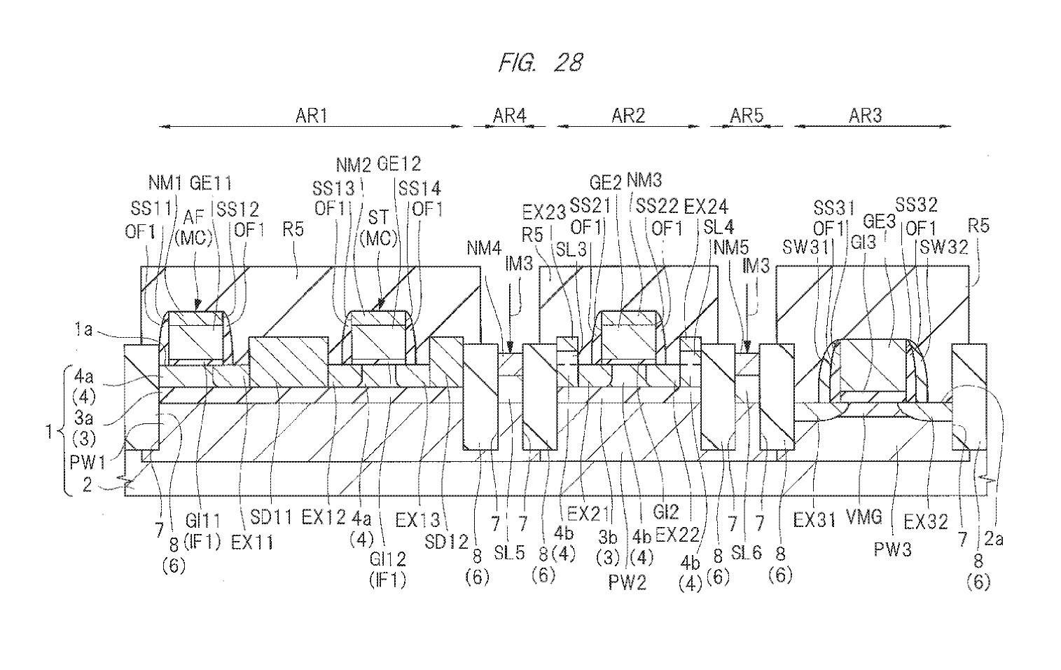

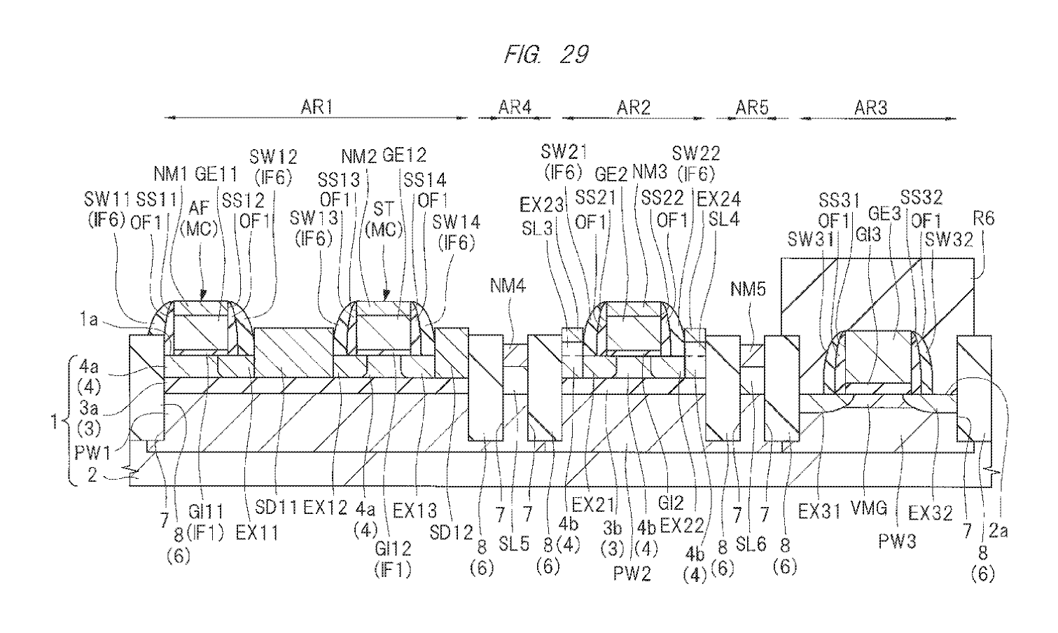

Next, the process similar to that described with reference to FIG. 15 and FIG. 16 in the first embodiment (step S13 of FIG. 5) is performed to form the sidewall spacers SW11 and SW12 as illustrated in FIG. 28 and FIG. 29 (step S23 of FIG. 23). In this step S23, the sidewall spacer SW12 is formed on the side surface SS12 of the gate electrode GE11, and the sidewall spacer SW21 is formed on the side surface SS21 on one side (left side in FIG. 29) of the gate electrode GE2.

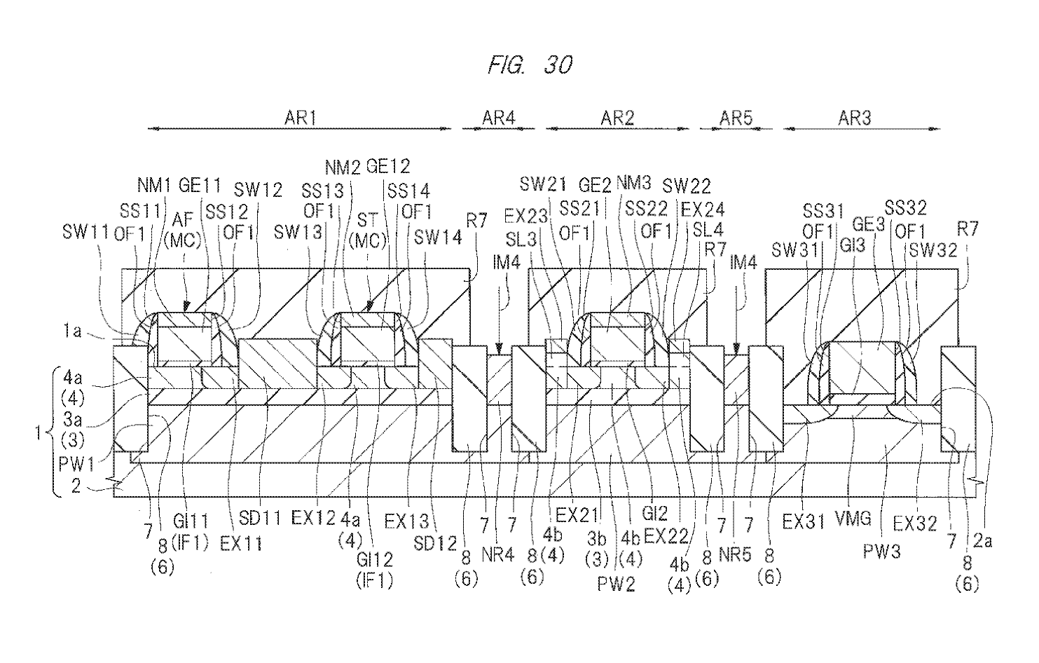

Next, as illustrated in FIG. 30 to FIG. 32, the n⁺ type semiconductor regions SD21 and SD22 are formed in the peripheral circuit region AR2 (step S24 of FIG. 23).

In this step S24, first, the process similar to that described with reference to FIG. 17 in the first embodiment is performed to ion-implant a p type impurity at a high concentration to the silicon layers SL5 and SL6 (see FIG. 29) in the regions AR4 and AR5 as illustrated in FIG. 30.

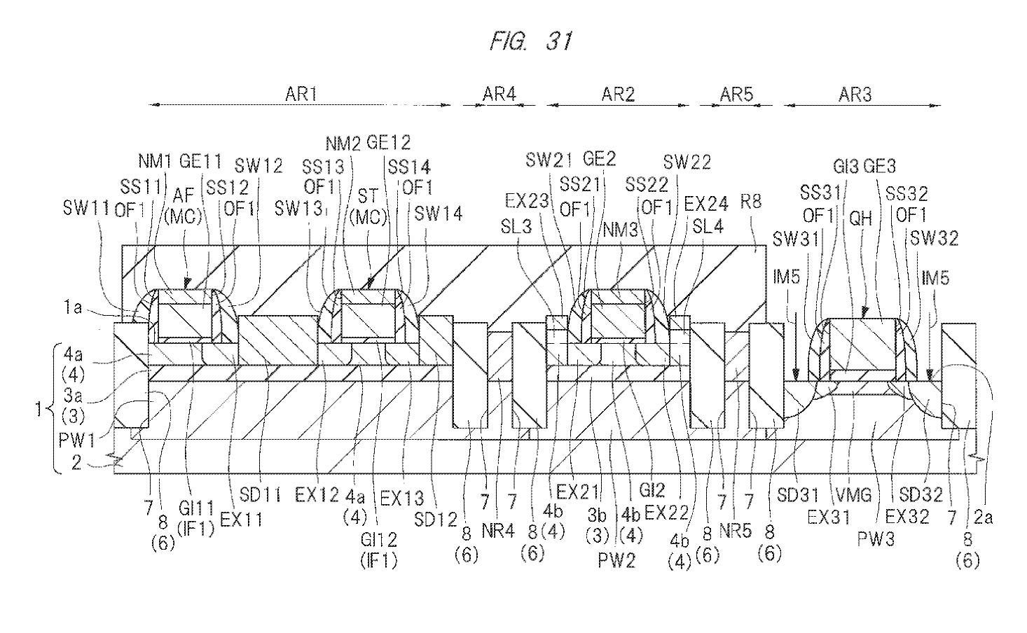

In this step S24, next, the process similar to that described with reference to FIG. 18 in the first embodiment is performed to form the n⁺ type semiconductor regions SD31 and SD32 as illustrated in FIG. 31.

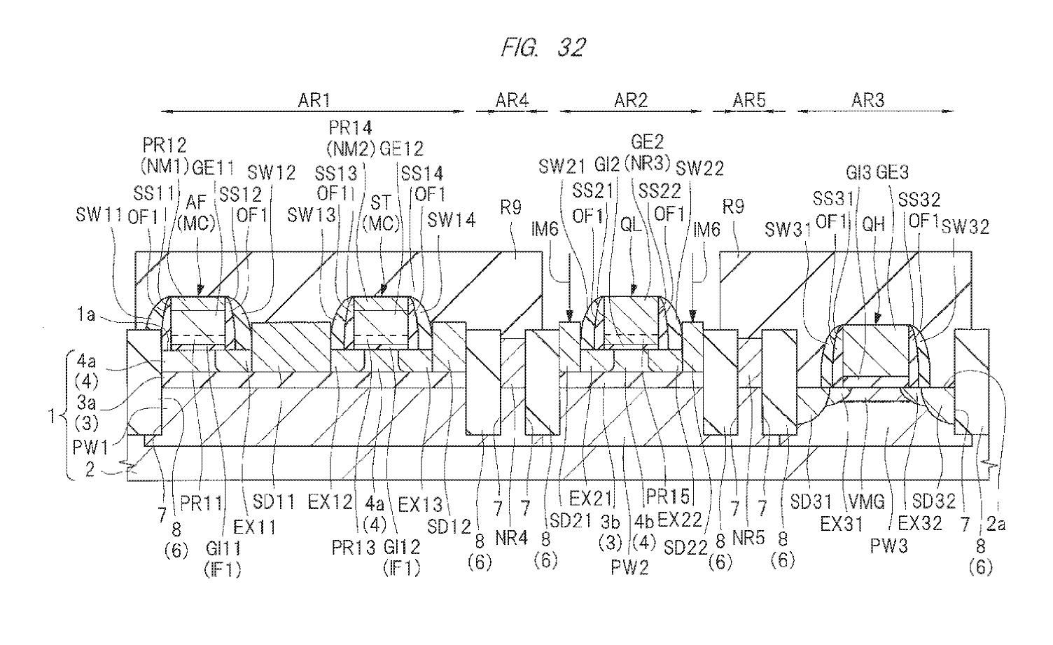

In this step S24, next, the n⁺ type semiconductor regions SD21 and SD22 are formed in the peripheral circuit region AR2 as illustrated in FIG. 32. This process of forming the n⁺ type semiconductor regions SD21 and SD22 is the same process as the process described with reference to FIG. 19 in the first embodiment (part of the step S14 of FIG. 5) insofar as they are compared in terms of the process in the peripheral circuit region AR2.

Specifically, in the memory cell region AR1, the peripheral circuit regions AR2 and AR3 and the regions AR4 and AR5, the photoresist film R9 is formed on the upper surface 1a of the SOI substrate 1 or the upper surface 2a of the support substrate 2. Then, in the peripheral circuit region AR2, the photoresist film R9 formed on the upper surface 1a of the SOI substrate 1 is removed. At this time, in the memory cell region AR1, the peripheral circuit region AR3 and the regions AR4 and AR5, the photoresist film R9 is left without being removed.

Then, the n type impurity ion IM6 is implanted to the silicon layers SL3 and SL4 (see FIG. 31) and the SOI layers 4a and 4b with using the gate electrode GE2 and the sidewall spacers SW21 and SW22 as masks.

Consequently, in the peripheral circuit region AR2, the n⁺ type semiconductor region SD21 is formed in the silicon layer SL3 (see FIG. 31) and in a part of the SOI layer 4b located below the silicon layer SL3. Also, the n⁺ type semiconductor region SD22 is formed in the silicon layer SL4 (see FIG. 31) and in a part of the SOI layer 4b located below the silicon layer SL4.

Namely, in the step S24, the n⁺ type semiconductor region SD21 is formed by ion-implanting an n type impurity to a part of the SOI layer 4b located on the side opposite to the gate electrode GE2 with the sidewall spacer SW21 interposed therebetween.

In addition, at this time, the n type impurity ion IM6 is implanted at a high concentration also to the gate electrode GE2, and the n⁺ type semiconductor region NR3 is formed. In this case, the n type impurity concentration in the part PR11 of the gate electrode GE11 to which an n type impurity has been ion-implanted in the step S22, the part PR11 being in contact with the gate insulating film GI11, is lower than the n type impurity concentration in the part PR15 of the gate electrode GE2 to which an n type impurity has been ion-implanted in the step S24, the part PR15 being in contact with the gate insulating film GI12. Thereafter, the photoresist film R9 is removed.

Note that, in the step S24, an n type impurity is ion-implanted to the gate electrode GE2, but the n type impurity is not ion-implanted to the gate electrodes GE11 and GE12.

In the manner described above, the MISFET QL including the gate electrode GE2, the n⁺ type semiconductor regions SD21 and SD22 and the n⁻ type semiconductor regions EX21 and EX22 is formed in the peripheral circuit region AR2. The n type impurity concentration in each of the n⁺ type semiconductor regions SD21 and SD22 is higher than the n type impurity concentration in each of the n⁻ type semiconductor regions EX21 and EX22.

Thereafter, the process similar to that described with reference to FIG. 1 in the first embodiment (step S15 of FIG. 5) is performed to form the semiconductor device of the second embodiment as illustrated in FIG. 22 (step S25 of FIG. 23).

<Gate Withstand Voltage>

Next, the gate withstand voltage of the gate electrode GE11 of the anti-fuse element AF in the second embodiment will be described while being compared with a gate withstand voltage of a gate electrode GE11 of an anti-fuse element AF in a comparative example 2.

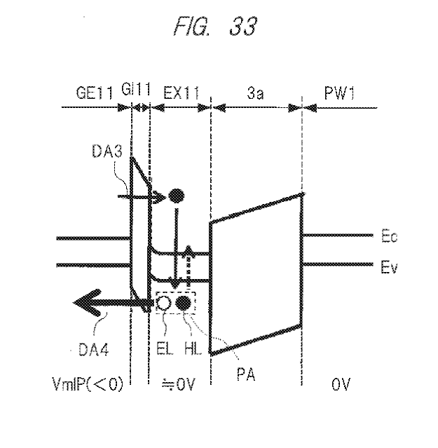

FIG. 33 is a band diagram illustrating an energy distribution in the write operation of the semiconductor device of the comparative example 2. In FIG. 33, an energy at an upper end of the valence band is represented as an energy Ev and an energy at a lower end of the conduction band is represented as an energy Ec for each layer.

As described in the first embodiment above, in the semiconductor device of the comparative example 1, the positive potential VmlP is applied to the gate electrode GE11 in the write operation. In such a case, in the semiconductor device of the comparative example 1 in which the potential having a polarity opposite to that of the potential applied to the gate electrode GE11 or the potential of 0 V is applied to the p type well region PW1 in the write operation, there is a fear that the hot holes as hot carriers generated in the write operation may be injected to the BOX layer 3a.

Meanwhile, the structure of the semiconductor device of the comparative example 2 is the same as that of the semiconductor device of the first embodiment, but the negative potential VmlP is applied to the gate electrode GE11 in the write operation in the semiconductor device of the comparative example 2. In such a case, the hot holes as hot carriers generated in the write operation are less likely to be injected to the BOX layer 3a.

However, in the semiconductor device of the comparative example 2, an inversion layer is not formed in a part of the n⁻ type semiconductor region EX11 which is in contact with the gate insulating film GI11 in the write operation, and an accumulation layer in which carriers are accumulated is formed. In addition, electrons EL in the gate electrode GE11 are injected from the gate electrode GE11 to the n⁻ type semiconductor region EX11 by the FN tunneling as indicated by an arrow DA3.

Meanwhile, hot carriers are generated in the n⁻ type semiconductor region EX11 when the dielectric breakdown of the gate insulating film GI11 is caused in the anti-fuse element AF for the write operation. When the anti-fuse element AF in the semiconductor device of the comparative example 2 has the structure similar to that of an n channel type MISFET and a negative potential is applied to the gate electrode GE11, hot holes made of holes HL of the pairs PA of the electrons EL and the holes HL are generated as hot carriers in the n⁻ type semiconductor region EX11. Then, the hot holes generated in the n⁻ type semiconductor region EX11 are injected to the gate electrode GE11, and are accelerated in the gate electrode GE11 toward the side opposite to the gate insulating film GI11 as indicated by an arrow DA4.

In such a case, the voltage which is the potential difference of the gate electrode GE11 with respect to the n⁺ type semiconductor region SD11 at the time of the dielectric breakdown of the gate insulating film GI11, that is, the gate withstand voltage increases by the voltage corresponding to the band gap in the SOI layer 4a. When the SOI layer 4a is made of single crystal silicon, the gate withstand voltage increases by the voltage of 1.1 V corresponding to the band gap of silicon.

The problem of the increase of the gate withstand voltage described above is not resolved when the conductivity type of the semiconductor film included in the gate electrode GE1 of the anti-fuse element AF is the same as the conductivity type of the n⁺ type semiconductor region SD11 serving as the source/drain region of the anti-fuse element AF. In addition, the semiconductor device of the comparative example 2 is manufactured through the same manufacturing process as that of the semiconductor device of the first embodiment. However, as described with reference to FIG. 19 in the first embodiment above, an n type impurity is introduced at a high concentration to the conductive film CF1 as the semiconductor film included in the gate electrode GE11 when forming the n⁺ type semiconductor region SD11, and the conductivity type of the semiconductor film included in the gate electrode GE11 becomes an n type. Therefore, in the semiconductor device of the comparative example 2, it is not possible to resolve the problem of the increase of the gate withstand voltage by the voltage corresponding to the band gap in the SOI layer 4a.

In the manufacturing process of the semiconductor device of the comparative example 2, for example, the gate electrode GE11 is formed in the state where the hard mask film. HM1 is formed on the gate electrode GE11 through the process similar to that described with reference to FIG. 8 in the first embodiment, and then the hard mask film HM1 is removed by performing the process similar to that described with reference to FIG. 12. Next, in the state where the upper surface of the gate electrode GE11 is exposed, an n type impurity is ion-implanted at a low concentration to form the n⁻ type semiconductor region EX11, and an n type impurity is ion-implanted at a high concentration to form the n⁺ type semiconductor region SD11.

In the manufacturing process of the semiconductor device of the comparative example 2 described above, when an n type impurity is ion-implanted at a high concentration to form the n⁺ type semiconductor region SD11, the n type impurity is ion-implanted at a high concentration also to the semiconductor film included in the gate electrode GE11, and the gate electrode GE11 made of an n type semiconductor film is formed. Accordingly, it is not possible to resolve the problem of the increase of the gate withstand voltage by the voltage corresponding to the band gap in the SOI layer 4a.

### Main Characteristics and Effect of Present Embodiment

On the other hand, in the semiconductor device of the second embodiment, the gate electrode GE11 is made of a p type semiconductor film in the memory cell region AR1. Alternatively, in the semiconductor device of the second embodiment, the n type impurity concentration of the part PR11 of the gate electrode GE11 in the memory cell region AR1, the part PR11 being in contact with the gate insulating film GI11, is lower than the n type impurity concentration of the part PR15 of the gate electrode GE2 in the peripheral circuit region AR2, the part PR15 being in contact with the gate insulating film GI2.

Consequently, even when the potential of the polarity which forms an accumulation layer in the channel region in the SOI layer 4a is applied to the gate electrode GE11 of the anti-fuse element AF in the write operation, the increase of the gate withstand voltage of the gate insulating film GI11 by the voltage corresponding to the band gap in the SOI layer 4a can be prevented or suppressed. Therefore, the increase of the gate withstand voltage of the gate insulating film GI11 can be prevented or suppressed, while preventing or suppressing the hot holes as hot carriers generated in the write operation from being injected to the BOX layer 3a.

In addition, in the manufacturing process of the semiconductor device of the second embodiment, the gate electrodes GE11 and GE2 are formed in the memory cell region AR1 and the peripheral circuit region AR2 and the hard mask film HM1 is formed on the gate electrode GE11, and then an n type impurity is ion-implanted at a high concentration to form the n⁺ type semiconductor region SD11 in the memory cell region AR1. Next, after the hard mask film HM1 is removed and an n type impurity is ion-implanted at a low concentration to form the n⁻ type semiconductor regions EX11 and EX21 in the memory cell region AR1 and the peripheral circuit region AR2, an n type impurity is ion-implanted at a high concentration to form the n⁺ type semiconductor region SD21 in the peripheral circuit region AR2.

Consequently, the n type impurity is introduced at a high concentration to the gate electrode GE2, but is not introduced to the gate electrode GE11. Therefore, the gate electrode GE11 can be made of a p type semiconductor film, or the n type impurity concentration of the part PR11 of the gate electrode GE11, which is in contact with the gate insulating film GI11, can be made lower than the n type impurity concentration of the part PR15 of the gate electrode GE2, which is in contact with the gate insulating film GI2. Consequently, it is possible to prevent or suppress the increase of the gate withstand voltage by the voltage corresponding to the band gap in the SOI layer 4a.

The dependency of the capacitance C between the gate electrode GE11 and the channel region on the gate voltage V, that is, the C-V characteristics was measured with respect to the anti-fuse element AF in each of the semiconductor device of the second embodiment and the semiconductor device of the comparative example 2.

As a result, in the semiconductor device of the second embodiment, the falling voltage of the capacitance C when the accumulation layer was formed and the rising voltage of the capacitance C when the inversion layer was formed were both moved to the positive polarity side by the voltage approximately corresponding to the band gap in comparison with the semiconductor device of the comparative example 2. Also from this fact, it was apparent that the conductivity type of the semiconductor film included in the gate electrode GE11 in the second embodiment was a p type or the conductivity type thereof was made close to a p type even though it was an n type compared with the conductivity type of the semiconductor film included in the gate electrode GE11 in the comparative example 2.

### Third Embodiment

In the third embodiment, an example in which a length of a part of the n⁻ type semiconductor region EX11 of the anti-fuse element AF in a gate length direction, the part overlapping with the gate electrode GE11, is longer than a length of a part of the n⁻ type semiconductor region EX21 of the MISFET QL in a gate length direction, the part overlapping with the gate electrode GE2, will be described.

Hereinafter, an example in which a length of a part of the n⁻ type semiconductor region EX11 in a gate length direction, the part overlapping with the gate electrode GE11, is made long in the semiconductor device of the second embodiment will be described as the semiconductor device of the third embodiment. Alternatively, an example in which a length of a part of the n⁻ type semiconductor region EX11 in a gate length direction, the part overlapping with the gate electrode GE11, is made long in the semiconductor device of the first embodiment may also be described as the semiconductor device of the third embodiment.

<Structure of Semiconductor Device>

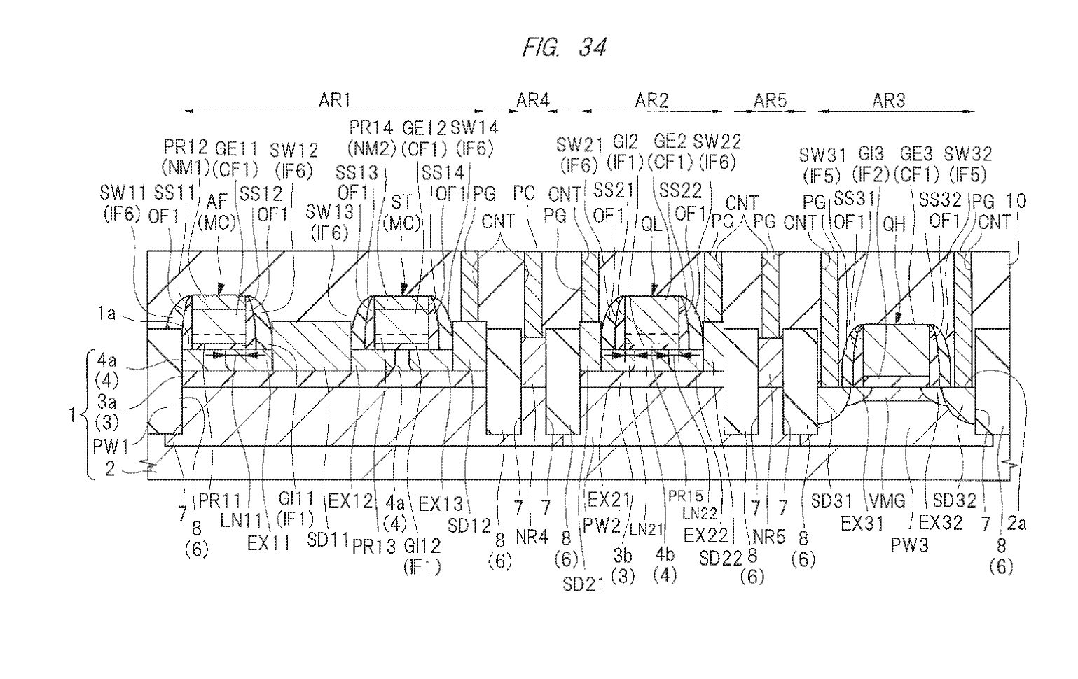

First, a structure of the semiconductor device of the third embodiment will be described with reference to drawings. FIG. 34 is a cross-sectional view illustrating the principal part of the semiconductor device of the third embodiment.

The structure of the semiconductor device of the third embodiment is the same as that of the semiconductor device of the second embodiment except that a length of a part of the n⁻ type semiconductor region EX11 in a gate length direction, the part overlapping with the gate electrode GE11, is made longer than a length of a part of the n⁻ type semiconductor region EX21 in a gate length direction, the part overlapping with the gate electrode GE2. Therefore, the difference from the structure of the semiconductor device of the second embodiment will be mainly described below.

Also in the third embodiment, the n⁻ type semiconductor region EX11 overlaps with a part of the gate electrode GE11 on a side close to the side surface SS12 in the gate length direction when seen in a plan view like in the first embodiment. In addition, also in the third embodiment, the n⁻ type semiconductor region EX12 overlaps with a part of the gate electrode GE12 on aside close to the side surface SS13 in the gate length direction when seen in a plan view, and the n⁻ type semiconductor region EX13 overlaps with a part of the gate electrode GE12 on a side close to the side surface SS14 in the gate length direction when seen in a plan view like in the first embodiment. Meanwhile, also in the third embodiment, the n⁻ type semiconductor region EX21 overlaps with a part of the gate electrode GE2 on a side close to the side surface SS21 in the gate length direction when seen in a plan view, and the n⁻ type semiconductor region EX22 overlaps with a part of the gate electrode GE2 on a side close to the side surface SS22 in the gate length direction when seen in a plan view like in the first embodiment.

Also, a length LN11 of the part of the n⁻ type semiconductor region EX11 in the gate length direction of the gate electrode GE11, the part overlapping with the gate electrode GE11 when seen in a plan view, is longer than a length LN21 of the part of the n⁻ type semiconductor region EX21 in the gate length direction of the gate electrode GE2, the part overlapping with the gate electrode GE2 when seen in a plan view. In addition, the length LN11 is longer than a length LN22 of the part of the n⁻ type semiconductor region EX22 in the gate length direction of the gate electrode GE2, the part overlapping with the gate electrode GE2 when seen in a plan view.

Consequently, it is possible to reduce the gate withstand voltage of the gate electrode GE11 in the memory cell region AR1, and the absolute value of the potential applied to the gate electrode GE11 in the write operation of writing the data to the memory cell MC can be further reduced in comparison with the second embodiment. Meanwhile, the increase of the off-leakage current in the peripheral circuit region AR2 can be prevented or suppressed.

Note that a length of a part of the n⁻ type semiconductor region EX12 in the gate length direction of the gate electrode GE12, the part overlapping with the gate electrode GE12 when seen in a plan view, may be longer than the length LN21 or the length LN22. Also, a length of a part of the n⁻ type semiconductor region EX13 in the gate length direction of the gate electrode GE12, the part overlapping with the gate electrode GE12 when seen in a plan view, may be longer than the length LN21 or the length LN22.

<Operation of Memory Cell>

Since the operation of the memory cell in the semiconductor device of the third embodiment is the same as that of the memory cell in the semiconductor device of the second embodiment, the description thereof is omitted.

In addition, in the third embodiment, a negative potential is applied to the gate electrode GE11 in the write operation of writing data to the memory cell MC like in the second embodiment, and it is thus possible to prevent or suppress the degradation of the insulation properties of the BOX layer 3a due to the injection of the hot holes as hot carriers to the BOX layer 3a.

<Manufacturing Process of Semiconductor Device>

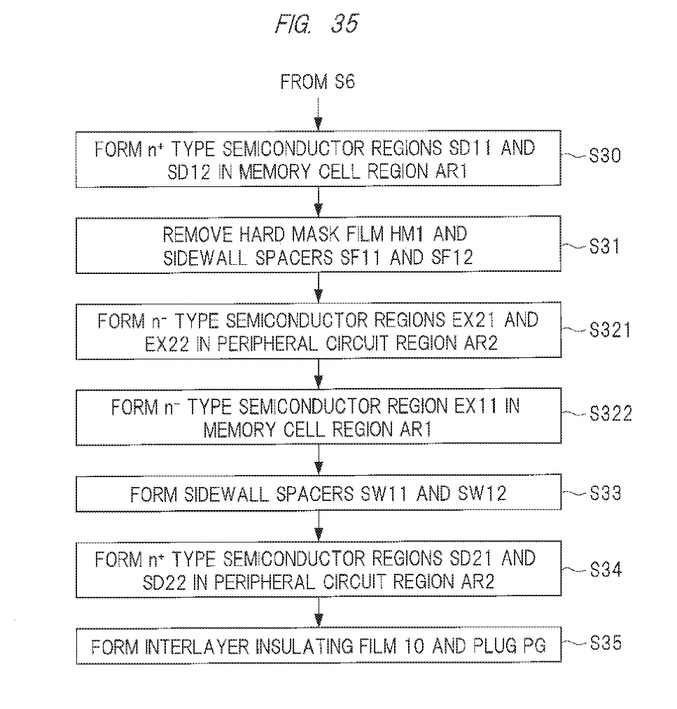

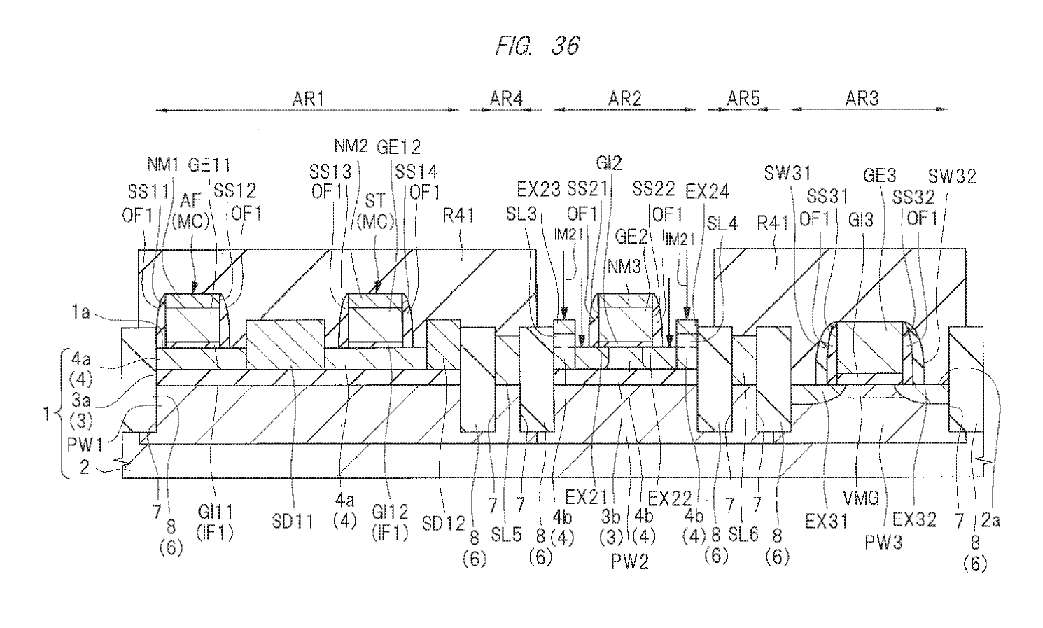

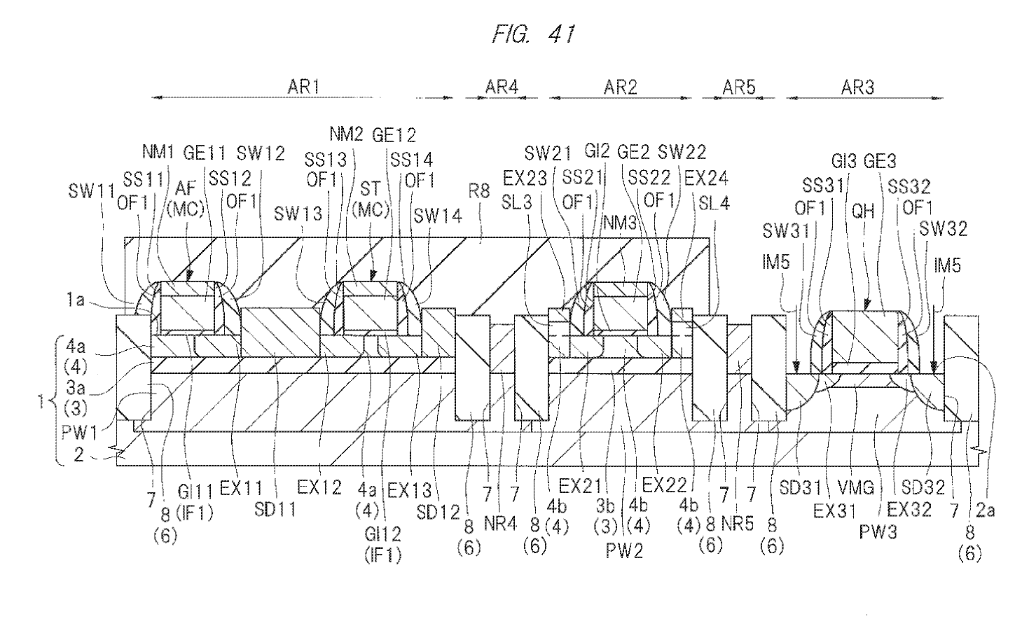

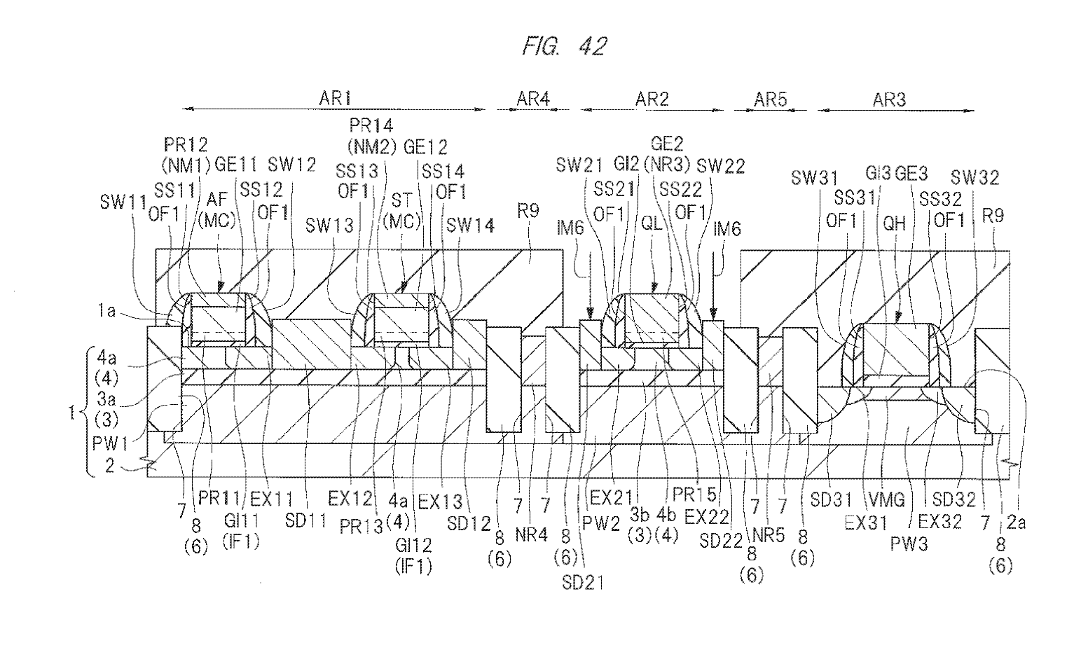

Next, a manufacturing process of the semiconductor device of the third embodiment will be described with reference to drawings. FIG. 35 is a manufacturing process flowchart illustrating a part of the manufacturing process of the semiconductor device of the third embodiment. FIG. 36 to FIG. 42 are cross-sectional views illustrating the principal part in the manufacturing process of the semiconductor device of the third embodiment.

In the manufacturing process of the semiconductor device of the third embodiment, after the steps S1 to S6 of FIG. 4 are performed, the process similar to the steps S20 and S21 of FIG. 23 is performed (steps S30 and S31 of FIG. 35).

Next, as illustrated in FIG. 36, the n⁻ type semiconductor regions EX21 and EX22 are formed in the peripheral circuit region AR2 (step S321 of FIG. 35).

Specifically, in the memory cell region AR1, the peripheral circuit regions AR2 and AR3 and the regions AR4 and AR5, a photoresist film R41 is formed on the upper surface 1a of the SOI substrate 1 or the upper surface 2a of the support substrate 2. Then, in the peripheral circuit region AR2, the photoresist film R41 formed on the upper surface 1a of the SOI substrate 1 is removed. At this time, in the memory cell region AR1, the peripheral circuit region AR3 and the regions AR4 and AR5, the photoresist film R41 is left without being removed.

Then, an n type impurity ion IM21 is implanted to the silicon layers SL3 and SL4 and the SOI layer 4b with using the photoresist film R41 and the gate electrode GE2 as masks.

Consequently, the n type semiconductor region EX21 is formed in a part of the SOI layer 4b located between the gate electrode GE2 and the silicon layer SL3 in the peripheral circuit region AR2. Also, the n⁻ type semiconductor region EX22 is formed in a part of the SOI layer 4b located between the gate electrode GE2 and the silicon layer SL4 in the peripheral circuit region AR2. Namely, the n⁻ type semiconductor region EX21 is formed by ion-implanting an n type impurity to a part of the SOI layer 4b located on one side (left side in FIG. 36) of the gate electrode GE2. The n⁻ type semiconductor region EX21 overlaps with a part of the gate electrode GE2 on one side (left side in FIG. 36) in the gate length direction when seen in a plan view.

Note that the n⁻ type semiconductor region EX23 is formed also in an upper layer part of the silicon layer SL3 and the n⁻ type semiconductor region EX24 is formed also in an upper layer part of the silicon layer SL4.

At this time, the n⁻ type impurity ion IM21 is implanted at a low concentration also to the gate electrode GE2. Consequently, the n⁻ type semiconductor region NM3 is formed in the upper layer part of the gate electrode GE2. Thereafter, the photoresist film R41 is removed.

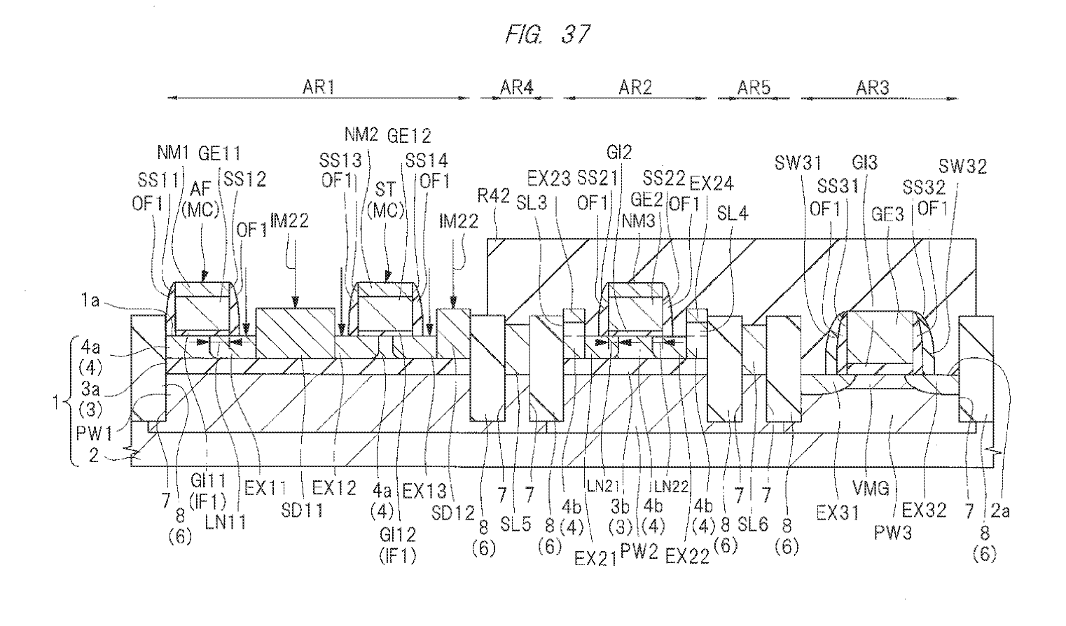

Next, as illustrated in FIG. 37, the n⁻ type semiconductor region EX11 is formed in the memory cell region AR1 (step S322 of FIG. 35).

Specifically, in the memory cell region AR1, the peripheral circuit regions AR2 and AR3 and the regions AR4 and AR5, a photoresist film R42 is formed on the upper surface 1a of the SOI substrate 1 or the upper surface 2a of the support substrate 2. Then, the photoresist film R42 formed on the upper surface 1a of the SOI substrate 1 is removed in the memory cell region AR1. At this time, in the peripheral circuit regions AR2 and AR3 and the regions AR4 and AR5, the photoresist film. R42 is left without being removed.

Then, an n type impurity ion IM22 is implanted to the SOI layer 4a with using the photoresist film R42 and the gate electrodes GE11 and GE12 as masks.

Consequently, in the memory cell region AR1, the n⁻ type semiconductor region EX11 is formed in apart of the SOI layer 4a located between the gate electrode GE11 and the n⁺ type semiconductor region SD11. Namely, the n⁻ type semiconductor region EX11 is formed by ion-implanting an n type impurity to a part of the SOI layer 4a located between the gate electrode GE11 and the n⁺ type semiconductor region SD11. The n⁻ type semiconductor region EX11 overlaps with a part of the gate electrode GE11 on the other side (right side in FIG. 37) in the gate length direction when seen in a plan view.

In addition, in the memory cell region AR1, the n⁻ type semiconductor region EX12 is formed in a part of the SOI layer 4a located between the gate electrode GE12 and the n⁺ type semiconductor region SD11, and the n⁻ type semiconductor region EX13 is formed in a part of the SOI layer 4a located between the gate electrode GE12 and the n⁺ type semiconductor region SD12.

At this time, the n type impurity ion IM22 is implanted at a low concentration also to the gate electrodes GE11 and GE12. Consequently, the n type semiconductor region NM1 is formed in the upper layer part of the gate electrode GE11, and the n⁻ type semiconductor region NM2 is formed in the upper layer part of the gate electrode GE12. Thereafter, the photoresist film R42 is removed.

In the manner described above, the anti-fuse element AF including the gate electrode GE11, the n⁺ type semiconductor region SD11 and the n⁻ type semiconductor region EX11 is formed in the memory cell region AR1. In addition, the selection transistor ST including the gate electrode GE12, the n⁺ type semiconductor regions SD11 and SD12 and the n⁻ type semiconductor regions EX12 and EX13 is formed in the memory cell region AR1.

In the third embodiment, the condition for the introduction of the impurity ion IM21 and the condition for the introduction of the impurity ion IM22 are made different from each other with the inclusion of the condition for the activation annealing. Consequently, the length LN11 of the part of the n⁻ type semiconductor region EX11 in the gate length direction of the gate electrode GE11, the part overlapping with the gate electrode GE11 when seen in a plan view, can be made longer than the length LN21 of the part of the n⁻ type semiconductor region EX21 in the gate length direction of the gate electrode GE2, the part overlapping with the gate electrode GE2 when seen in a plan view. In addition, the length LN11 can be made longer than the length LN22 of the part of the n⁻ type semiconductor region EX22 in the gate length direction of the gate electrode GE2, the part overlapping with the gate electrode GE2 when seen in a plan view.

Note that it is also possible to exchange the order of the step S321 and the step S322, and the step S322 may be performed before the step S321.

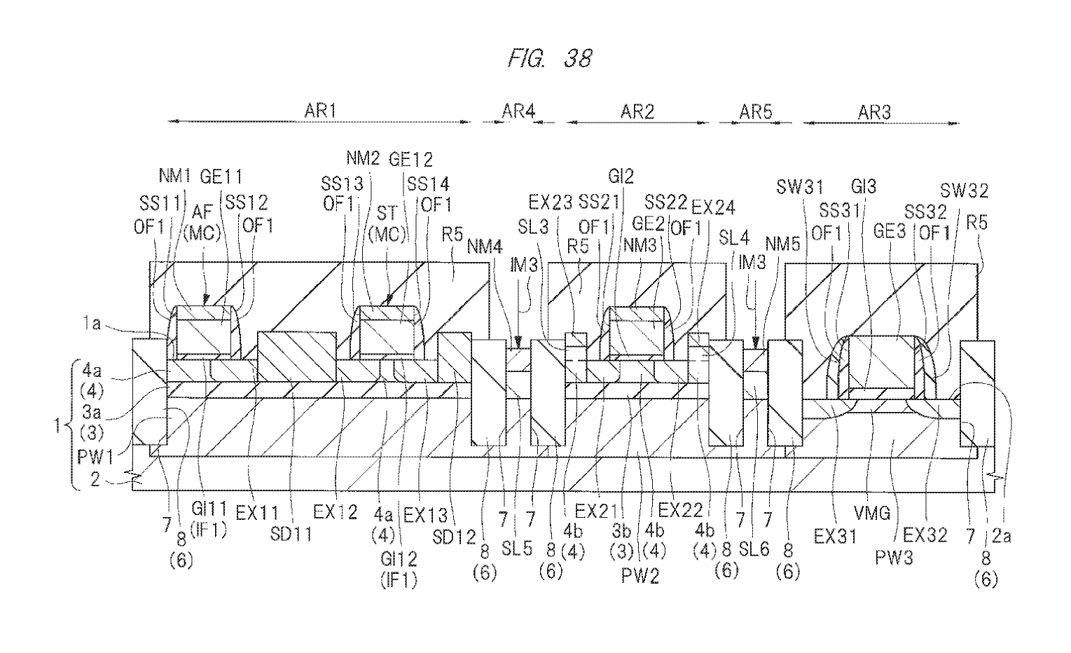

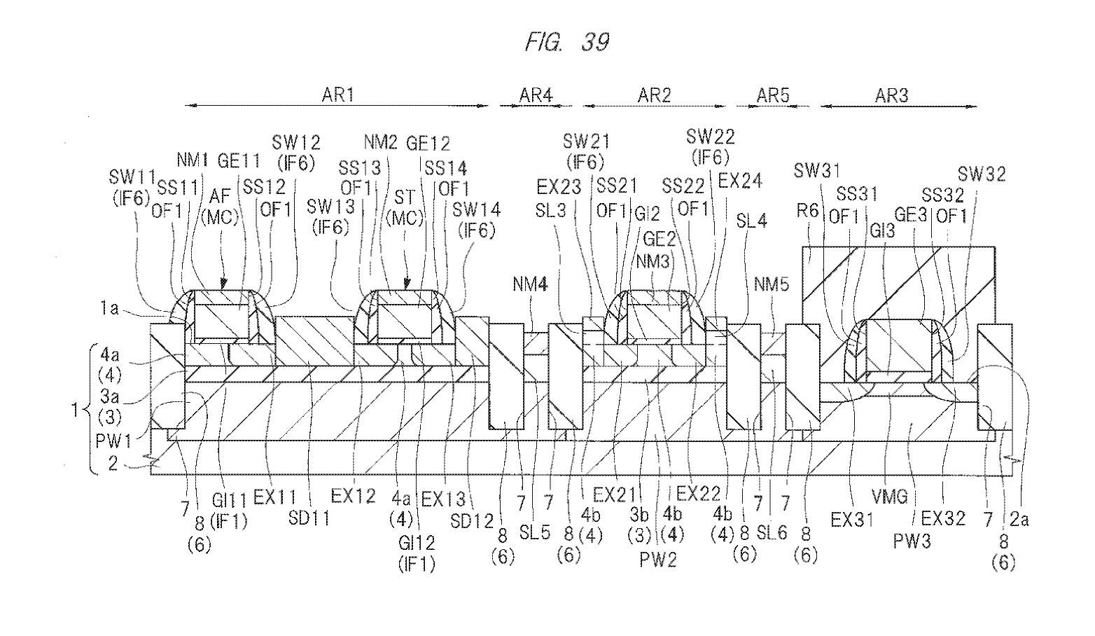

Next, the process similar to that described with reference to FIG. 28 and FIG. 29 in the second embodiment (step S23 of FIG. 23) is performed to form the sidewall spacers SW11 and SW12 as illustrated in FIG. 38 and FIG. 39 (step S33 of FIG. 35).

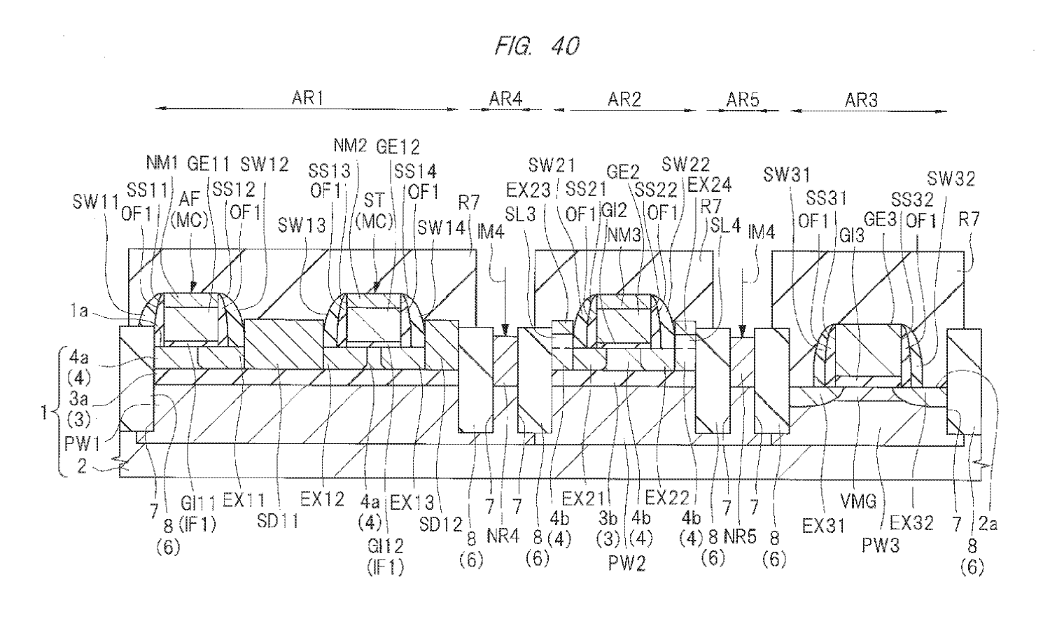

Next, the process similar to that described with reference to FIG. 30 to FIG. 32 in the second embodiment (step S24 of FIG. 23) is performed to form the n⁺ type semiconductor regions SD21 and SD22 in the peripheral circuit region AR2 as illustrated in FIG. 40 to FIG. 42 (step S34 of FIG. 35).

In the manner described above, the MISFET QL including the gate electrode GE2, the n⁺ type semiconductor regions SD21 and SD22 and the n⁻ type semiconductor regions EX21 and EX22 is formed in the peripheral circuit region AR2.

Thereafter, the process similar to that described with reference to FIG. 1 in the first embodiment (step S15 of FIG. 5) is performed to form the semiconductor device of the third embodiment as illustrated in FIG. 34 (step S35 of FIG. 35).

<Overlap Length between Extension Region and Gate Electrode>

Next, the length of a part of the extension region, which overlaps with the gate electrode, in a gate length direction, that is, an overlap length between the extension region and the gate electrode will be described while comparing the third embodiment with the comparative example 1, the comparative example 2 and the first and second embodiments.

In the semiconductor device of the comparative example 1 in which the positive potential VmlP is applied to the gate electrode GE11 and the potential having a polarity opposite to that of the potential applied to the gate electrode GE11 or the potential of 0 V is applied to the p type well region PW1 in the write operation, there is a fear that the hot holes as hot carriers generated in the write operation may be injected to the BOX layer 3a.

Meanwhile, in the semiconductor device of the comparative example 2, the negative potential VmlP is applied to the gate electrode GE11 in the write operation. In such a case, the hot holes as hot carriers generated in the write operation are less likely to be injected to the BOX layer 3a, but there is a problem that the gate withstand voltage increases in comparison with the comparative example 1.

In the semiconductor device of the first embodiment in which the positive potential is applied to the gate electrode GE11, the threshold voltage is set high in order to reduce the power consumption and off-leakage current as much as possible. Therefore, the gate induced drain leakage (GIDL) serves as a parameter for controlling the off-leakage current. The reduction of the overlap length between the n⁻ type semiconductor region EX11 and the gate electrode GE11 is effective for the reduction of the GIDL.

However, in the semiconductor device of the comparative example 2 in which the negative potential is applied to the gate electrode, the part of the gate insulating film GI11 in the anti-fuse element AF, in which the current is caused to flow by the FN tunneling, is limited to the part of the n⁻ type semiconductor region EX11, which overlaps with the gate electrode GE11. Therefore, in the semiconductor device of the comparative example 2, the current which is cause to flow by the FN tunneling decreases by the reduction in the area of the part of the n⁻ type semiconductor region EX11, which overlaps with the gate electrode GE11, in comparison with the semiconductor device of the first embodiment. Namely, since the current which is caused to flow by the FN tunneling decreases, the voltage which is the potential difference of the gate electrode GE11 with respect to the n⁺ type semiconductor region SD11 at the time of the dielectric breakdown of the gate insulating film GI11, that is, the gate withstand voltage increases.

Note that, in the anti-fuse element AF constituting the memory cell MC, the off-leakage current is not an important parameter in performing the write operation and the read operation.

Here, an example in which the overlap length between the n⁻ type semiconductor region EX11 as an extension region and the gate electrode GE11 is reduced in comparison with the semiconductor device of the second embodiment is provided as a comparative example 3. Then, the dependency of the current I flowing between the gate electrode GE11 and the n⁺ type semiconductor region SD11 in the semiconductor device of the second embodiment on the drain voltage V, that is, the I-V characteristics was measured. Namely, in the semiconductor device of the comparative example 3, a length of a part of the n⁻ type semiconductor region EX11 in a gate length direction in the memory cell region AR1, the part overlapping with the gate electrode GE11 when seen in a plan view, is shorter than a length of a part of the n⁻ type semiconductor region EX21 in a gate length direction in the peripheral circuit region AR2, the part overlapping with the gate electrode GE2 when seen in a plan view.

As a result, the gate withstand voltage in the comparative example 3 was higher than the gate withstand voltage in the second embodiment. Namely, this indicates that the gate withstand voltage increases in the semiconductor device of the comparative example 3 in which the overlap length between the n⁻ type semiconductor region EX11 as the extension region and the gate electrode GE11 is longer than that of the semiconductor device of the second embodiment.

### Main Characteristics and Effect of Present Embodiment

On the other hand, in the semiconductor device of the third embodiment, the length of the part RP11 of the n⁻ type semiconductor region EX11 in the gate length direction, the part PR 11 overlapping with the gate electrode GE11 when seen in a plan view, is longer than the length of the part PR15 of the n⁻ type semiconductor device EX21 in the gate length direction, the part PR15 overlapping with the gate electrode GE2 when seen in a plan view.

Consequently, in the memory cell region AR1, the overlap length between the n⁻ type semiconductor region EX11 and the gate electrode GE11 can be made relatively longer, and the ratio of the part in which the current is caused to flow by the FN tunneling increases in the gate insulating film GI11 of the anti-fuse element AF, so that the current caused to flow by the FN tunneling increases. Therefore, it is possible to prevent or suppress the increase of the gate withstand voltage of the gate insulating film GI11 while preventing or suppressing the injection of the hot holes as the hot carriers generated in the write operation to the BOX layer 3a.

Meanwhile, in the peripheral circuit region AR2, the overlap length between the n⁻ type semiconductor region EX21 and the gate electrode GE2 can be made relatively shorter, and the off-leakage current of the MISFET QL can be reduced.

Also, in the manufacturing process of the semiconductor device of the third embodiment, the process of forming the n⁻ type semiconductor region EX11 as an extension region in the memory cell region AR1 is performed separately from the process of forming the n⁻ type semiconductor region EX21 as an extension region in the peripheral circuit region AR2.

Consequently, the length LN11 of the part of the n⁻ type semiconductor region EX11 in the gate length direction, the part overlapping with the gate electrode GE11 when seen in a plan view, can be made longer than the length LN21 of the part of the n⁻ type semiconductor region EX21 in the gate length direction, the part overlapping with the gate electrode GE2 when seen in a plan view.

Note that the example in which the overlap length between the n⁻ type semiconductor region EX11 as an extension region and the gate electrode GE11 is made longer in the semiconductor device of the second embodiment has been described in the third embodiment. Accordingly, by the synergy effect between the second embodiment and the third embodiment, the effect of preventing or suppressing the increase of the gate withstand voltage is enhanced in comparison with the semiconductor device of the second embodiment.

However, it is also possible to increase the overlap length between n⁻ type semiconductor region EX11 as an extension region and the gate electrode GE11 in the semiconductor device of the first embodiment. Namely, the semiconductor device of the third embodiment can be applied also to the case where a positive potential is applied to the gate electrode GE11 in the write operation. In this manner, the gate withstand voltage can be further reduced in comparison with the first embodiment.

In the foregoing, the invention made by the inventors of the present invention has been concretely described based on the embodiments. However, it is needless to say that the present invention is not limited to the foregoing embodiments and various modifications and alterations can be made within the scope of the present invention.

What is claimed is:

1. A semiconductor device comprising:
a semiconductor substrate; and
an anti-fuse element formed on the semiconductor substrate,
wherein the semiconductor substrate includes:
a base member;
a first semiconductor region of a first conductivity type formed on a main surface side of the base member;
a first insulating layer formed on the first semiconductor region; and
a first semiconductor layer formed on the first insulating layer,
the anti-fuse element includes:
a first gate electrode formed on the first semiconductor layer via a first gate insulating film; and
a second semiconductor region of a second conductivity type opposite to the first conductivity type formed in a part of the first semiconductor layer located on a first side with respect to the first gate electrode,
the anti-fuse element constitutes a storage element, and
a first potential is applied to the first gate electrode and a second potential having the same polarity as the first potential is applied to the first semiconductor region in a write operation of the storage element.

2. The semiconductor device according to claim 1,
wherein a potential of the first semiconductor region is a ground potential in a read operation of the storage element.

3. The semiconductor device according to claim 1,
wherein the first conductivity type is a p type,
the second conductivity type is an n type,
the first gate electrode is made of an n type first semiconductor film, and
the first potential and the second potential are both positive potentials.

4. The semiconductor device according to claim 1,
wherein the first conductivity type is a p type,
the second conductivity type is an n type,
the first gate electrode is made of a p type second semiconductor film, and
the first potential and the second potential are both negative potentials.

5. The semiconductor device according to claim 1, further comprising:
a first field effect transistor formed on the semiconductor substrate,
wherein the first conductivity type is a p type,
the second conductivity type is an n type,
the first semiconductor region is formed in a first region on the main surface side of the base member,
the first gate electrode is made of a third semiconductor film to which an n type first impurity is introduced,
the semiconductor substrate includes:
a p type third semiconductor region formed in a second region on the main surface side of the base member;
a second insulating layer formed on the third semiconductor region; and
a second semiconductor layer formed on the second insulating layer,
the first field effect transistor includes:
a second gate electrode formed on the second semiconductor layer via a second gate insulating film; and
an n type fourth semiconductor region formed in a part of the second semiconductor layer located on a second side with respect to the second gate electrode,
the second gate electrode is made of a fourth semiconductor film to which an n type second impurity is introduced,
a concentration of the first impurity in the first gate electrode is lower than a concentration of the second impurity in the second gate electrode, and
the first potential and the second potential are both negative potentials.

6. The semiconductor device according to claim 1,
wherein the first conductivity type is a p type,
the second conductivity type is an n type,
the first gate electrode is made of a fifth semiconductor film to which an n type third impurity is introduced,
a concentration of the third impurity in a part of the first gate electrode, which is in contact with the first gate insulating film, is lower than a concentration of the third impurity in an upper layer part of the first gate electrode, and
the first potential and the second potential are both negative potentials.

7. The semiconductor device according to claim 1, further comprising:
a second field effect transistor formed on the semiconductor substrate,
wherein the first conductivity type is a p type,
the second conductivity type is an n type,
the first semiconductor region is formed in a third region on the main surface side of the base member,
the first gate electrode is made of a sixth semiconductor film to which an n type fourth impurity is introduced,
the semiconductor substrate includes:
a p type fifth semiconductor region formed in a fourth region on the main surface side of the base member;
a third insulating layer formed on the fifth semiconductor region; and
a third semiconductor layer formed on the third insulating layer,
the second field effect transistor includes:
a third gate electrode formed on the third semiconductor layer via a third gate insulating film; and
an n type sixth semiconductor region formed in a part of the third semiconductor layer located on a third side with respect to the third gate electrode,
the third gate electrode is made of a seventh semiconductor film to which an n type fifth impurity is introduced,
the second semiconductor region is formed in a part of the first semiconductor layer located on the first side with respect to the first gate electrode in a first gate length direction of the first gate electrode,
the sixth semiconductor region is formed in a part of the third semiconductor layer located on the third side with respect to the third gate electrode in a second gate length direction of the third gate electrode,
the second semiconductor region overlaps with the part of the first gate electrode on the first side when seen in a plan view,
the sixth semiconductor region overlaps with the part of the third gate electrode on the third side when seen in a plan view, and
a length of the part of the second semiconductor region in the first gate length direction, which overlaps with the first gate electrode, is longer than a length of the part of the sixth semiconductor region in the second gate length direction, which overlaps with the third gate electrode.

8. The semiconductor device according to claim 1, further comprising:
a third field effect transistor formed on the semiconductor substrate,
wherein the first semiconductor region is formed in a fifth region on the main surface side of the base member,
the semiconductor substrate includes:
a seventh semiconductor region of the first conductivity type formed in a sixth region on the main surface side of the base member;
a fourth insulating layer formed on the seventh semiconductor region; and
a fourth semiconductor layer formed on the fourth insulating layer,
the third field effect transistor includes:
a fourth gate electrode formed on the fourth semiconductor layer via a fourth gate insulating film; and
an eighth semiconductor region of the second conductivity type formed in a part of the fourth semiconductor layer located on a fourth side with respect to the fourth gate electrode, and
a third potential different from the second potential is applied to the eighth semiconductor region in the write operation of the storage element.

9. The semiconductor device according to claim 1, further comprising:
a fourth field effect transistor formed on the semiconductor substrate,
wherein the fourth field effect transistor includes:
a fifth gate electrode formed via a fifth gate insulating film on a part of the first semiconductor layer located on a side opposite to the first gate electrode with the second semiconductor region interposed therebetween; and
a ninth semiconductor region of the second conductivity type formed in a part of the first semiconductor layer located on a side opposite to the second semiconductor region with the fifth gate electrode interposed therebetween,
the anti-fuse element and the fourth field effect transistor share the second semiconductor region,
the anti-fuse element and the fourth field effect transistor constitute the storage element,
data is written to the storage element by a dielectric breakdown of the first gate insulating film, and
a potential of the ninth semiconductor region is a ground potential and the fourth field effect transistor is in an ON state in the write operation of the storage element.

10. A semiconductor device comprising:
a semiconductor substrate;
an anti-fuse element formed on the semiconductor substrate; and
a field effect transistor formed on the semiconductor substrate,
wherein the semiconductor substrate includes:
a base member;
a first semiconductor region of a first conductivity type formed in a first region on a main surface side of the base member;
a first insulating layer formed on the first semiconductor region;
a first semiconductor layer formed on the first insulating layer;
a second semiconductor region of the first conductivity type formed in a second region on the main surface side of the base member;
a second insulating layer formed on the second semiconductor region; and
a second semiconductor layer formed on the second insulating layer,
the anti-fuse element includes:
a first gate electrode formed on the first semiconductor layer via a first gate insulating film; and
a third semiconductor region of a second conductivity type opposite to the first conductivity type formed in a part of the first semiconductor layer located on a first side with respect to the first gate electrode,
the field effect transistor includes:
a second gate electrode formed on the second semiconductor layer via a second gate insulating film; and
a fourth semiconductor region of the second conductivity type formed in a part of the second semiconductor layer located on a second side with respect to the second gate electrode,
the anti-fuse element constitutes a storage element,
the first gate electrode is made of a first semiconductor film to which a first impurity of the second conductivity type is introduced,
the second gate electrode is made of a second semiconductor film to which a second impurity of the second conductivity type is introduced, and
a concentration of the first impurity in the first gate electrode is lower than a concentration of the second impurity in the second gate electrode.

11. The semiconductor device according to claim 10,
wherein a concentration of the first impurity in a part of the first gate electrode, which is in contact with the first gate insulating film, is lower than a concentration of the first impurity in an upper layer part of the first gate electrode.

12. The semiconductor device according to claim 10,
wherein the first conductivity type is a p type,
the second conductivity type is an n type, and
a negative potential is applied to the first gate electrode in a write operation of the storage element.

13. The semiconductor device according to claim 10,
wherein the third semiconductor region is formed in a part of the first semiconductor layer located on the first side with respect to the first gate electrode in a first gate length direction of the first gate electrode,
the fourth semiconductor region is formed in a part of the second semiconductor layer located on the second side with respect to the second gate electrode in a second gate length direction of the second gate electrode,
the third semiconductor region overlaps with a part of the first gate electrode on the first side when seen in a plan view,
the fourth semiconductor region overlaps with apart of the second gate electrode on the second side when seen in a plan view, and
a length of a part of the third semiconductor region in the first gate length direction, which overlaps with the first gate electrode, is longer than a length of a part of the fourth semiconductor region in the second gate length direction, which overlaps with the second gate electrode.

14. A manufacturing method of a semiconductor device, comprising the steps of:
(a) preparing a semiconductor substrate; and
(b) forming an anti-fuse element and a field effect transistor on the semiconductor substrate,
wherein, in the step (a), the semiconductor substrate including: a base member; a first semiconductor region of a first conductivity type formed in a first region on a main surface side of the base member; a first insulating layer formed on the first semiconductor region; a first semiconductor layer formed on the first insulating layer; a second semiconductor region of the first conductivity type formed in a second region on the main surface side of the base member; a second insulating layer formed on the second semiconductor region; and a second semiconductor layer formed on the second insulating layer is prepared,
the step (b) includes the steps of:
(b1) forming a first gate electrode made of a first semiconductor film on the first semiconductor layer via a first gate insulating film, forming a protective film on the first gate electrode, and forming a second gate electrode made of a second semiconductor film on the second semiconductor layer via a second gate insulating film;
(b2) forming a first sidewall spacer on a first side surface on a first side of the first gate electrode;
(b3) ion-implanting a first impurity of a second conductivity type opposite to the first conductivity type to a part of the first semiconductor layer located on a side opposite to the first gate electrode with the first sidewall spacer interposed therebetween, thereby forming a third semiconductor region of the second conductivity type, and ion-implanting no first impurity to the second semiconductor layer;
(b4) after the step (b3), removing the protective film and the first sidewall spacer;
(b5) after the step (b4), ion-implanting a second impurity of the second conductivity type to a part of the first semiconductor layer located between the first gate electrode and the third semiconductor region, thereby forming a fourth semiconductor region of the second conductivity type, and ion-implanting a third impurity of the second conductivity type to a part of the second semiconductor layer located on a second side of the second gate electrode, thereby forming a fifth semiconductor region of the second conductivity type;
(b6) after the step (b5), forming a second sidewall spacer on the first side surface of the first gate electrode and forming a third sidewall spacer on a second side surface on the second side of the second gate electrode; and
(b7) ion-implanting a fourth impurity of the second conductivity type to a part of the second semiconductor layer located on a side opposite to the second gate electrode with the third sidewall spacer interposed therebetween, thereby forming a sixth semiconductor region of the second conductivity type,
in the step (b3), the first impurity is not ion-implanted to the first gate electrode,
in the step (b5), the second impurity is ion-implanted to the first gate electrode,
in the step (b7), the fourth impurity is ion-implanted to the second gate electrode and the fourth impurity is not ion-implanted to the first gate electrode,
a concentration of the first impurity in the third semiconductor region is higher than a concentration of the second impurity in the fourth semiconductor region,
a concentration of the fourth impurity in the sixth semiconductor region is higher than a concentration of the third impurity in the fifth semiconductor region, and
a concentration of the second impurity in the first gate electrode to which the second impurity is ion-implanted in the step (b5) is lower than a concentration of the fourth impurity in the second gate electrode to which the fourth impurity is ion-implanted in the step (b7).

15. The manufacturing method of a semiconductor device according to claim 14,
wherein the step (b5) includes the steps of:
(b8) ion-implanting the second impurity to a part of the first semiconductor layer located between the first gate electrode and the third semiconductor region, thereby forming the fourth semiconductor region; and
(b9) before the step (b8) or after the step (b8), ion-implanting the third impurity to a part of the second semiconductor layer located on the second side of the second gate electrode, thereby forming the fifth semiconductor region,
the fourth semiconductor region is formed in a part of the first semiconductor layer located on the first side with respect to the first gate electrode in a first gate length direction of the first gate electrode,
the fifth semiconductor region is formed in a part of the second semiconductor layer located on the second side with respect to the second gate electrode in a second gate length direction of the second gate electrode,
the fourth semiconductor region overlaps with a part of the first gate electrode on the first side when seen in a plan view,
the fifth semiconductor region overlaps with a part of the second gate electrode on the second side when seen in a plan view, and
a length of a part of the fourth semiconductor region in the first gate length direction, which overlaps with the first gate electrode, is longer than a length of a part of the fifth semiconductor region in the second gate length direction, which overlaps with the second gate electrode.
